(19) United States
(12) Patent Application Publication
(10) Pub. No.: US 2008/0114151 A1
(43) Pub. Date: May 15, 2008

(54) Polymer Compound And Device Using The Same

(75) Inventors: Nobuhiko Shirasawa, Shiga (JP); Nobuhiko Akino, Saitama (JP); Tomoya Nakatani, Ibaraki (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY LIMITED, CHUO-KU TOKYO (JP)

(21) Appl. No.: 11/722,361

(22) PCT Filed: Dec. 22, 2005
(86) PCT No.: PCT/JP05/24162

§ 371 Date: Jun. 21, 2007

(30) Foreign Application Priority Data
Dec. 28, 2004 (JP) 2004-378519
Jan. 14, 2005 (JP) 2005-007565

(51) Int. Cl. C09K 11/06; H01L 51/54

(52) U.S. Cl. 528/395; 546/2; 546/4; 546/10; 548/101; 548/402; 549/3; 257/40; 428/917; 313/504; 313/506; 428/690; 257/E51.044; 549/206

(57) ABSTRACT

A polymer compound comprising in the same molecule a structure of (A) a conjugated polymer and a structure of (B) a metal complex having at least one tridentate ligand and having a central metal of which atomic number is 21 or more.

### TECHNOLOGICAL FIELD

The present invention relates to a polymer compound and a device using the same.

### BACKGROUND ART

Polymer compounds having in the same molecule a structure of a conjugated polymer and a structure of a metal complex are known as the material for polymer light emitting devices (polymer LED) (Journal of American Chemical Society, vol. 125, p 636 (2003); WO 03/102109A1).

### DISCLOSURE OF THE INVENTION

The structure of a metal complex in the above-mentioned polymer compound has a ligand which is a bidentate ligand of phenylpyridine and the like and has a central metal composed of iridium (atomic number: 77), and a polymer LED using this polymer compound is not admitted to have practically sufficient performances since light emitting efficiency is insufficient, and the like.

An object of the present invention is to provide a metal complex and a polymer compound having in the same molecule a structure of a conjugated polymer and a structure of a metal complex which when used in a light emitting device, the light emitting device having excellent practical properties such as drivability with high efficiency and at low voltage, and the like.

That is, the present invention provides a polymer compound comprising in the same molecule a structure of (A) a conjugated polymer and a structure of (B) a metal complex having at least one tridentate ligand and having a central metal of which atomic number is 21 or more.

### BEST MODES FOR CARRYING OUT THE INVENTION

The polymer compound of the present invention has a structure of (A) a conjugated polymer and a structure of (B) a metal complex having at least one tridentate ligand and having a central metal of which atomic number is 21 or more, in the same molecule.

Examples of the polymer compound of the present invention include polymer compounds having a structure of the above-mentioned metal complex (B) in the main chain of the conjugated polymer (A); polymer compounds having a structure of the above-mentioned metal complex (B) on the end of the conjugated polymer (A); polymer compounds having a structure of the above-mentioned metal complex (B) on the side chain of the conjugated polymer (A); and the like.

Of polymer compounds of the present invention, those satisfying the following formula (Eq1) are preferable.

ET_{A}−ES_{A0}≧(ET_{B}−ES_{B0})−0.2 eV (Eq1)

Here, ES_{A0} represents energy at the ground state of the conjugated polymer (A), ET_{A} represents energy level at the lowest excited triplet state of the conjugated polymer (A), ES_{B0} represents energy level at the ground state of the metal complex (B), and ET_{B} represents energy level at the lowest excited triplet state of the metal complex (B).

Respective energy differences between the ground state and the lowest excited triplet state of the conjugated polymer (A) and the metal complex (B) in (Eq1) (ET_{A}−ES_{A0}, ET_{B}−ES_{B0}, in this order) are determined by some actual measurement methods, however, in the present invention, the relative magnitude relation between the above-mentioned energy difference of the metal complex (B) and the above-mentioned energy difference of the conjugated polymer (A) to be used as a matrix is usually important for obtaining higher light emission efficiency, thus, the energy differences are determined usually by a computational scientific means.

Particularly, it is preferable to further satisfy the following formula (Eq1-2) in the range satisfying the above-mentioned formula (Eq1), for obtaining higher light emission efficiency.

ET_{A}−ES_{A0}≧ET_{B}−ES_{B0} (Eq1-2)

Here, ET_{A}, ES_{A0}, ET_{B} and ES_{B0} represent the same meanings as described above.

Further, it is preferable that energy level ET_{A} at the lowest excited triplet state of the conjugated polymer (A) and energy level ET_{B} at the lowest excited triplet state of the metal complex (B) satisfy the relation of

ET_{A}≧ET_{B} (Eq2)

and lowest excited singlet level ES_{A1} of the conjugated polymer (A) and lowest excited singlet level ES_{B1} of the metal complex (B) satisfy the relation of

ES_{A1}≧ES_{B1} (Eq3)

for obtaining higher light emission efficiency.

As the above-mentioned computational scientific means for calculating the energy difference at vacuum level and LUMO, there are known a molecular orbital method, density functional method and the like based on semi-empirical methods and non-empirical methods. For example, for calculating excitation energy, a Hartree-Fock (HF) method or a density functional method may be used. Usually, using a quantum chemical calculation program Gaussian 98, energy difference between the ground stated and the lowest excited triplet state (hereinafter, referred to as lowest excited triplet energy), energy difference between the ground stated and the lowest excited singlet state (hereinafter, referred to as lowest excited singlet energy), HOMO energy level at the ground state and LUMO energy level at the ground state, of a triplet light emitting compound and a conjugated polymer, were calculated.

Calculations of the lowest excited triplet energy, lowest excited singlet energy, HOMO energy level at the ground state and LUMO energy level at the ground state of a conjugated polymer were effected for a monomer (n=1), dimer (n=2) and trimer (n=3), and for excitation energy of a conjugated polymer, a method was used in which the results when n=1 to 3 are treated by a function E (1/n) of 1/n (here, E represents excitation energy value to be calculated such as lowest excited singlet energy or lowest excited triplet energy and the like and linearly extrapolated to n=0. When repeating units of a conjugated polymer contain, for example, a side chain of longer chain length, then, the chemical structure can be calculated while simplifying a side chain portion into a minimum unit (for example, when an octyl group is present as the side chain, calculation is performed while hypothesizing the side chain as a methyl group). HOMO, LUMO, singlet excitation energy and triplet excitation energy of a copolymer can be calculated by the same calculation means as for the above-mentioned case for a homopolymer while using as a unit a minimum unit expected from the copolymerization ratio.

The conjugated polymer (A) in the polymer compound of the present invention will be explained.

The conjugated polymer is a molecule including long repeated connection of multiple bonds and single bonds as described in, for example, “Yuki EL no hanashi (topic of organic EL)” (edited by Katsumi Yoshino, Nikkan Kogyo Shinbun, Ltd.) p. 23, and typical examples thereof include polymers containing a repeating structure of the following structure, or a structure combining appropriately the following structures.

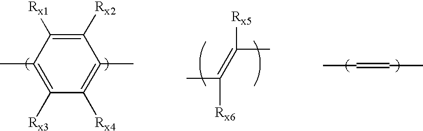

(the above-described Rₓ₁ to Rₓ₆ represent a substituent).

As the conjugated polymer (A), mentioned are those containing no aromatic ring in the main chain (for example, polyenes, polyynes) and those containing an aromatic ring in the main chain (including copolymers such as phenyletheny, phenylethynyl and the like).

Among those containing an aromatic ring in the main chain, preferable are divalent arylene groups optionally having a substituent as described above, divalent heterocyclic groups having at least one atom selected from the group consisting of an oxygen atom, nitrogen atom, silicon atom, germanium atom, tin atom, phosphorus atom, boron atom, sulfur atom, selenium atom and tellurium atom, or those having a repeating unit of the following formula (A-1), from the standpoint of high light emission efficiency.

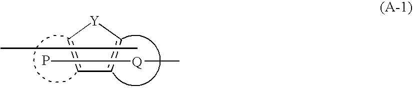

(wherein, P ring and Q ring represent each independently an aromatic ring, but P ring may not exist. Two connecting bonds exist respectively on P ring and/or Q ring when P ring is present, and exist respectively on 5-membered ring containing Y and/or Q ring when P ring is not present. A substituent may be present on an aromatic ring and/or 5-membered ring containing Y. Y represents —O—, —S—, —Se—, —B(R₃₁)—, —C(R₁)(R₂)—, —Si(R₁)(R₂)—, —P(R₃)—, —PR₄(═O)—, —C(R₅₁)(R₅₂)—C(R₅₃)(R₅₄)—, —O—C(R₅₅)(R₅₆)—, —S—C(R₅₇)(R₅₈)—, —N—C(R₅₉)(R₆₀)—, —Si(R₆₁)(R₆₂)—C(R₆₃)(R₆₄)—, —Si(R₆₅)(R₆₆)—Si(R₆₇)(R₆₈)—, —C(R₆₉)═C(R₇₀)—, —N═C(R₇₁)—, or —Si(R₇₂)═C(R₇₃)— or —Si(R₇₂)═C(R₇₃)—, R₃, represents a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group or substituted silyloxy group, R₁ to R₄ and R₅₁ to R₇₃ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group or halogen atom.).

The alkyl group may be any of linear, branched or cyclic. The number of carbon atoms is usually about 1 to 20, preferably 3 to 20. Concrete examples thereof include methyl group, ethyl group, propyl group, i-propyl group, butyl group, i-butyl group, t-butyl group, pentyl group, hexyl group, cyclohexyl group, heptyl group, octyl group, 2-ethylhexyl group, nonyl group, decyl group, 3,7-dimethyloctyl group, lauryl group, trifluoromethyl group, pentafluoroethyl group, perfluorobutyl group, perfluorohexyl group, perfluorooctyl group, etc.; and pentyl group, hexyl group, octyl group, 2-ethylhexyl group, decyl group, and 3,7-dimethyloctyl group are preferable.

The alkoxy group may be any of linear, branched or cyclic. The number of carbon atoms is usually about 1 to 20, preferably 3 to 20. Concrete examples thereof include methoxy group, ethoxy group, propyloxy group, i-propyloxy group, butoxy group, i-butoxy group, t-butoxy group, pentyloxy group, hexyloxy group, cyclohexyloxy group, heptyloxy group, octyloxy group, 2-ethyl hexyloxy group, nonyloxy group, decyloxy group, 3,7-dimethyl octyloxy group, lauryloxy group, trifluoromethoxy group, pentafluoroethoxy group, perfluorobutoxy group, perfluorohexyloxy group, perfluorooctyloxy group, methoxymethyloxy group, 2-methoxyethyloxy group, etc.; and pentyloxy group, hexyloxy group, octyloxy group, 2-ethylhexyloxy group, decyloxy group, and 3,7-dimethyl octyloxy group are preferable.

The alkylthio group may be any of linear, branched or cyclic. The number of carbon atoms is usually about 1 to 20, preferably 3 to 20. Concrete examples thereof include methylthio group, ethylthio group, propylthio group, i-propylthio group, butylthio group, i-butylthio group, t-butylthio group, pentylthio group, hexylthio group, cyclo hexylthio group, heptylthio group, octylthio group, 2-ethyl hexylthio group, nonylthio group, decylthio group, 3,7-dimethyloctylthio group, laurylthio group, trifluoromethylthio group, etc.; and pentylthio group, hexylthio group, octylthio group, 2-ethyl hexylthio group, decylthio group, and 3,7-dimethyloctylthio group are preferable.

The aryl group has usually about 6 to 60 carbon atoms, and preferably 7 to 48. Concrete examples thereof include phenyl group, C₁-C₁₂ alkoxyphenyl group (C₁-C₁₂ represents the number of carbon atoms 1-12. Hereafter the same), C₁-C₁₂ alkylphenyl group, 1-naphtyl group, 2-naphtyl group, 1-anthracenyl group, 2-anthracenyl group, 9-anthracenyl group, pentafluorophenyl group, etc., and C₁-C₁₂ alkoxyphenyl group and C₁-C₁₂ alkylphenyl group are preferable. The aryl group is an atomic group in which one hydrogen atom is removed from an aromatic hydrocarbon. The aromatic hydrocarbon includes those having a condensed ring, an independent benzene ring, or two or more condensed rings bonded through groups, such as a direct bond or a vinylene group.

Concrete examples of C₁-C₁₂ alkoxy include methoxy, ethoxy, propyloxy, i-propyloxy, butoxy, i-butoxy, t-butoxy, pentyloxy, hexyloxy, cyclohexyloxy, heptyloxy, octyloxy, 2-ethylhexyloxy, nonyloxy, decyloxy, 3,7-dimethyloctyloxy, lauryloxyphenoxy, etc.

Concrete examples of C₁-C₁₂ alkylphenyl group include methylphenyl group, ethylphenyl group, dimethylphenyl group, propylphenyl group, mesityl group, methylethylphenyl group, i-propylphenyl group, butylphenyl group, i-butylphenyl group, t-butylphenyl group, pentylphenyl group, isoamylphenyl group, hexylphenyl group, heptylphenyl group, octylphenyl group, nonylphenyl group, decylphenyl group, dodecylphenyl group, etc.

The aryloxy group has the number of carbon atoms of usually about 6 to 60, preferably 7 to 48, and concrete examples thereof include phenoxy group, C₁-C₁₂ alkoxyphenoxy group, C₁-C₁₂ alkyl phenoxy group, 1-naphtyloxy group, 2-naphtyloxy group, pentafluorophenyloxy group, etc.; and C₁-C₁₂ alkoxyphenoxy group and C₁-C₁₂ alkylphenoxy group are preferable.

Concrete examples of C₁-C₁₂ alkoxy include methoxy, ethoxy, propyloxy, i-propyloxy, butoxy, i-butoxy, t-butoxy, pentyloxy, hexyloxy, cyclohexyloxy, heptyloxy, octyloxy, 2-ethylhexyloxy, nonyloxy, decyloxy, 3,7-dimethyloctyloxy, lauryloxyphenoxy, etc.

Concrete examples of C₁-C₁₂ alkylphenoxy group include methylphenoxy group, ethylphenoxy group, dimethylphenoxy group, propylphenoxy group, 1,3,5-trimethylphenoxy group, methylethylphenoxy group, i-propylphenoxy group, butyl phenoxy group, i-butylphenoxy group, t-butylphenoxy group, pentylphenoxy group, isoamylphenoxy group, hexylphenoxy group, heptylphenoxy group, octylphenoxy group, nonylphenoxy group, decylphenoxy group, dodecylphenoxy group, etc.

The arylthio group has the number of carbon atoms of usually about 6 to 60, preferably 7 to 48, and concrete examples thereof include phenylthio group, C₁-C₁₂ alkoxyphenylthio group, C₁-C₁₂ alkylphenylthio group, 1-naphthylthio group, 2-naphthylthio group, pentafluorophenylthio group, etc.; C₁-C₁₂ alkoxy phenylthio group and C₁-C₁₂ alkyl phenylthio group are preferable.

The arylalkyl group has the number of carbon atoms of usually about 7 to 60, preferably 7 to 48, and concrete examples thereof include phenyl-C₁-C₁₂alkyl group, C₁-C₁₂alkoxy phenyl-C₁-C₁₂ alkyl group, C₁-C₁₂ alkylphenyl-C₁-C₁₂ alkyl group, 1-naphtyl-C₁-C₁₂ alkyl group, 2-naphtyl-C₁-C₁₂ alkyl group etc.; and C₁-C₁₂-alkoxyphenyl-C₁-C₁₂ alkyl group and C₁-C₁₂ alkyl phenyl-C₁-C₁₂ alkyl group are preferable.

The arylalkoxy group has the number of carbon atoms of usually about 7 to 60, preferably 7 to 48, and concrete examples thereof include: phenyl-C₁-C₁₂alkoxy groups, such as phenylmethoxy group, phenylethoxy group, phenylbutoxy group, phenylpentyloxy group, phenylhexyloxy group, phenylheptyloxy group, and phenyloctyloxy group; C₁-C₁₂alkoxyphenyl-C₁-C₁₂ alkoxy group, C₁-C₁₂alkylphenyl-C₁-C₁₂alkoxy group, 1-naphtyl-C₁-C₁₂ alkoxy group, 2-naphtyl-C₁-C₁₂ alkoxy group etc.; and C₁-C₁₂ alkoxyphenyl-C₁-C₁₂ alkoxy group and C₁-C₁₂ alkylphenyl-C₁-C₁₂ alkoxy group are preferable.

The arylalkylthio group has the number of carbon atoms of usually about 7 to 60, preferably 7 to 48, and concrete examples thereof include: phenyl-C₁-C₁₂ alkylthio group, C₁-C₁₂ alkoxy phenyl-C₁-C₁₂ alkylthio group, C₁-C₁₂ alkylphenyl-C₁-C₁₂ alkylthio group, 1-naphtyl-C₁-C₁₂ alkylthio group, 2-naphtyl-C₁-C₁₂ alkylthio group, etc.; and C₁-C₁₂ alkoxy phenyl-C₁-C₁₂ alkylthio group and C₁-C₁₂ alkylphenyl-C₁-C₁₂ alkylthio group are preferable.

The arylalkenyl group has the number of carbon atoms of usually about 7 to 60, preferably 7 to 48, and concrete examples thereof include: phenyl-C₂-C₁₂ alkenyl group, C₁-C₁₂ alkoxy phenyl-C₂-C₁₂ alkenyl group, C₁-C₁₂ alkyl phenyl-C₂-C₁₂ alkenyl group, 1-naphtyl-C₂-C₁₂ alkenyl group, 2-naphtyl-C₂-C₁₂alkenyl group, etc.; and C₁-C₁₂ alkoxy phenyl-C₂-C₁₂alkenyl group, and C₂-C₁₂alkyl phenyl-C₁-C₁₂ alkenyl group are preferable.

The arylalkynyl group has the number of carbon atoms of usually about 7 to 60, preferably 7 to 48, and concrete examples thereof include: phenyl-C₂-C₁₂ alkynyl group, C₁-C₁₂ alkoxy phenyl-C₂-C₁₂ alkynyl group, C₁-C₁₂ alkylphenyl-C₂-C₁₂ alkynyl group, 1-naphtyl-C₂-C₁₂ alkynyl group, 2-naphtyl-C₂-C₁₂ alkynyl group, etc.; and C₁-C₁₂ alkoxyphenyl-C₂-C₁₂ alkynyl group, and C₁-C₁₂ alkylphenyl-C₂-C₁₂ alkynyl group are preferable.

The substituted amino group means a amino group substituted by 1 or 2 groups selected from an alkyl group, aryl group, arylalkyl group, or monovalent heterocyclic group, and said alkyl group, aryl group, arylalkyl group, or monovalent heterocyclic group may have substituent. The substituted amino groups has usually about 1 to 60, preferably 2 to 48 carbon atoms, without including the number of carbon atoms of said substituent.

Concrete examples thereof include methylamino group, dimethylamino group, ethylamino group, diethylamino group, propylamino group, dipropylamino group, i-propylamino group, diisopropylamino group, butylamino group, i-butyl amino group, t-butylamino group, pentylamino group, hexyl amino group, cyclohexylamino group, heptylamino group, octyl amino group, 2-ethylhexylamino group, nonylamino group, decyl amino group, 3,7-dimethyloctylamino group, laurylamino group, cyclopentylamino group, dicyclopentyl amino group, cyclohexyl amino group, dicyclohexylamino group, pyrrolidyl group, piperidyl group, ditrifluoromethylamino group, phenylamino group, diphenylamino group, C₁-C₁₂ alkoxyphenylamino group, di(C₁-C₁₂ alkoxyphenyl)amino group, di(C₁-C₁₂ alkylphenyl)amino group, 1-naphtylamino group, 2-naphtylamino group, pentafluorophenylamino group, pyridylamino group, pyridazinylamino group, pyrimidylamino group, pyrazylamino group, triazylamino group phenyl-C₁-C₁₂ alkylamino group, C₁-C₁₂-alkoxyphenyl-C₁-C₁₂alkylamino group, C₁-C₁₂ alkyl phenyl-C₁-C₁₂ alkylamino group, di(C₁-C₁₂ alkoxyphenyl-C₁-C₁₂ alkyl)amino group, di(C₁-C₁₂ alkylphenyl-C₁-C₁₂ alkyl)amino group, 1-naphtyl-C₁-C₁₂ alkylamino group, 2-naphtyl-C₁-C₁₂ alkylamino group, etc.

The substituted silyl group means a silyl group substituted by 1, 2 or 3 groups selected from an alkyl group, aryl group, arylalkyl group, or monovalent heterocyclic group. The substituted silyl group has usually about 1 to 60, preferably 3 to 48 carbon atoms. Said alkyl group, aryl group, arylalkyl group, or monovalent heterocyclic group may have substituent.

Concrete examples of the substituted silyl group include trimethylsilyl group, triethylsilyl group, tripropylsilyl group, tri-1-propylsilyl group, dimethyl-1-propylsilyl group, diethyl-1-propylsilyl group, t-butylsilyldimethylsilyl group, pentyldimethylsilyl group, hexyldimethylsilyl group, heptyl dimethylsilyl group, octyldimethylsilyl group, 2-ethyl hexyl-dimethylsilyl group, nonyldimethylsilyl group, decyl dimethylsilyl group, 3,7-dimethyloctyl-dimethylsilyl group, lauryldimethylsilyl group, phenyl-C₁-C₁₂ alkylsilyl group, C₁-C₁₂ alkoxyphenyl-C₁-C₁₂ alkylsilyl group, C₁-C₁₂ alkyl phenyl-C₁-C₁₂ alkylsilyl group, 1-naphtyl-C₁-C₁₂ alkylsilyl group, 2-naphtyl-C₁-C₁₂ alkylsilyl group, phenyl-C₁-C₁₂ alkyl dimethylsilyl group, triphenylsilyl group, tri-p-xylylsilyl group, tribenzylsilyl group, diphenylmethylsilyl group, t-butyldiphenylsilyl group, dimethylphenylsilyl group, etc.

As the substituted silyloxy group, mentioned are silyloxy groups (H³SiO—) substituted with one, two or three groups selected from alkyl groups, aryl groups, arylalkyl groups and monovalent heterocyclic groups, and the carbon number is usually 1 to about 60, preferably 3 to 30. The alkyl group, aryl group, arylalkyl group or monovalent heterocyclic group may also have a substituent.

Specifically exemplified are a trimethylsilyloxy group, triethylsilyloxy group, tri-n-propylsilyloxy group, tri-1-propylsilyloxy group, t-butylsilyldimethylsilyloxy group, triphenylsilyloxy group, tri-p-xylylsilyloxy group, tribenzylsilyloxy group, diphenylmethylsilyloxy group, t-butyldiphenylsilyloxy group, dimethylphenylsilyloxy group and the like.

As the halogen atom, a fluorine atom, chlorine atom, bromine atom and iodine atom are exemplified.

The monovalent heterocyclic group means an atom group remaining after removing one hydrogen atom from a heterocyclic compound, and the carbon number is usually about 4 to 60, preferably 4 to 20. The carbon number of a heterocyclic group does not include the carbon number of a substituent. Here, the heterocyclic compound includes organic compounds having a cyclic structure in which elements constituting the ring include not only a carbon atom but also hetero atoms such as oxygen, sulfur, nitrogen, phosphorus, boron and the like contained in the ring. Specifically, a thienyl group, C₁ to C₁₂ alkylthienyl groups, pyrrolyl group, furyl group, pyridyl group, C₁ to C₁₂ alkylpyridyl groups, piperidyl group, quinolyl group, isoquinolyl group and the like are exemplified, and preferable are a thienyl group, C₁ to C₁₂ alkylthienyl groups, pyridyl group and C₁ to C₁₂ alkylpyridyl groups.

Among the above-mentioned groups, groups containing an alkyl chain may be any of linear, branched or cyclic, or a combination thereof, and in the case of nonlinear, for example, an isoamyl group, 2-ethylhexyl group, 3,7-dimethyloctyl group, cyclohexyl group, 4-C₁-C₁₂ alkylcyclohexyl groups and the like are exemplified. Also, ends of two alkyl chains may be connected to form a ring. Further, some methyl groups or methylene groups in alkyl chains may be substituted by methyl groups or methylene groups substituted with a group containing a hetero atom or with one or more fluorine atoms, and exemplified as the hetero atom are an oxygen atom, sulfur atom, nitrogen atom and the like.

When substituents exemplified above contain partially aryl groups or heterocyclic groups, these may have further one or more substituents.

Listed as the aromatic ring in the above-mentioned formula (A-1) are aromatic hydrocarbon rings such as a benzene ring, naphthalene ring and the like; and heteroaromatic rings such as a pyridine ring, bipyridine ring, phenanthroline ring, quinoline ring, isoquinoline ring, thiophene ring, furan ring, pyrrole ring and the like.

It is preferable that the repeating unit of the above-mentioned formula (A-1) has as a substituent a group selected from alkyl groups, alkoxy groups, alkylthio groups, aryl groups, aryloxy groups, arylthio groups, arylalkyl groups, arylalkoxy groups, arylalkylthio groups, arylalkenyl groups, arylalkynyl groups, amino group, substituted amino groups, silyl group, substituted silyl groups, acyloxy group, imine residue, amide group, acid imide group, monovalent heterocyclic groups, carboxyl group and substituted carboxyl groups.

Listed as the structure of the above-mentioned formula (A-1) are structures of the following formula (A-1-1), (A-1-2) or (A-1-3);

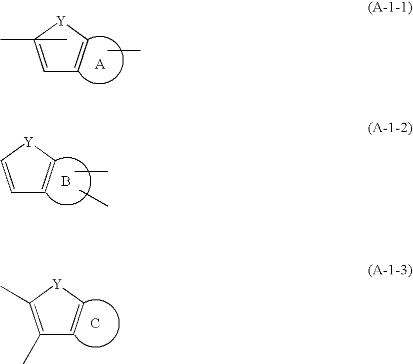

(wherein, A ring, B ring and C ring represent each independently an aromatic ring. The formulae (A-1-1), (A-1-2) and (A-1-3) may have a substituent selected from the group consisting of alkyl groups alkoxy groups, alkylthio groups, aryl groups, aryloxy groups, arylthio groups, arylalkyl groups, arylalkoxy groups, arylalkylthio groups, arylalkenyl groups, arylalkynyl groups, amino group, substituted amino groups, silyl group, substituted silyl groups, halogen atoms, acyl group, acyloxy group, imine residue, amide group, acid imide group, monovalent heterocyclic groups, carboxyl group, substituted carboxyl groups and cyano group. Y represents the same meaning as described above.) and

structures of the following formula (A-1-4) or (A-1-5);

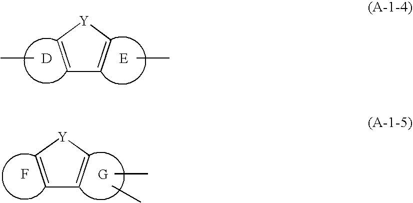

(wherein, D ring, E ring, F ring and G ring represent each independently an aromatic ring. D ring, E ring, F ring and G ring represent each independently an aromatic ring optionally having a substituent selected from the group consisting of alkyl groups, alkoxy groups, alkylthio groups, aryl groups, aryloxy groups, arylthio groups, arylalkyl groups, arylalkoxy groups, arylalkylthio groups, arylalkenyl groups, arylalkynyl groups, amino group, substituted amino groups, silyl group, substituted silyl groups, halogen atoms, acyl group, acyloxy group, imine residue, amide group, acid imide group, monovalent heterocyclic groups, carboxyl group, substituted carboxyl groups and cyano group. Y represents the same meaning as described above.), and preferable are structures of the above-mentioned formula (A-1-4) or (A-1-5) from the standpoint of light emission efficiency.

Y is preferably —S—, —O— or —C(R₁)(R₂)— for obtaining high light emission efficiency, and further preferably —S— or —O—. Here, R₁ and R₂ represent the same meanings as described above.

The acyl group has usually about 2 to 20 carbon atoms, preferably 2 to 18 carbon atoms, and concrete examples thereof include acetyl group, propionyl group, butyryl group, isobutyryl group, pivaloyl group, benzoyl group, trifluoro acetyl group, pentafluorobenzoyl group, etc.

The acyloxy group has usually about 2 to 20 carbon atoms, preferably 2 to 18 carbon atoms, and concrete examples thereof include acetoxy group, propionyloxy group, butyryloxy group, isobutyryloxy group, pivaloyloxy group, benzoyloxy group, trifluoroacetyloxy group, pentafluorobenzoyloxy group, etc.

Imine residue is a residue in which a hydrogen atom is removed from an imine compound (an organic compound having —N═C— is in the molecule. Examples thereof include aldimine, ketimine, and compounds whose hydrogen atom on N is substituted with an alkyl group etc.), and usually has about 2 to 20 carbon atoms, preferably 2 to 18 carbon atoms. As the concrete examples, groups represented by below structural formulas are exemplified.

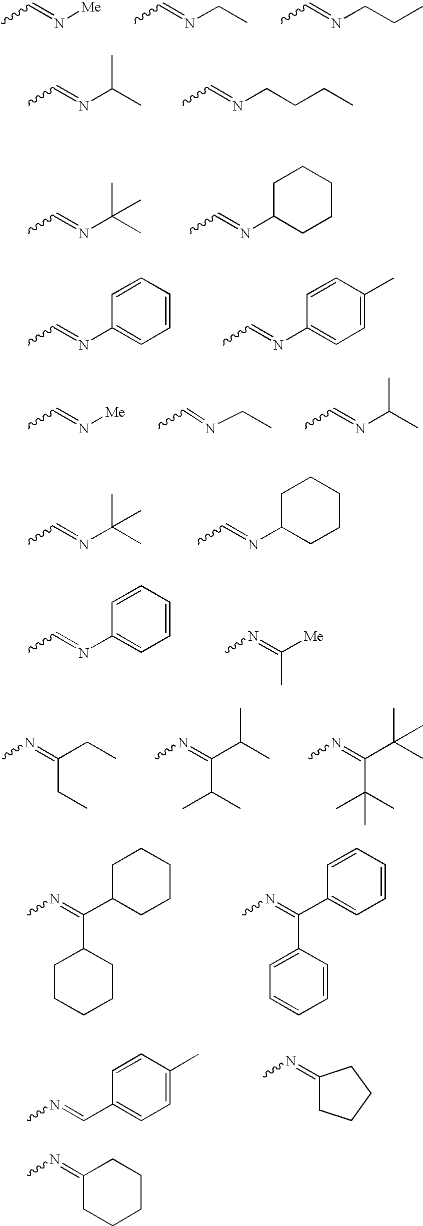

The amide group has usually about 2 to 20 carbon atoms, preferably 2 to 18 carbon atoms, and concrete examples thereof include formamide group, acetamide group, propioamide group, butyroamide group, benzamide group, trifluoroacetamide group, pentafluoro benzamide group, diformamide group, diacetoamide group, dipropioamide group, dibutyroamide group, dibenzamide group, ditrifluoro acetamide group, dipentafluorobenzamide group, etc.

Examples of the acid imide group include residual groups in which a hydrogen atom connected with nitrogen atom is removed, and have usually about 2 to 60 carbon atoms, preferably 2 to 48 carbon atoms. As the concrete examples of acid imide group, the following groups are exemplified.

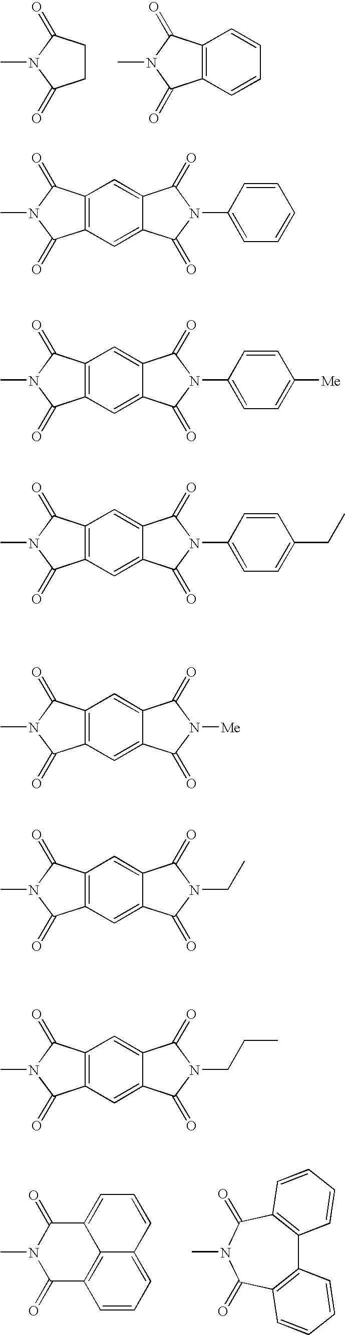

The substituted carboxyl group has a carbon number of usually about 2 to 60, preferably of 2 to 48. It means a carboxyl group substituted with an alkyl group, aryl group, arylalkyl group or monovalent heterocyclic group, and listed are a methoxycarbonyl group, ethoxycarbonyl group, propoxycarbonyl group, i-propoxycarbonyl group, butoxycarbonyl group, i-butoxycarbonyl group, t-butoxycarbonyl group, pentyloxycarbonyl group, hexyloxycarbonyl group, cyclohexyloxycarbonyl group, heptyloxycarbonyl group, octyloxycarbonyl group, 2-ethylhexyloxycarbonyl group, nonyloxycarbonyl group, decyloxycarbonyl group, 3,7-dimethyloctyloxycarbonyl group, dodecyloxycarbonyl group, trifluoromethoxycarbonyl group, pentafluoroethoxycarbonyl group, perfluorobutoxycarbonyl group, perfluorohexyloxycarbonyl group, perfluorooctyloxycarbonyl group, phenoxycarbonyl group, naphthoxycarbonyl group, pyridyloxycarbonyl group and the like. The alkyl group, aryl group, arylalkyl group or monovalent heterocyclic group may have a substituent. The carbon number of the substituted carboxyl group does not include the carbon number of the substituent.

As the aromatic ring represented by A ring, B ring, C ring, D ring, E ring, F ring and G ring in the above-described formulae (A-1-1), (A-1-2), (A-1-3), (A-1-4) and (A-1-5), listed are aromatic hydrocarbon rings such as a benzene ring, naphthalene ring, anthracene ring, tetracene ring, pentacene ring, pyrene ring, phenanthrene ring and the like; and heteroaromatic rings such as a pyridine ring, bipyridine ring, phenanthroline ring, quinoline ring, isoquinoline ring, thiophene ring, furan ring, pyrrole ring and the like.

It is preferable that the repeating unit of the above-described formulae (A-1-1), (A-1-2), (A-1-3), (A-1-4) and (A-1-5) has as a substituent a group selected from alkyl groups, alkoxy groups, alkylthio groups, aryl groups, aryloxy groups, arylthio groups, arylalkyl groups, arylalkoxy groups, arylalkylthio groups, arylalkenyl groups, arylalkynyl groups, amino group, substituted amino groups, silyl group, substituted silyl groups, acyloxy group, imine residue, amide group, acid imide group, monovalent heterocyclic groups, carboxyl group and substituted carboxyl groups.

Among specific examples of the formula (A-1-1), examples as shown below are listed as unsubstituted groups.

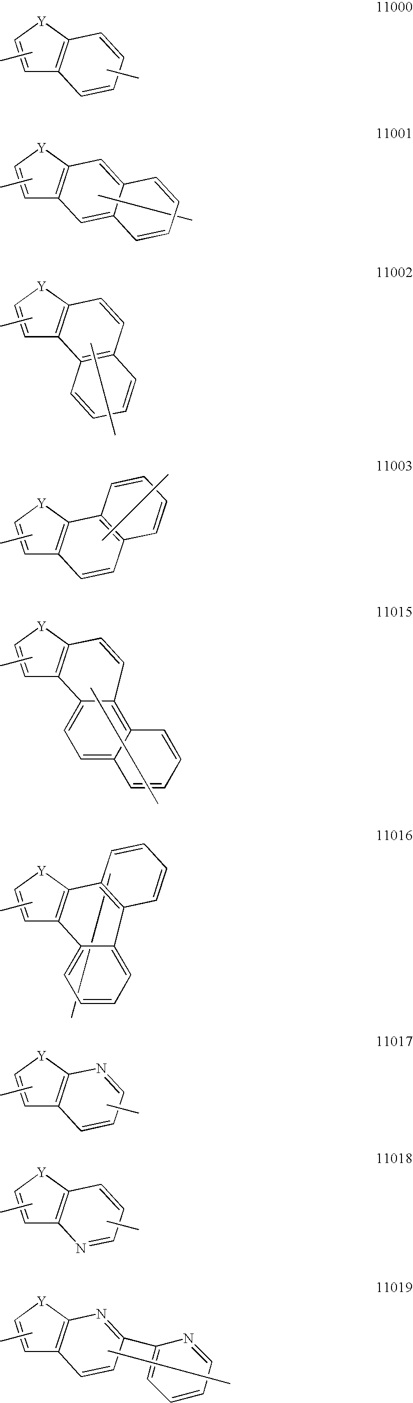

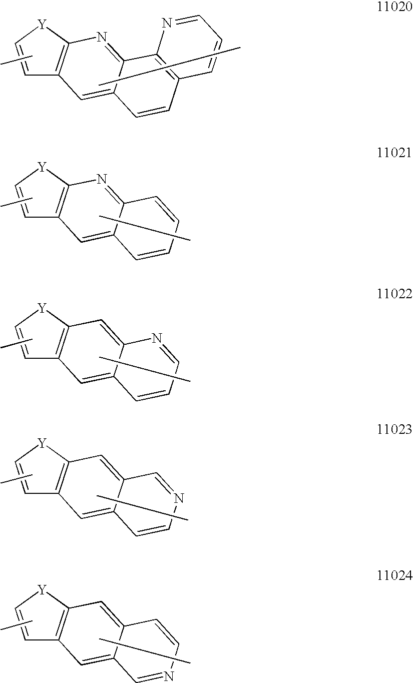

As specific examples of the formula (A-1-2), examples as shown below are listed as unsubstituted groups.

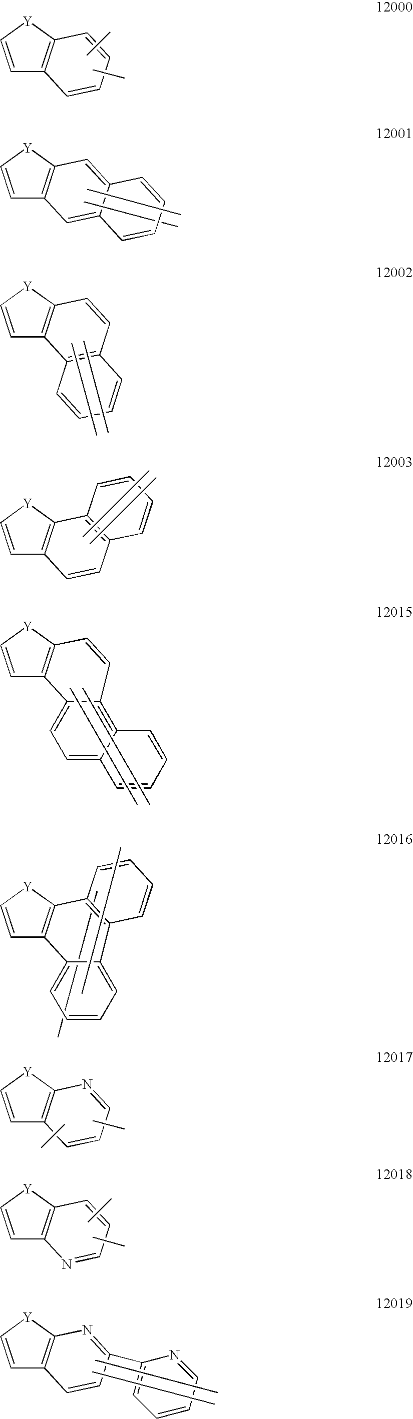

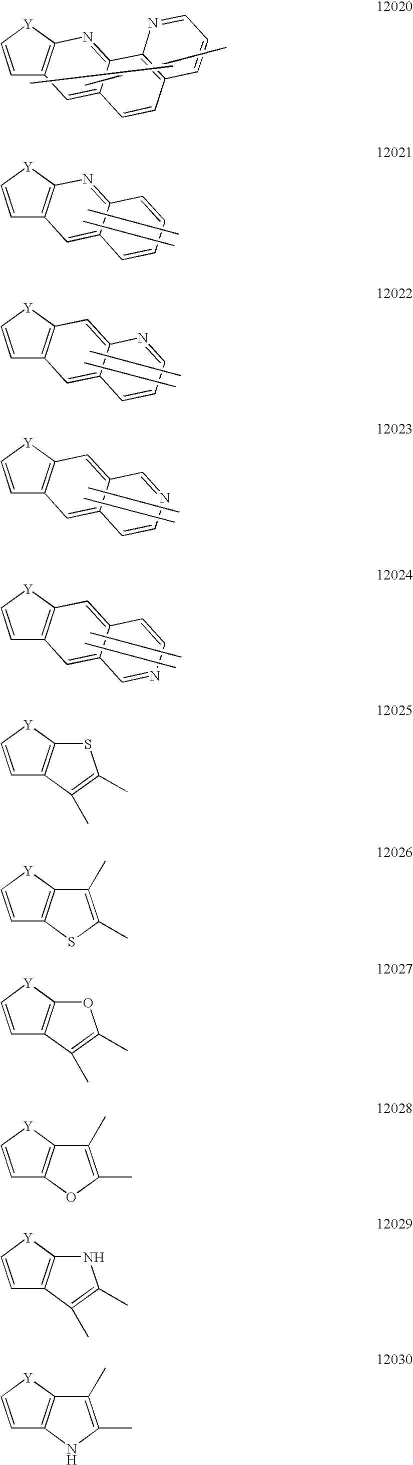

As specific examples of the formula (A-1-3), examples as shown below are listed as unsubstituted groups.

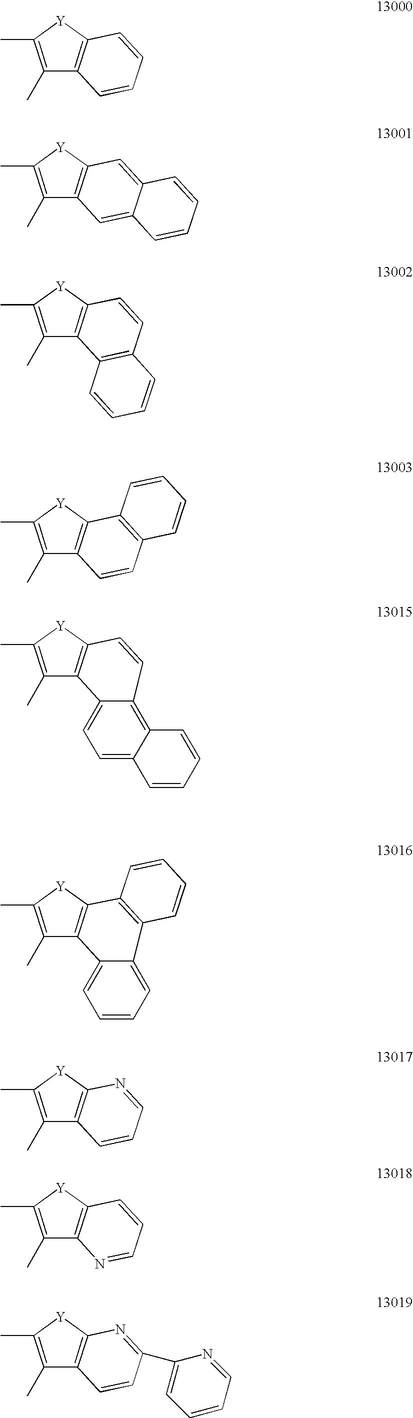

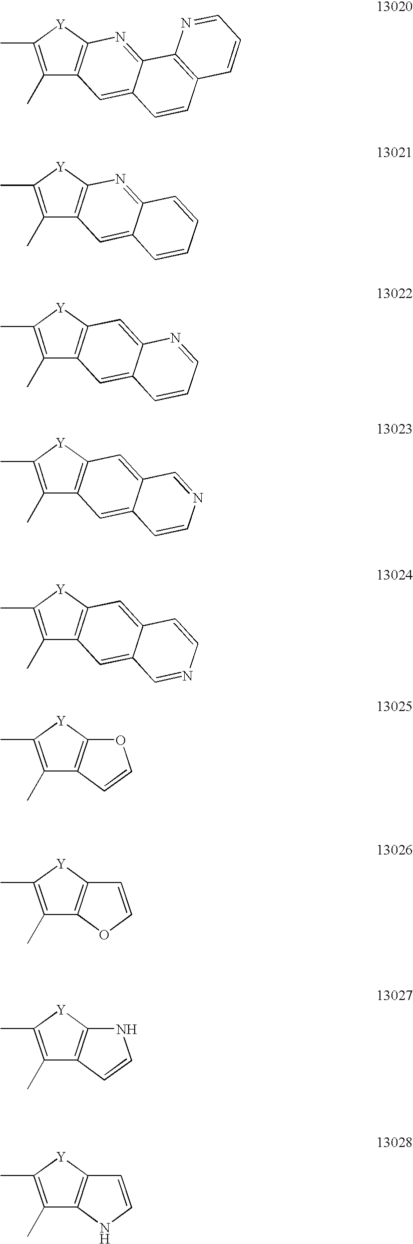

As specific examples of the formula (A-1-4), examples as shown below are listed as unsubstituted groups.

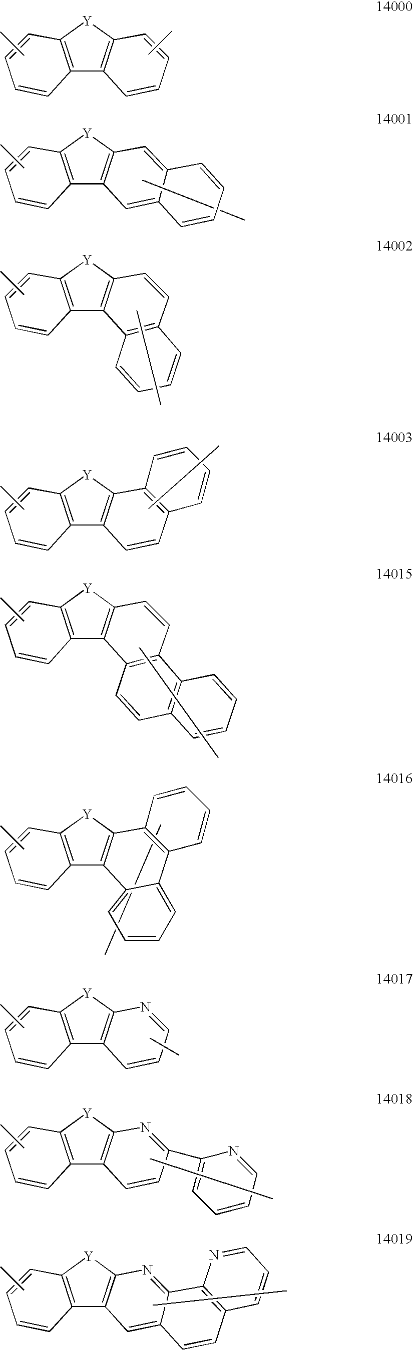

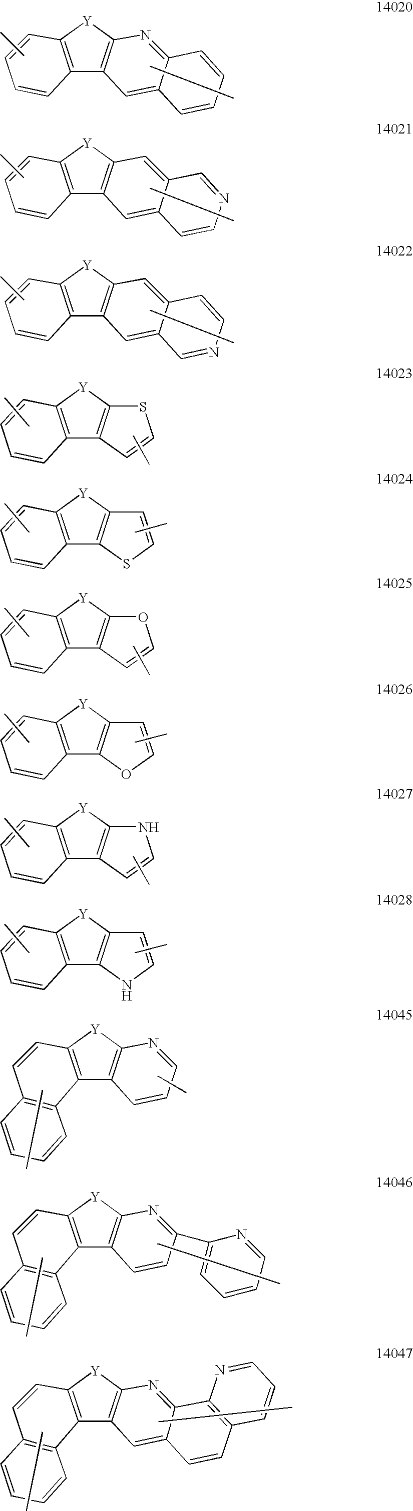

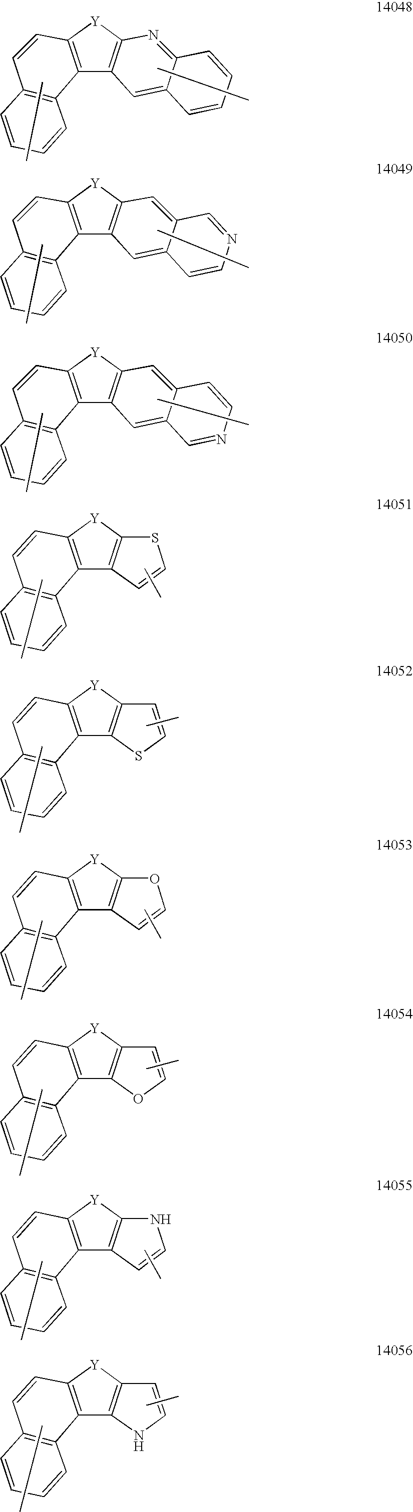

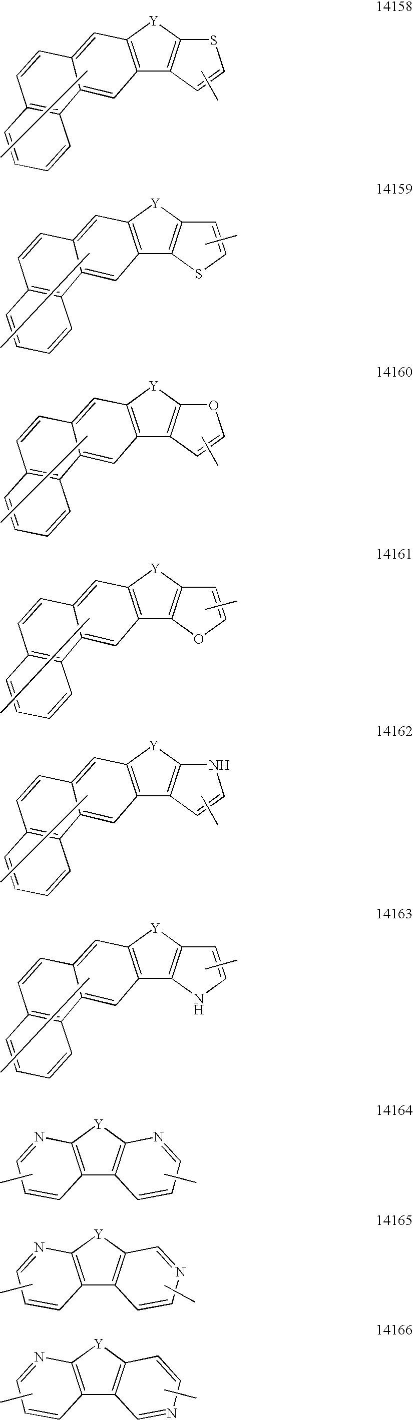

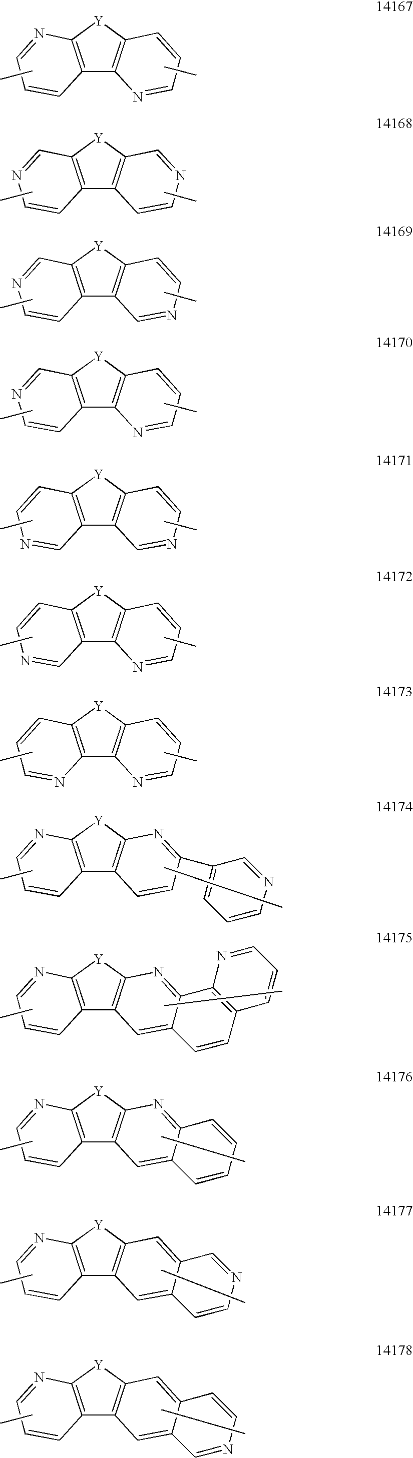

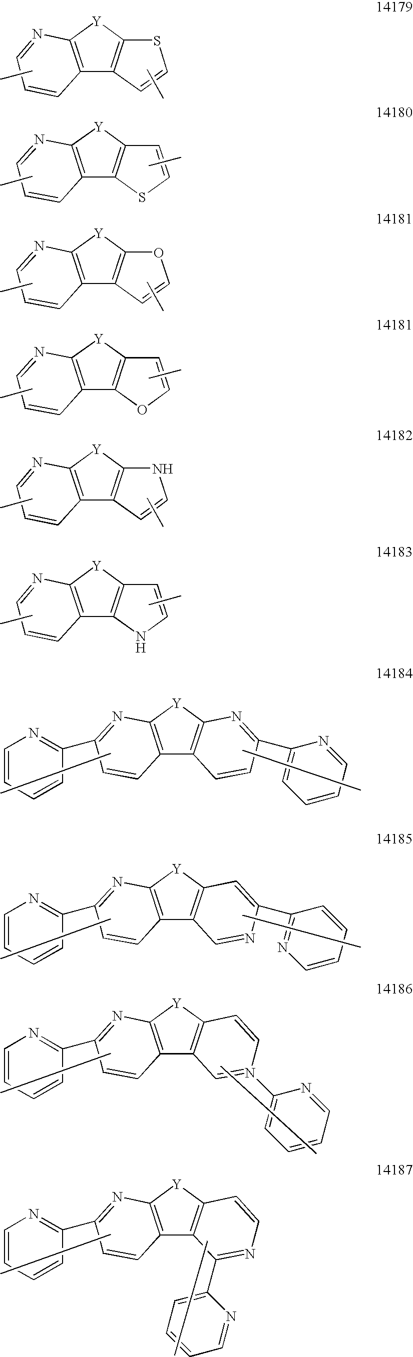

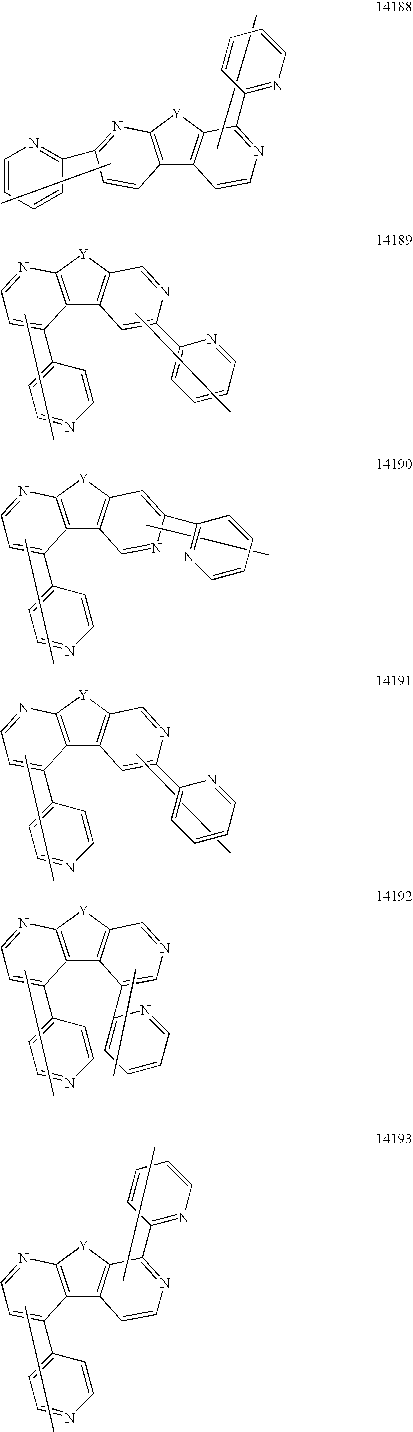

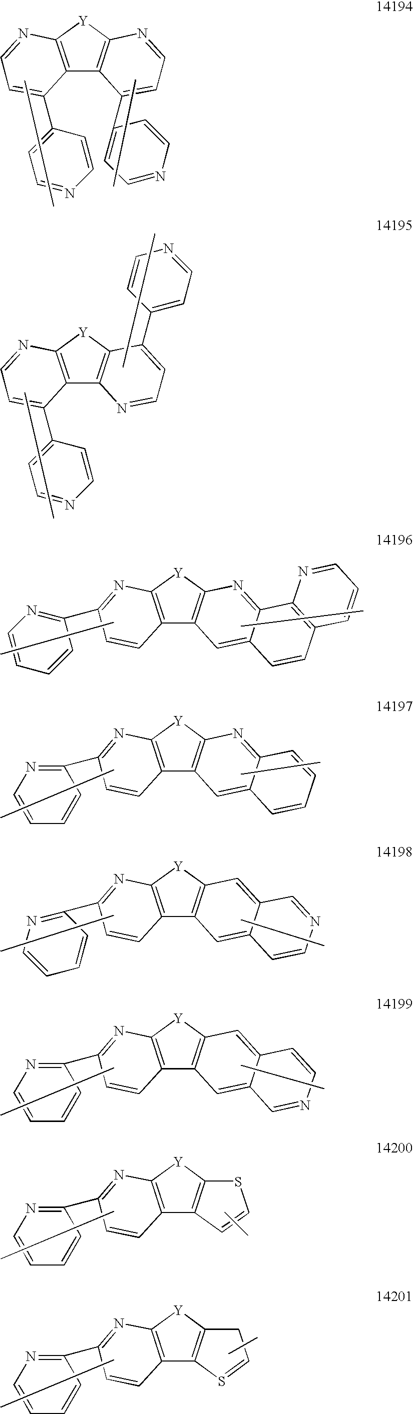

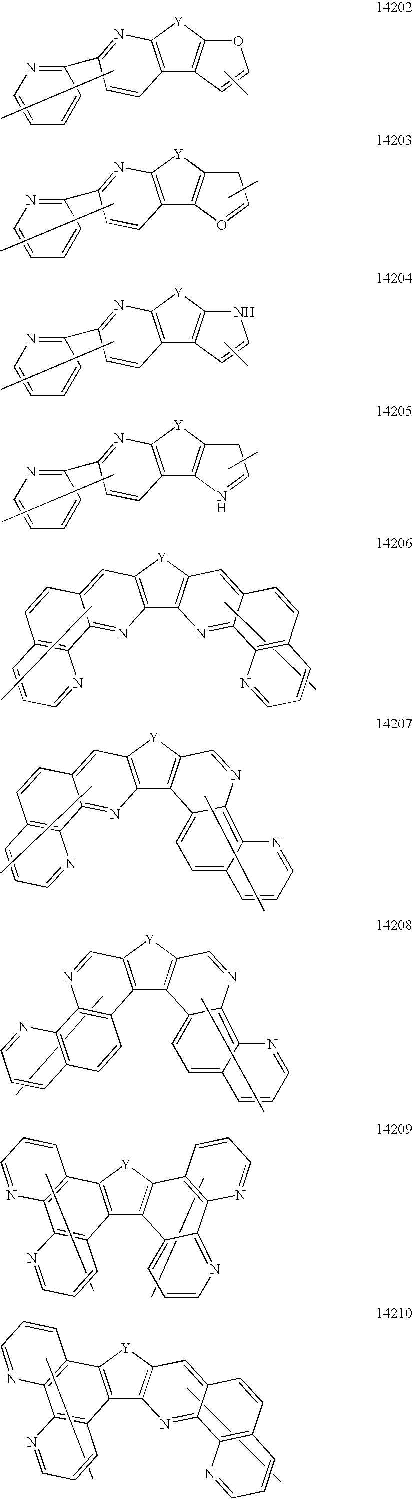

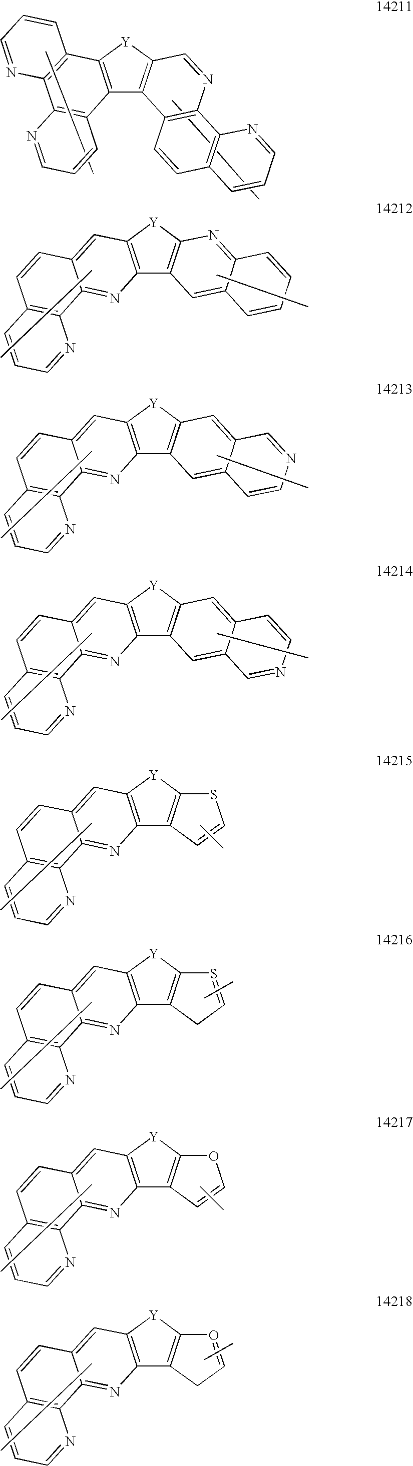

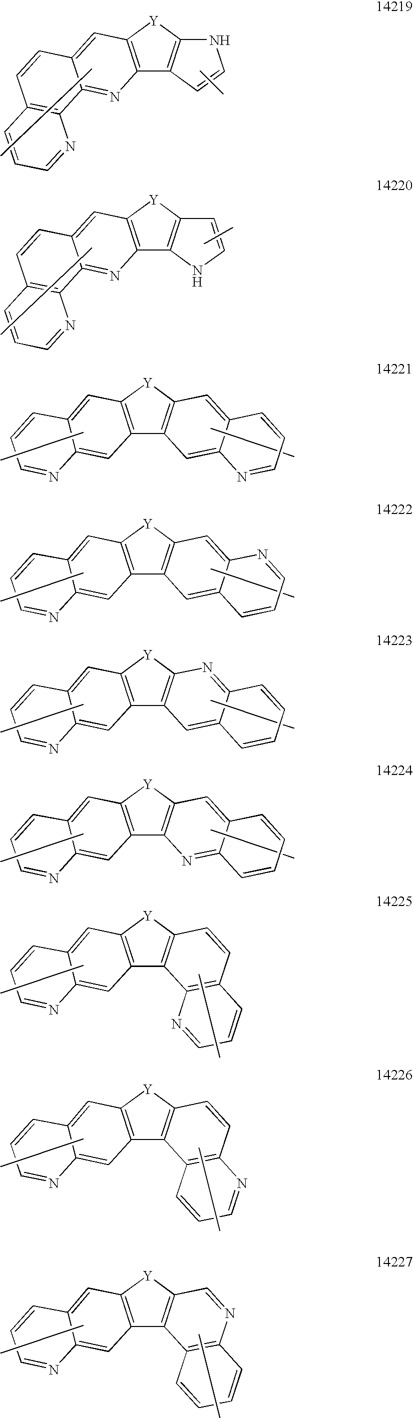

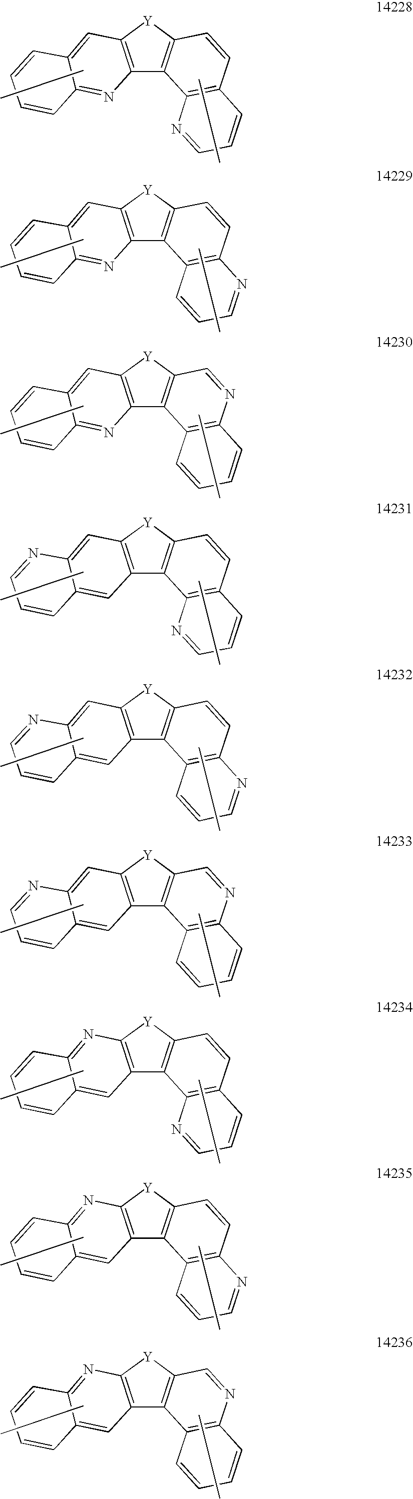

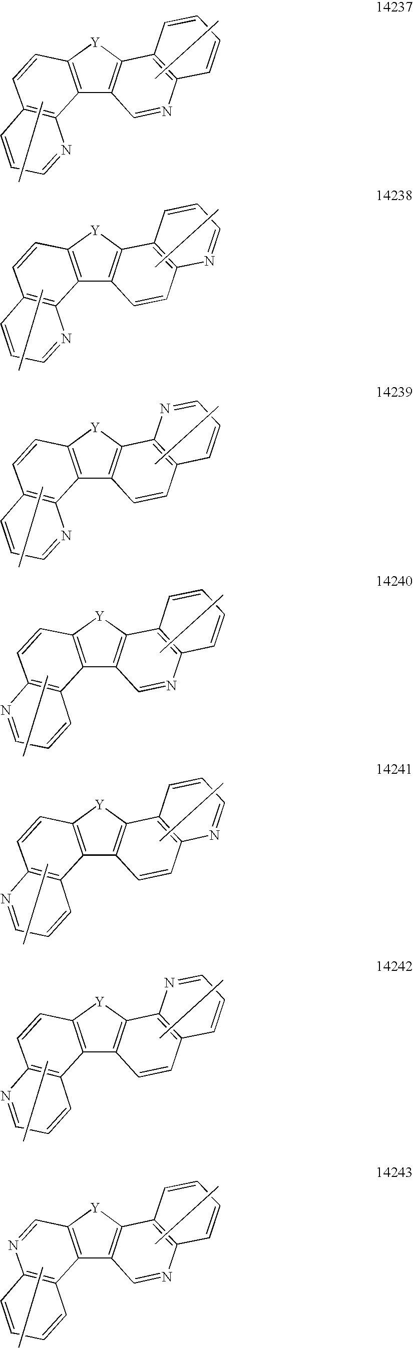

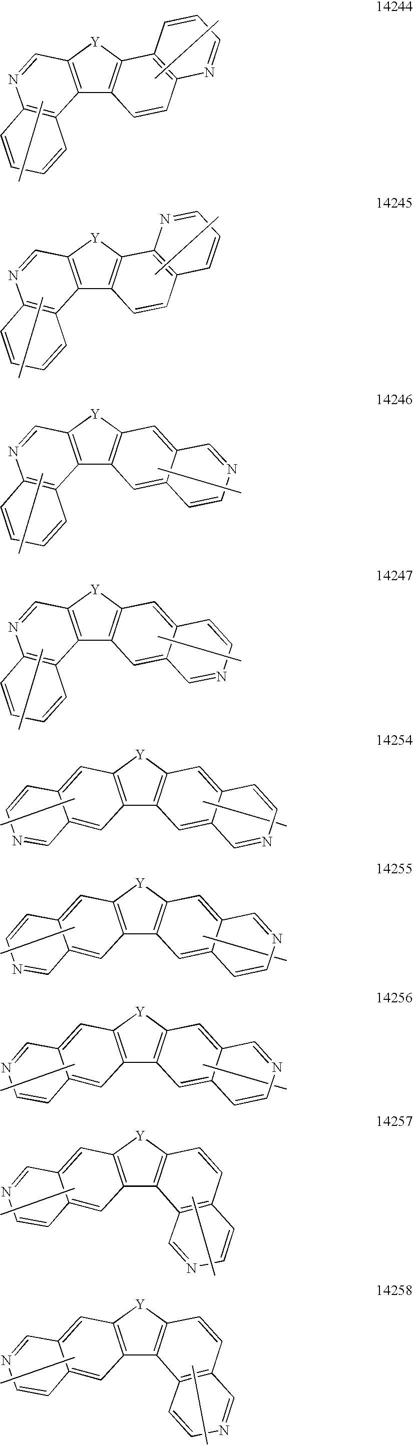

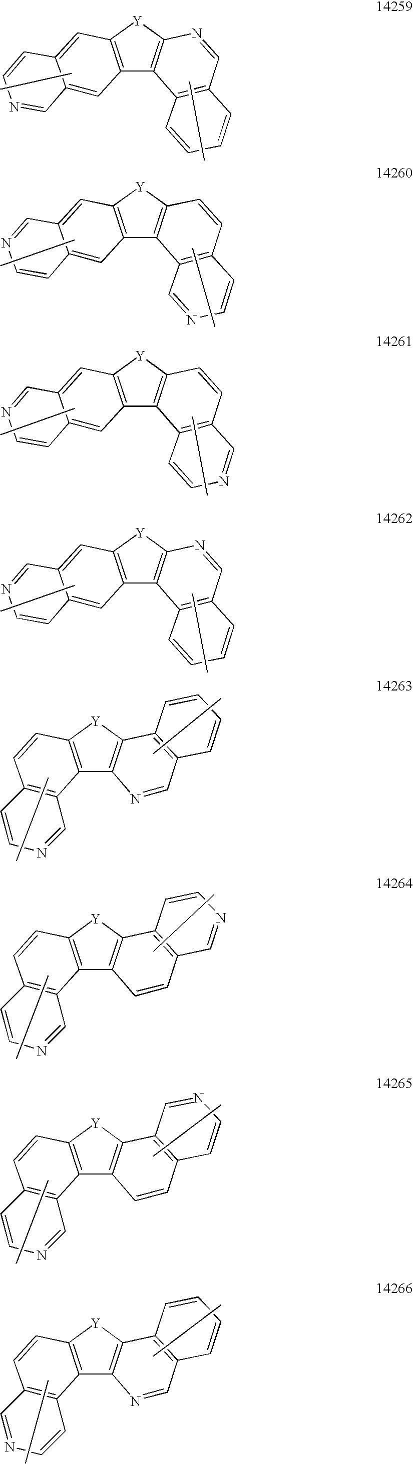

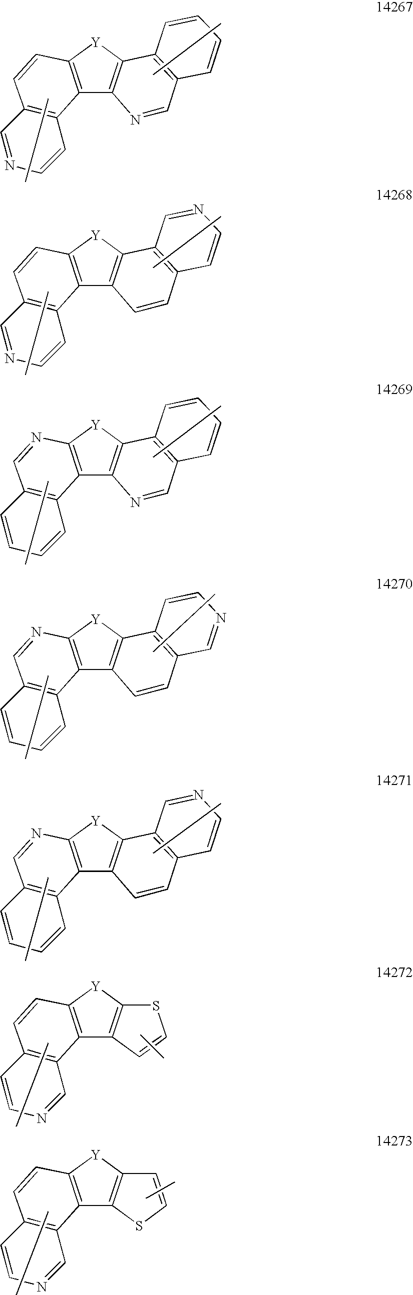

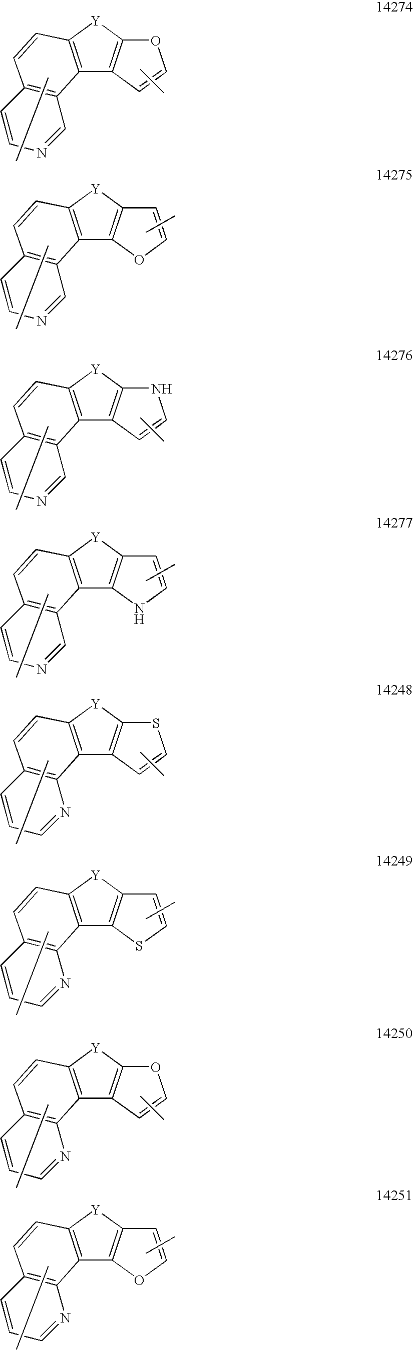

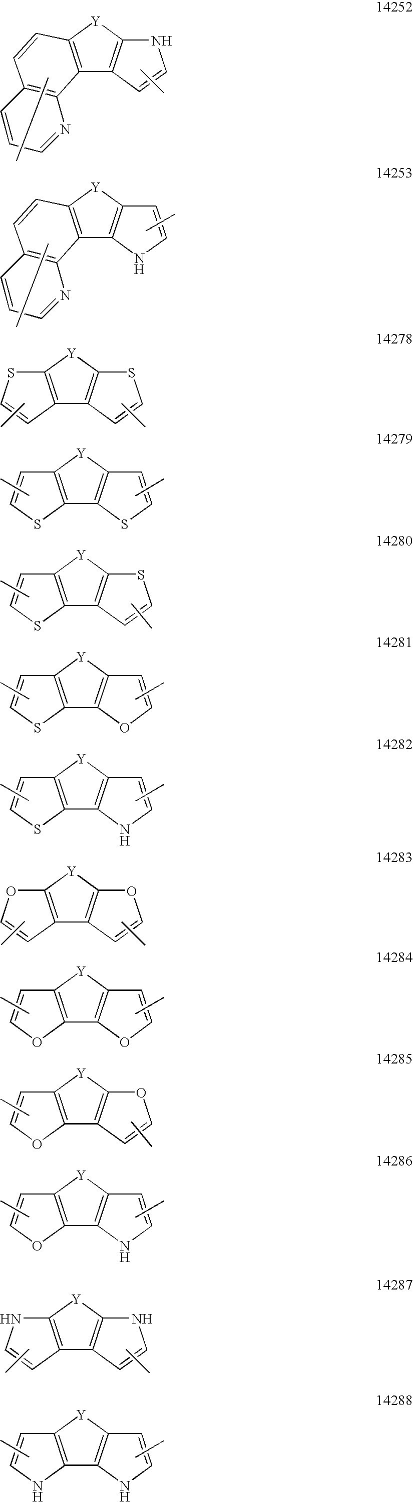

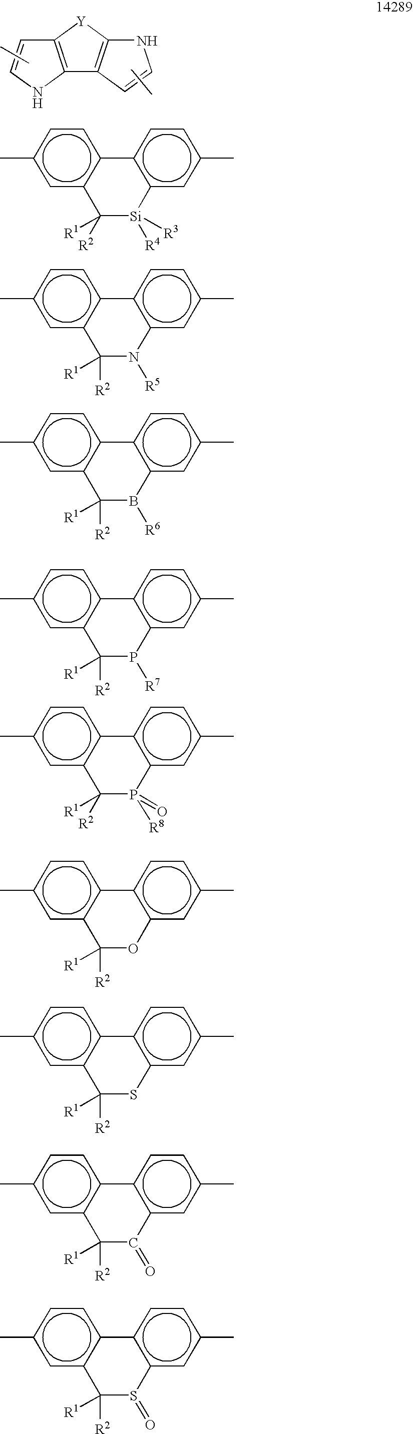

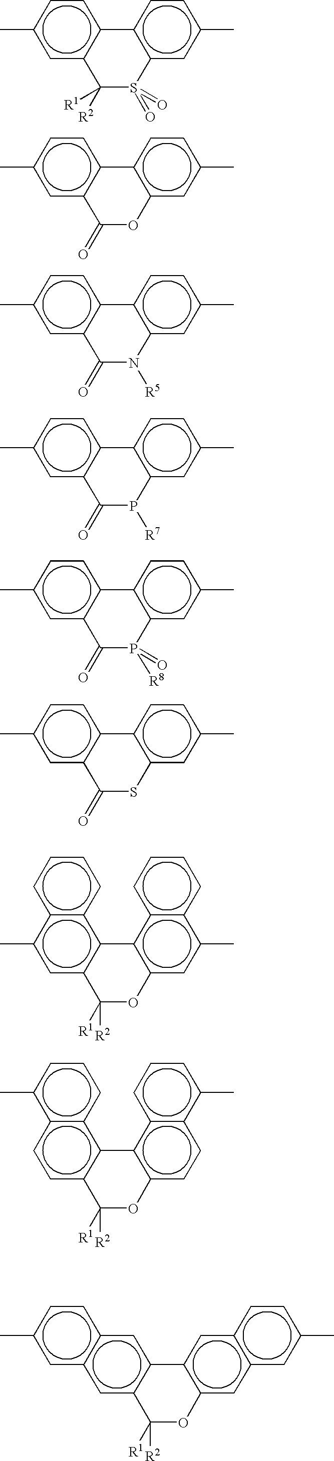

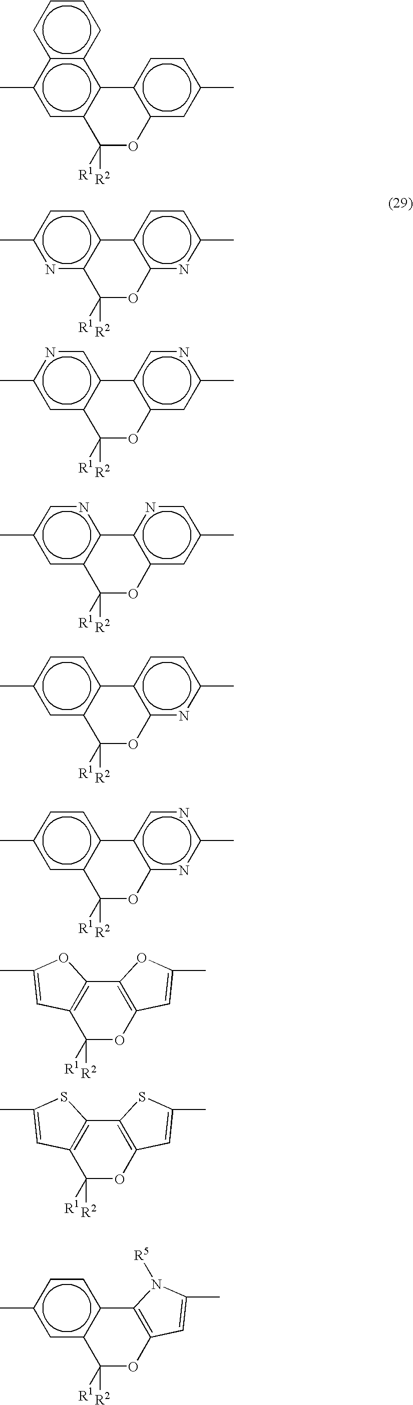

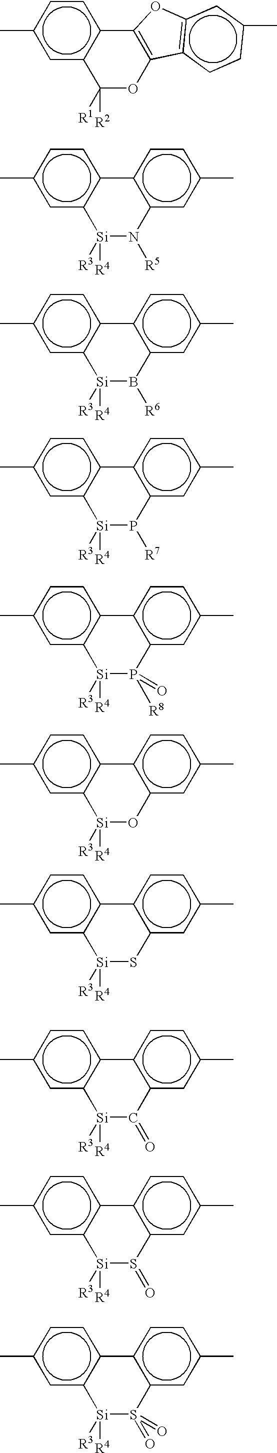

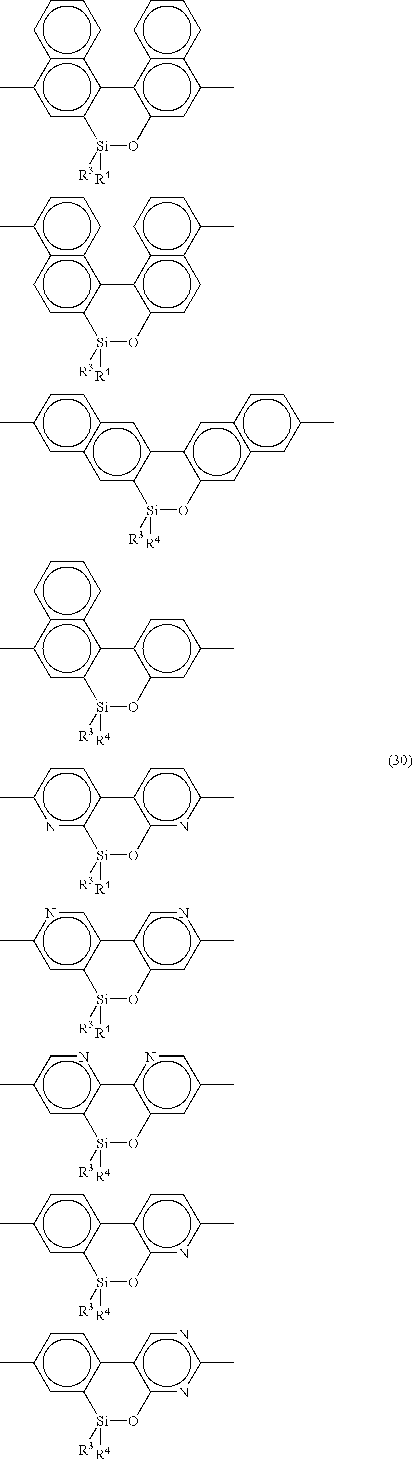

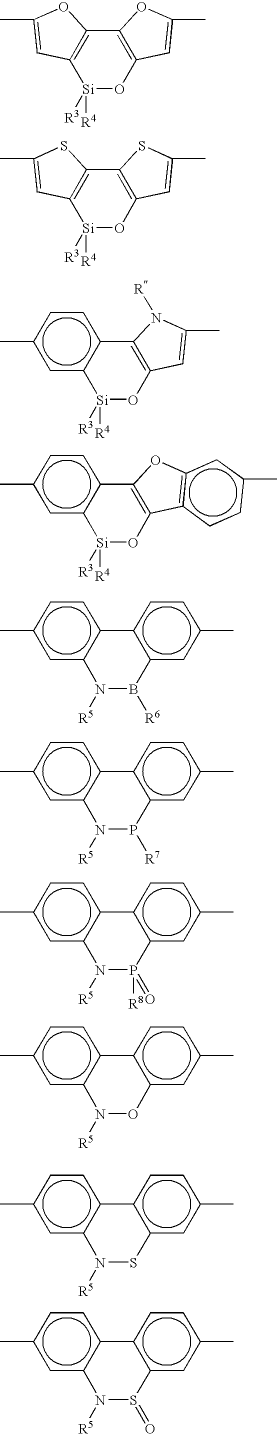

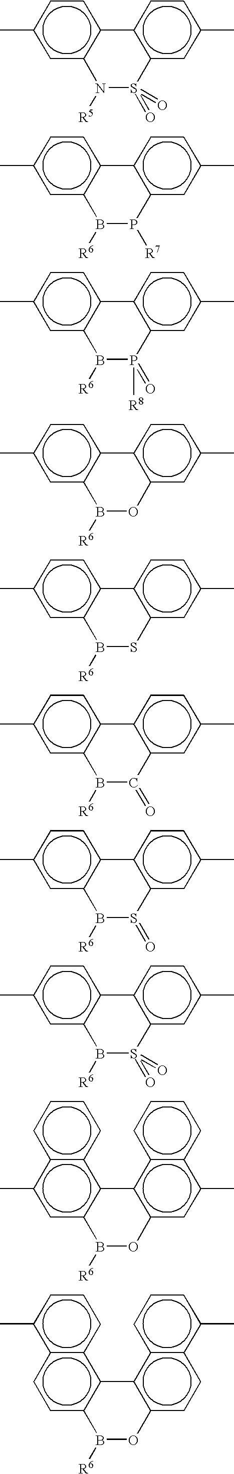

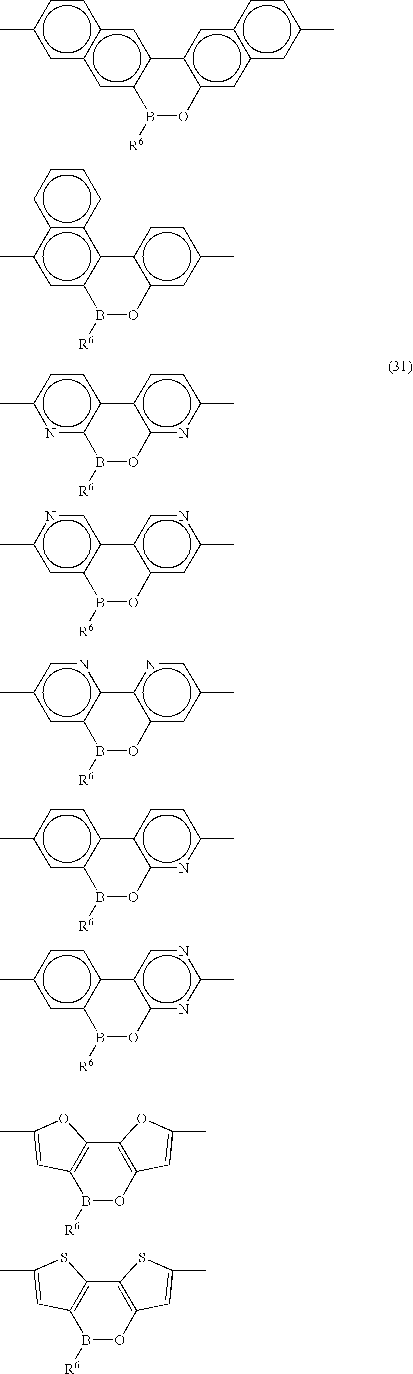

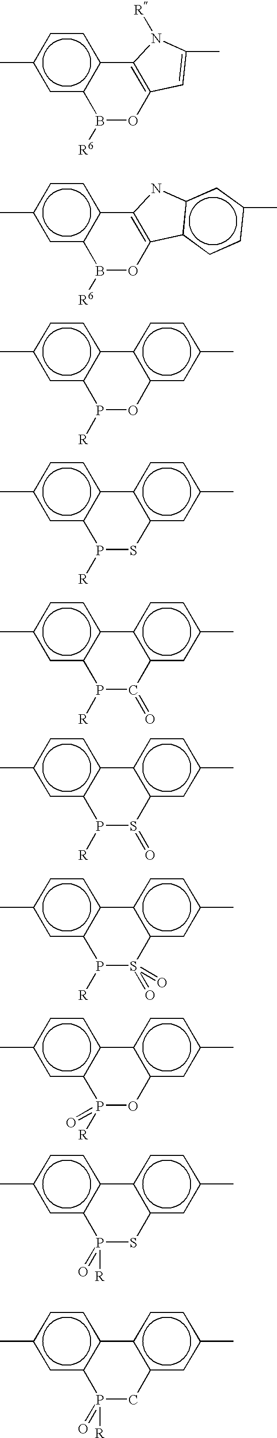

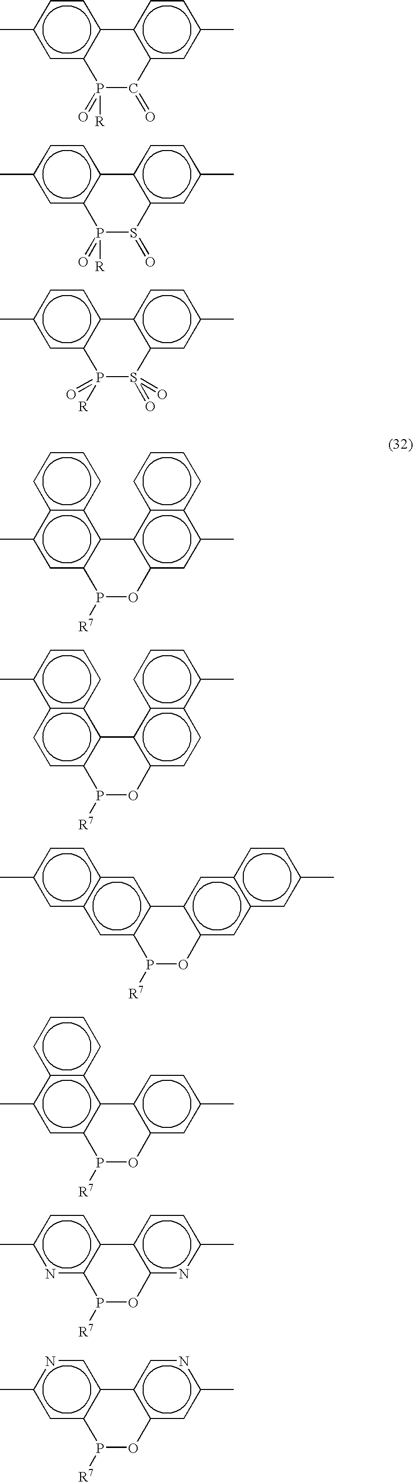

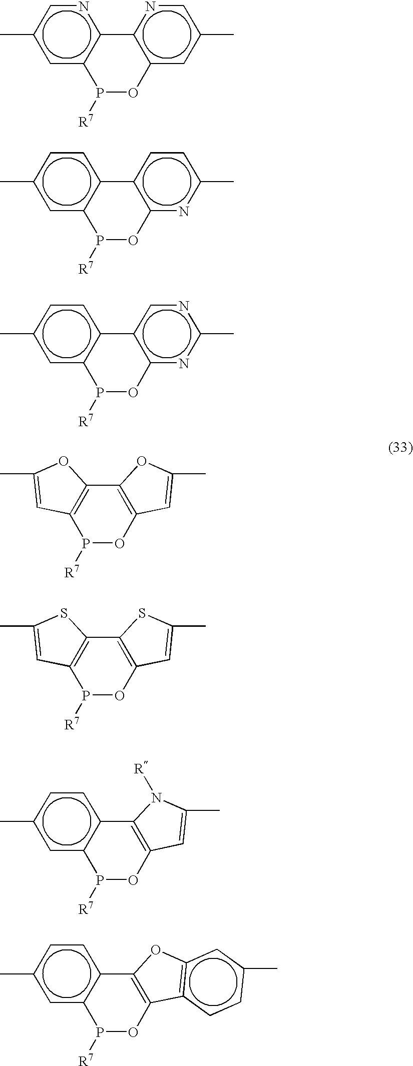

R¹ to R⁸ in the formulae (29) to (33) represent each independently a hydrogen atom, halogen atom, alkyl group, alkyloxy group, alkylthio group, aryl group, aryloxy group, arylthio group, arylalkyl group, arylalkyloxy group, arylalkylthio group, acyl group, acyloxy group, amide group, acid imide group, imine residue, amino group, substituted amino group, substituted silyl group, substituted silyloxy group, substituted silylthio group, substituted silylamino group, monovalent heterocyclic group, heteroaryloxy group, heteroarylthio group, arylalkenyl group, arylalkynyl group, carboxyl group or cyano group, and R¹ and R², and, R³ and R⁴ may each be mutually connected to form a ring.

Among specific examples of the formula (A-1-5), examples as shown below are listed as unsubstituted groups.

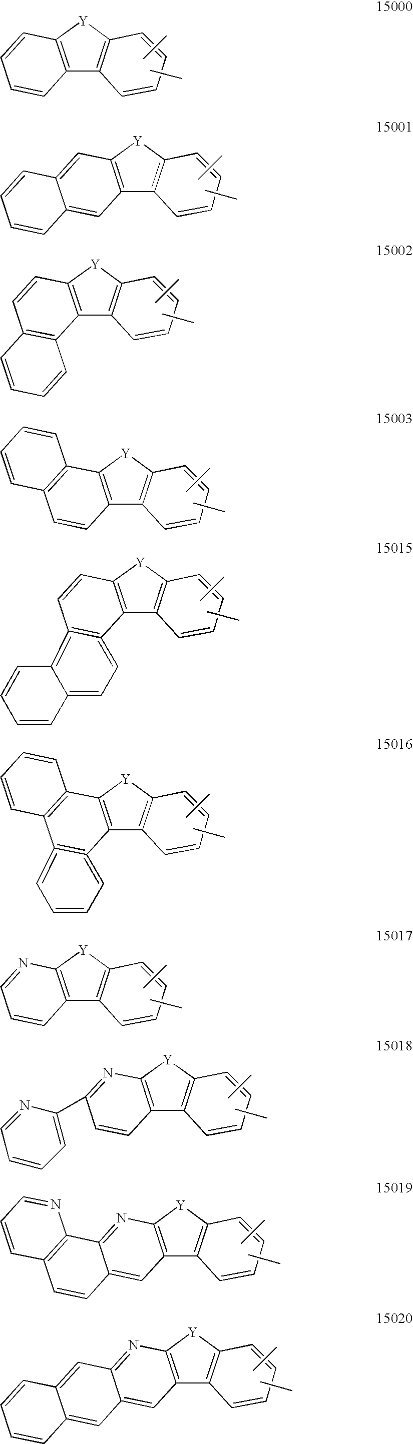

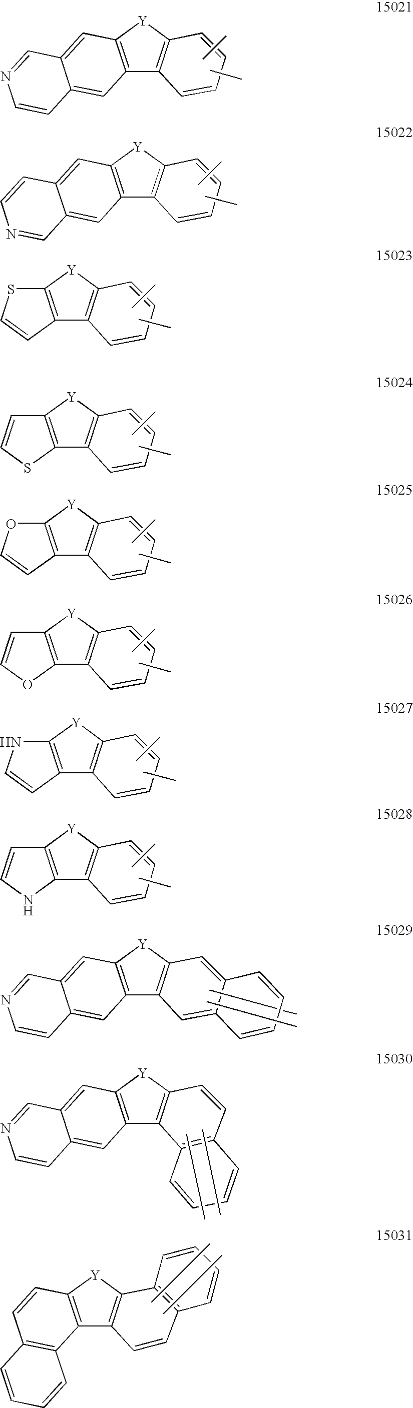

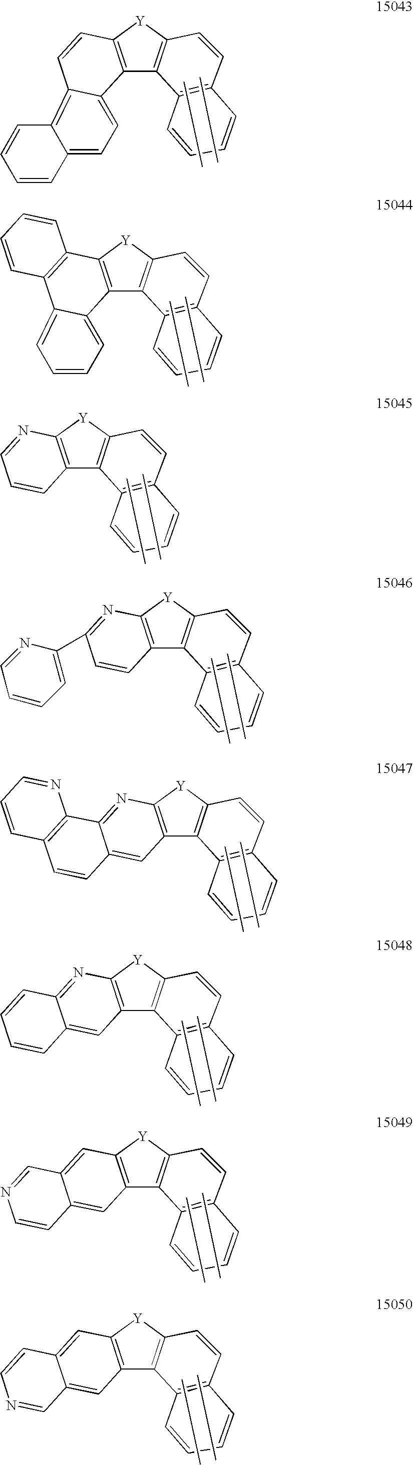

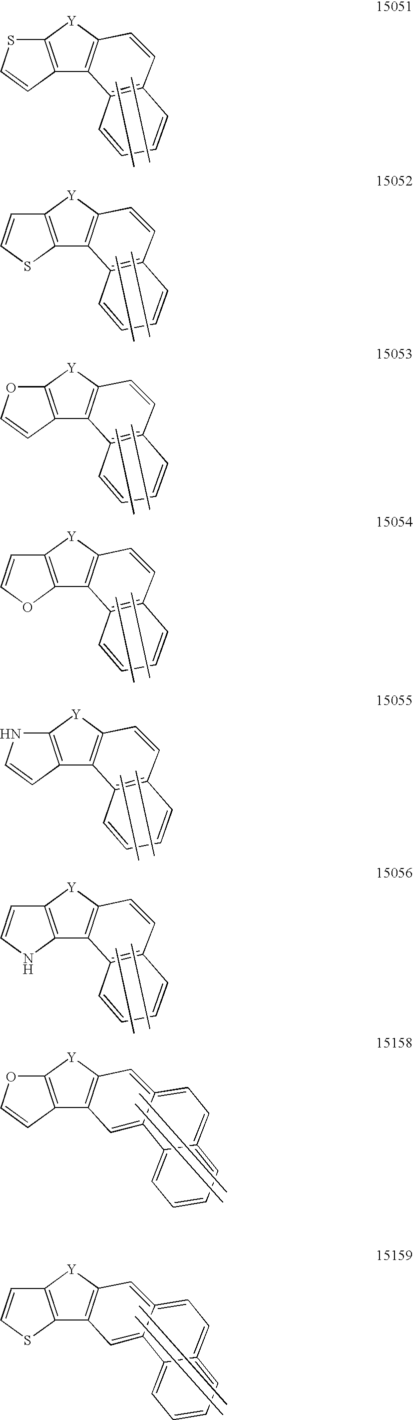

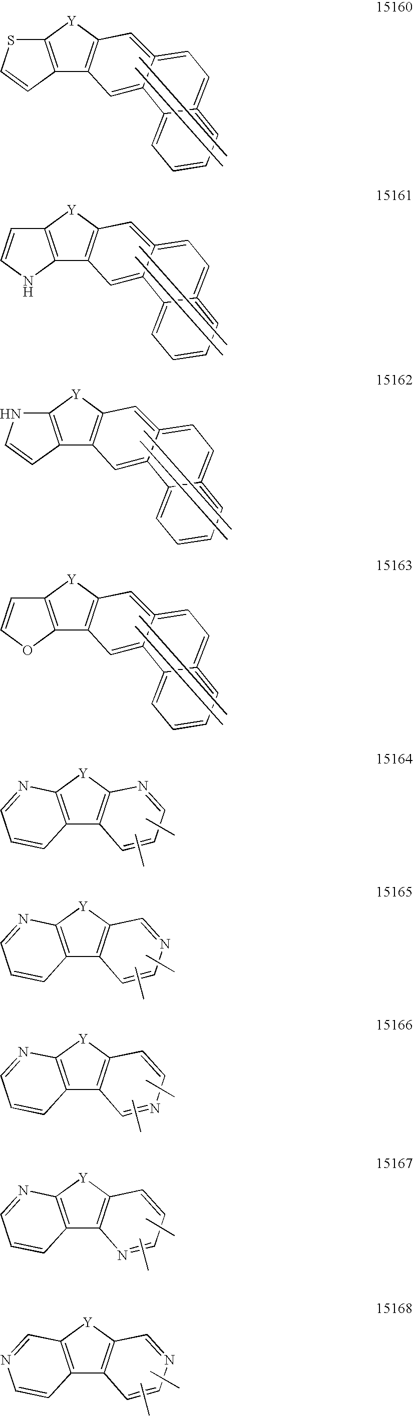

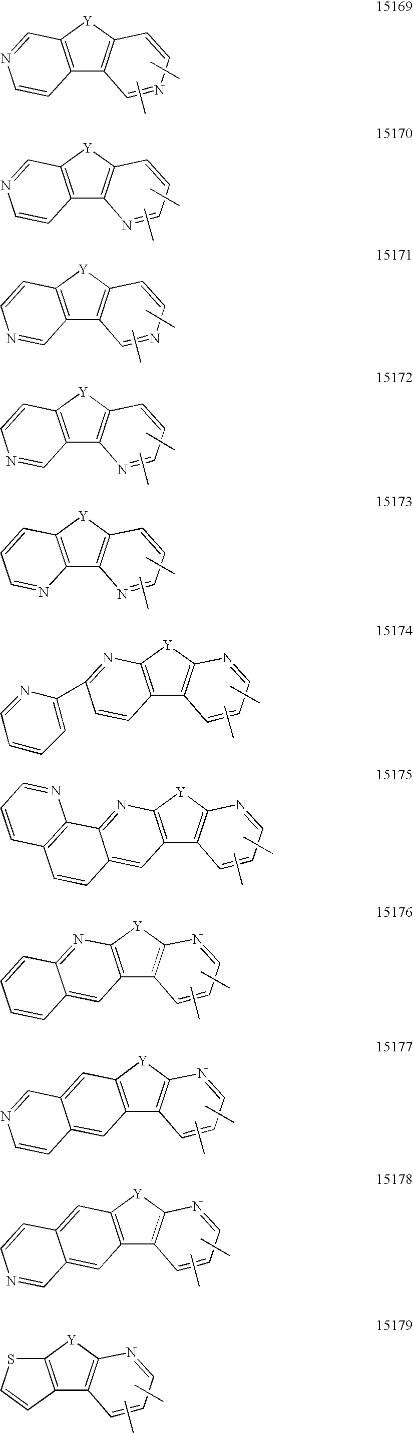

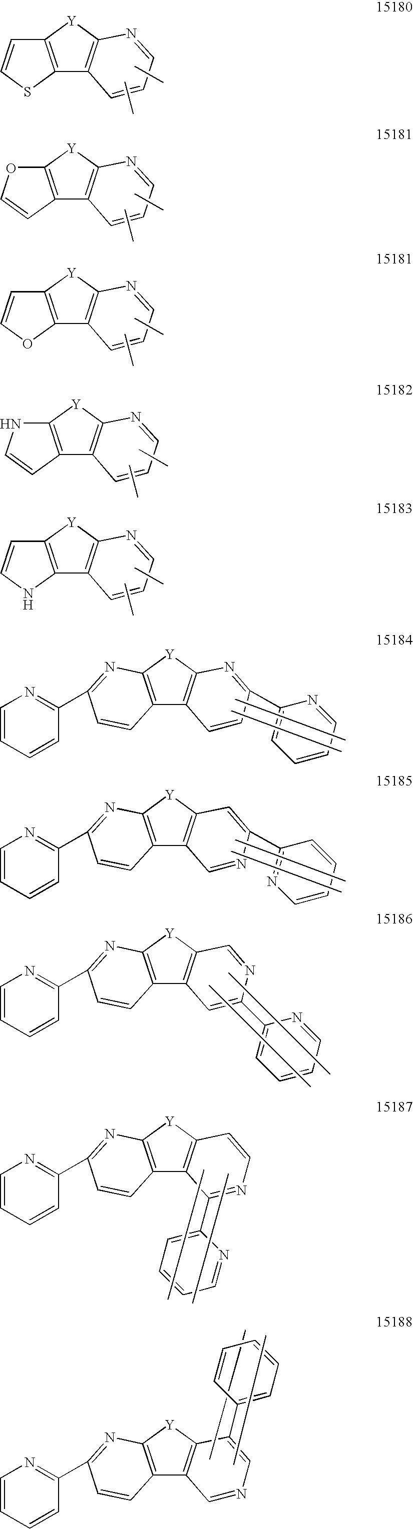

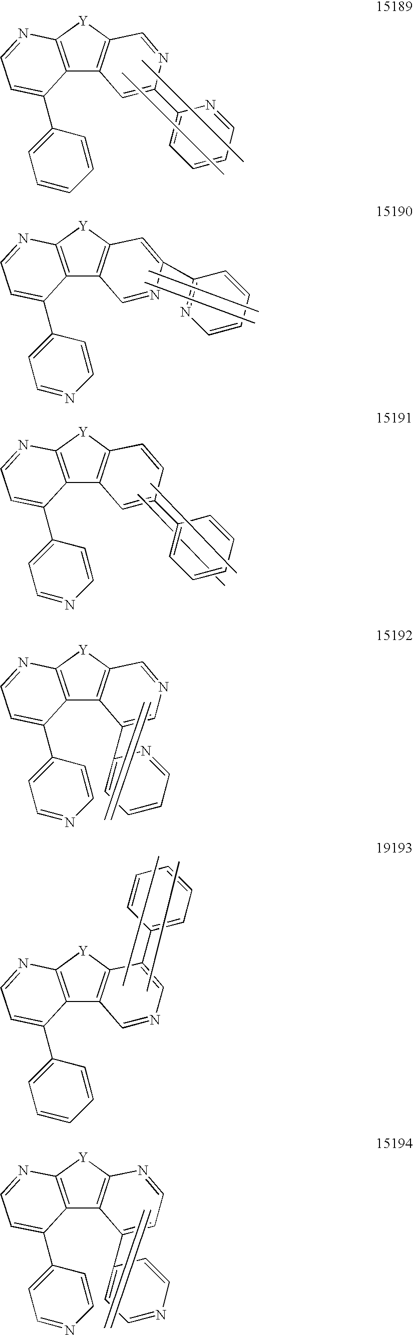

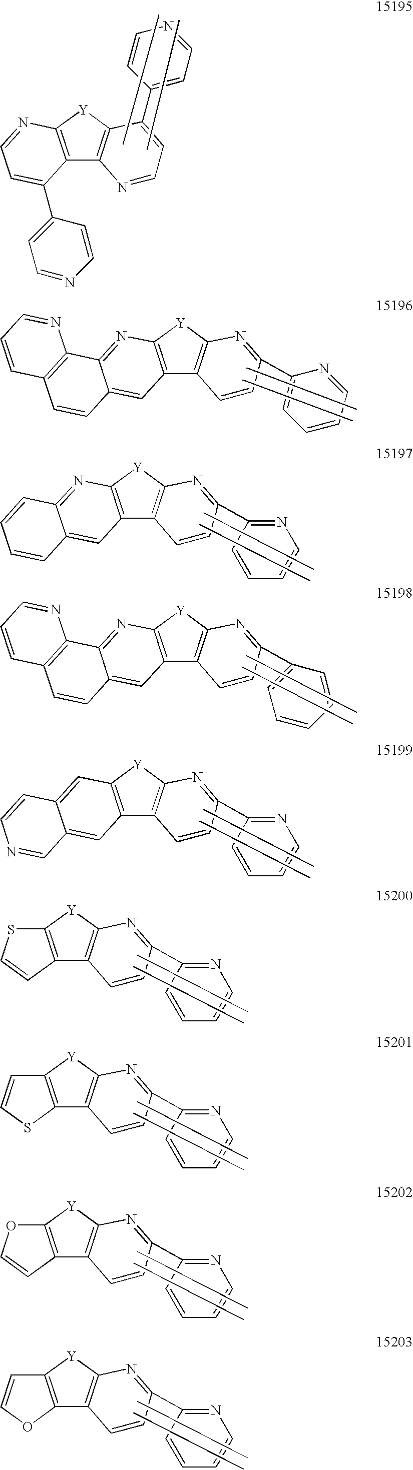

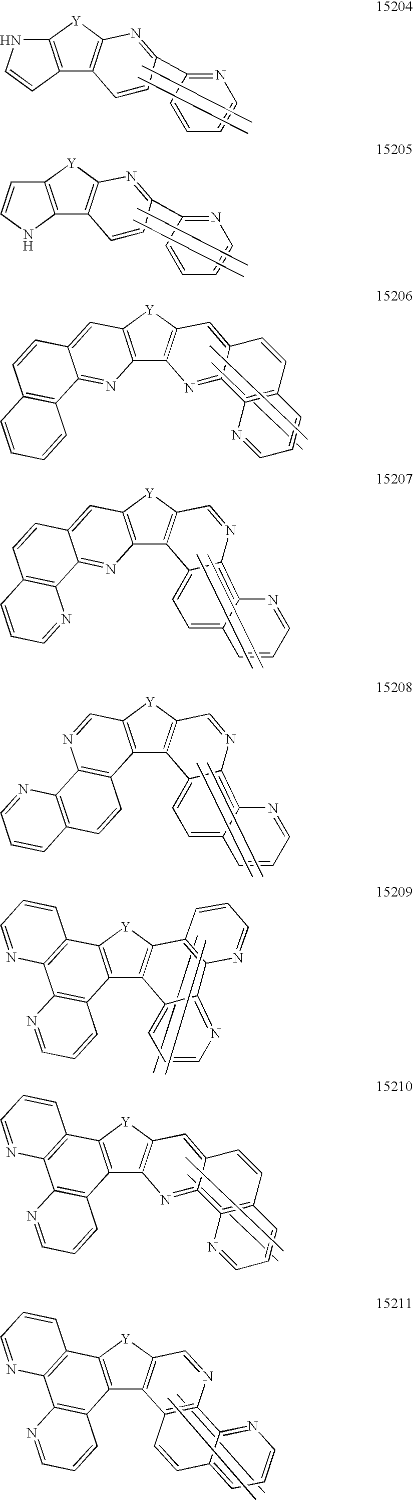

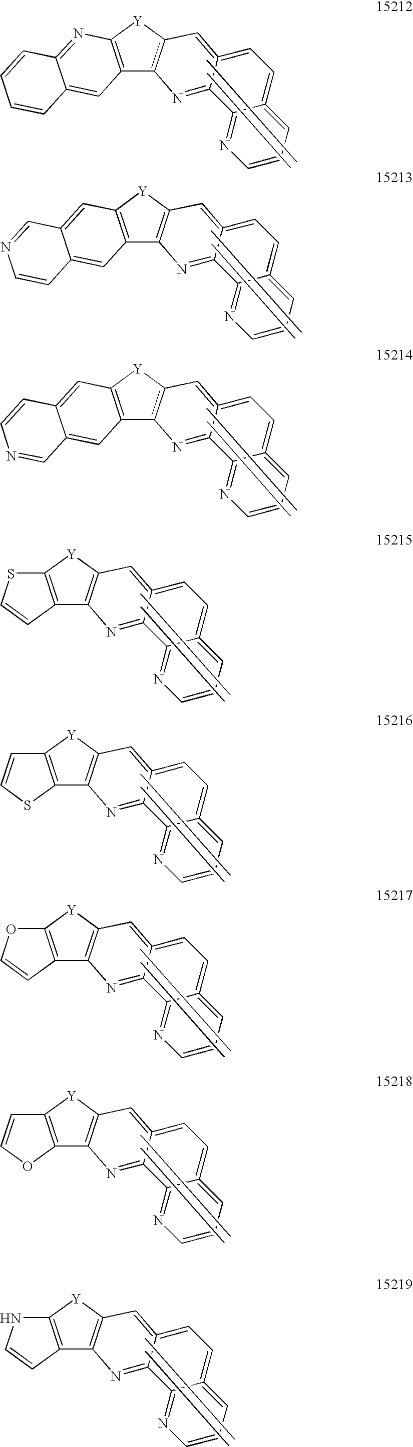

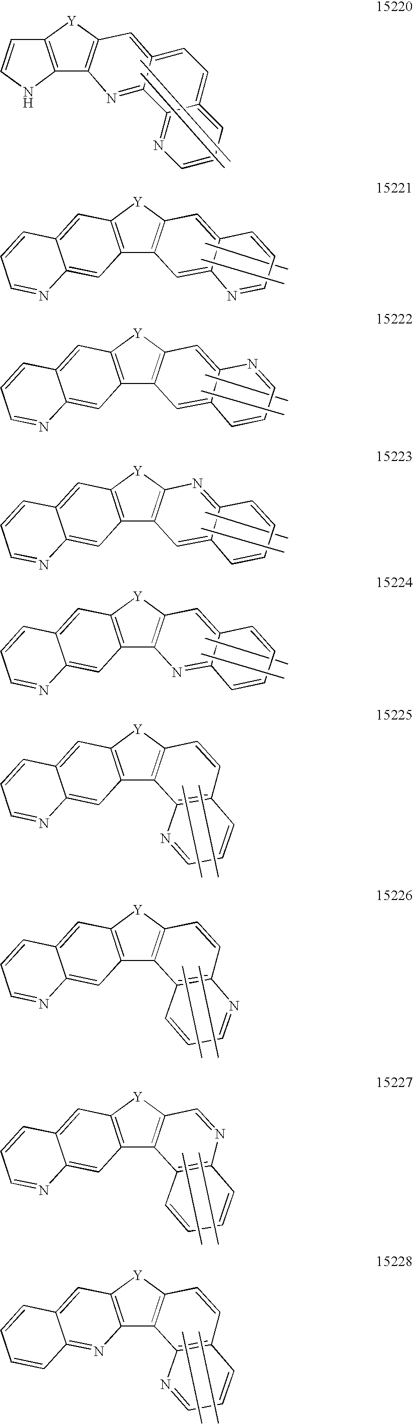

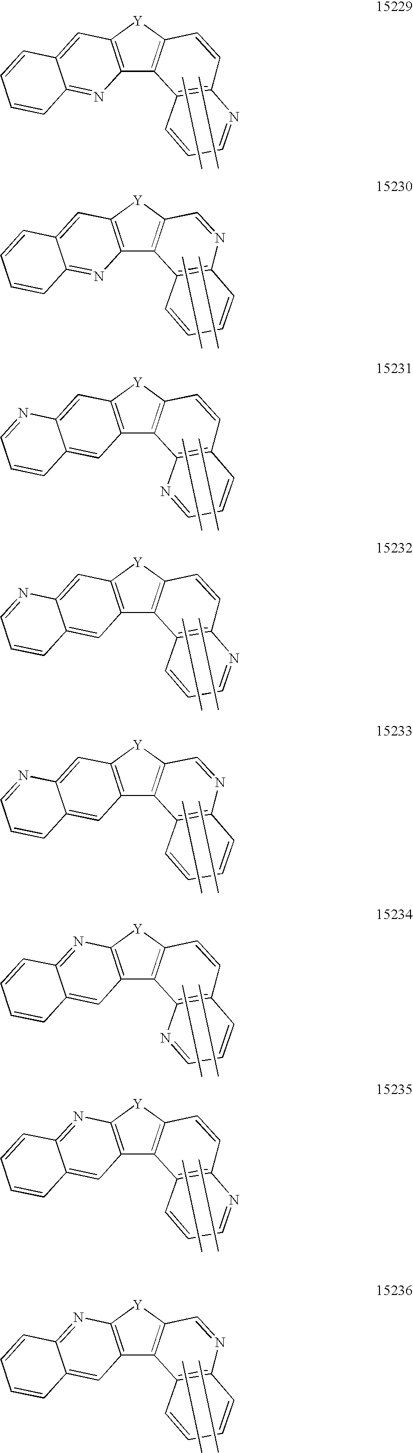

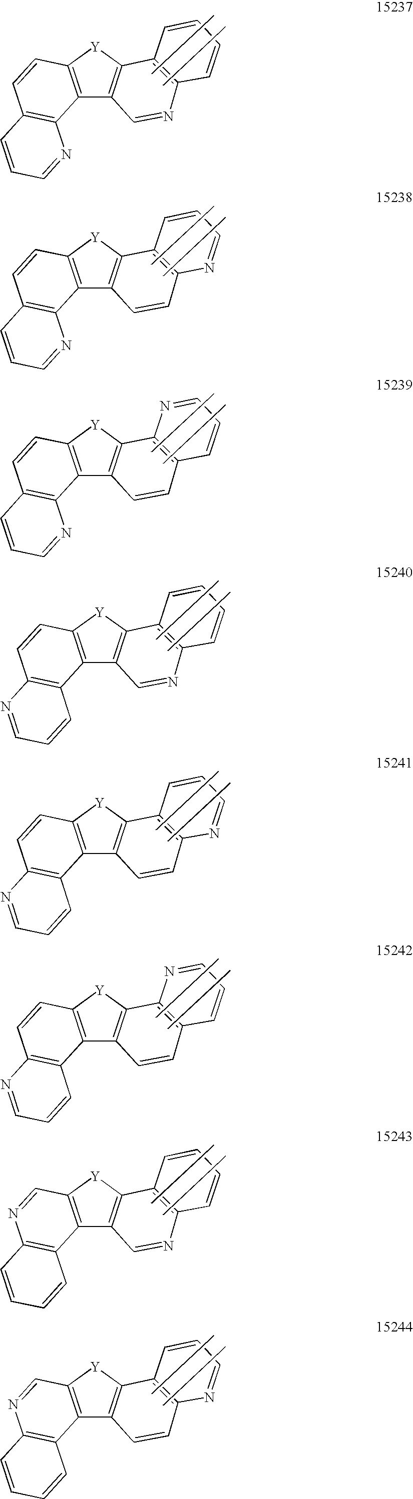

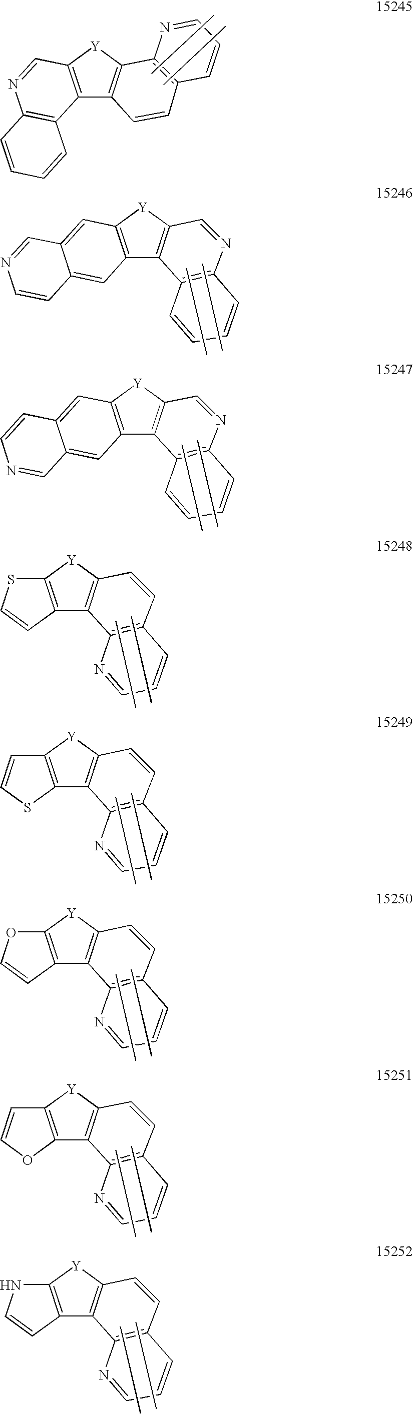

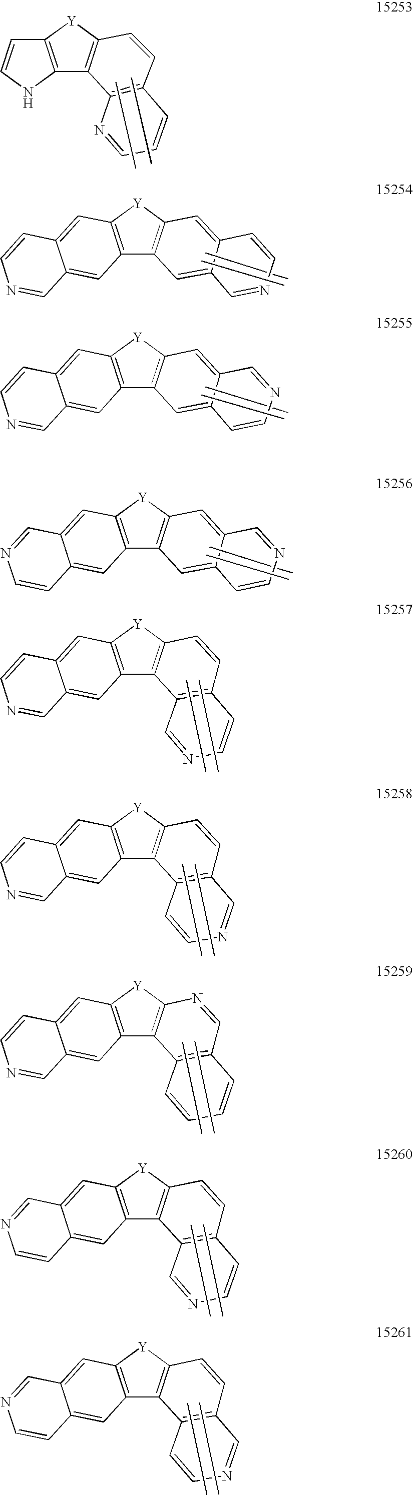

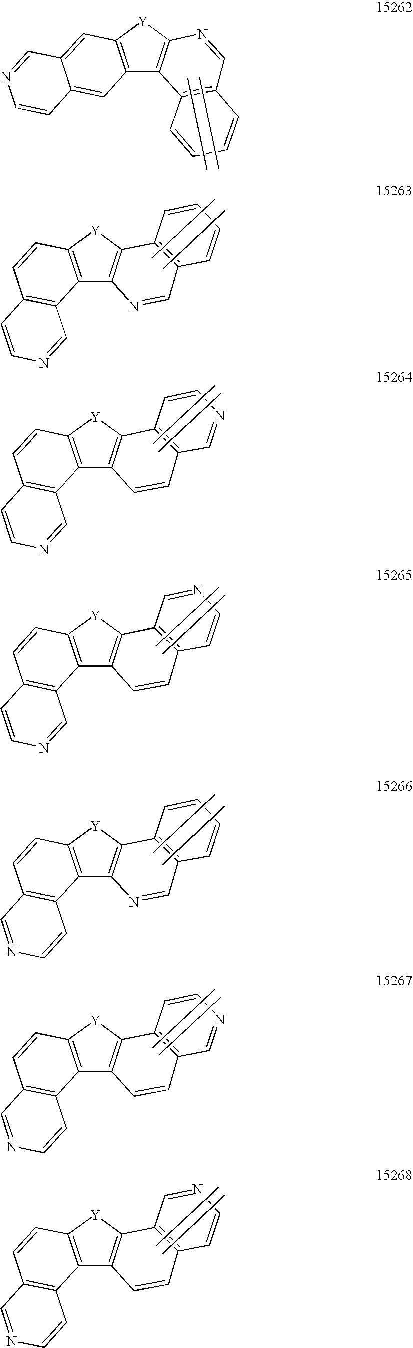

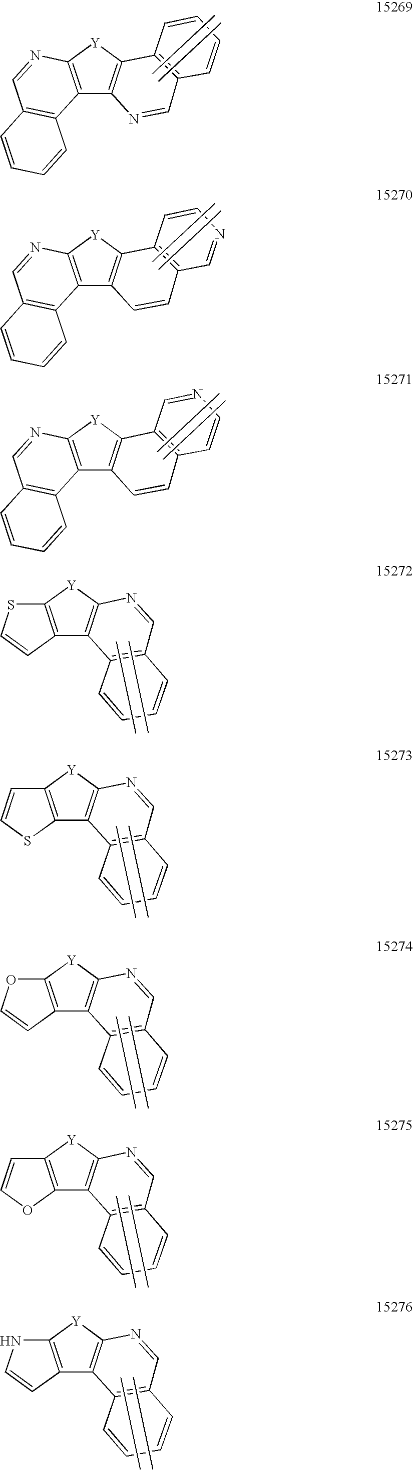

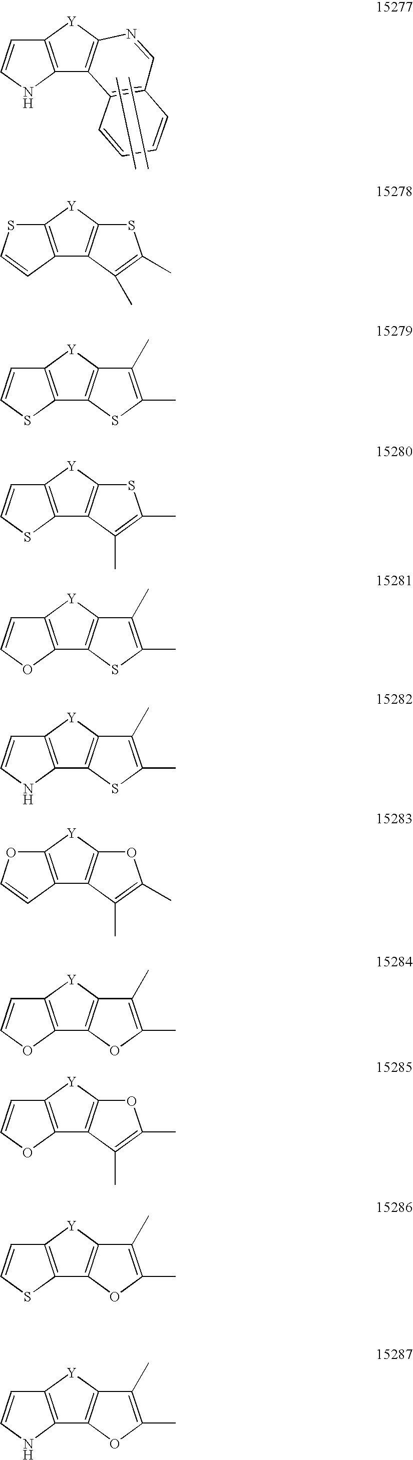

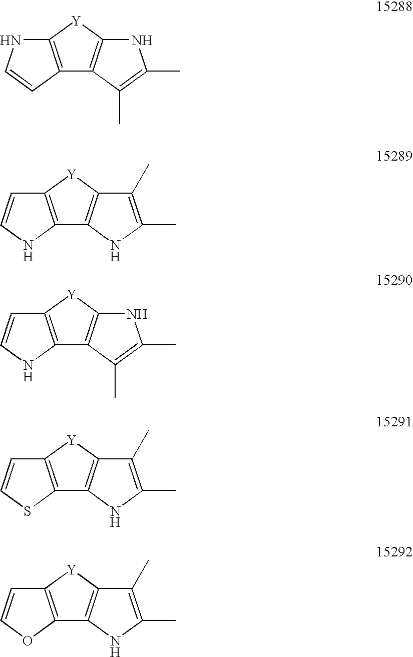

Among the above-mentioned specific examples, groups having further a substituent on those aromatic hydrocarbon groups or hetero rings are preferable from the standpoint of improvement in solubility. Exemplified as the substituent are halogen atoms, alkyl groups, alkyloxy groups, alkylthio groups, aryl groups, aryloxy groups, arylthio groups, arylalkyl groups, arylalkyloxy groups, arylalkylthio groups, acyl group, acyloxy group, amide group, acid imide group, imine residue, amino group, substituted amino groups, substituted silyl groups, substituted silyloxy groups, substituted silylthio groups, substituted silylamino groups, monovalent heterocyclic groups, heteroaryloxy groups, heteroarylthio groups, arylalkenyl groups, arylethynyl groups, carboxyl group or cyano group, and they may be mutually connected to form a ring.

From the standpoint of light emission efficiency, (A-1-4) and (A-1-5) are preferable in the above-mentioned formula (A-1), and (A-1-4) is more preferable, and among others, structures of the following formula (A-1-4-1) are further preferable.

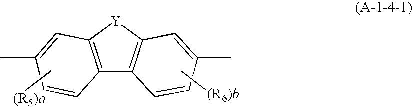

(wherein, R₅ and R₆ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, acyloxy group, imine residue, amide group, acid imide group, monovalent heterocyclic group, carboxyl group, substituted carboxyl group or halogen atom. a and b represent each independently an integer of to 3. When there are a plurality of R₅s and R₆s respectively, these may be the same or different. Y represents the same meaning as described above.).

From the standpoint of synthesis, Y is preferably —S—, —O— or —C(R₁)(R₂)—, and further preferably —S— or —O—, in the formula (A-1-4-1).

From the standpoint of solubility in a solvent, a+b is preferably 1 or more.

From the standpoint of synthesis, it is preferable that P ring, Q ring, A ring, B ring, C ring, D ring, E ring, F ring and G ring in the above-mentioned formulae (A-1), (A-1-1) to (A-1-5) represent an aromatic hydrocarbon ring.

The polymeric compound of the present invention may further contain the repeating unit of the below formula (2), (3), (4), or (5).

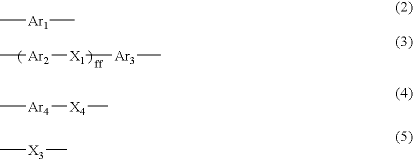

(wherein, Ar₁, Ar₂, Ar₃ and Ar₄ each independently represent an arylene group, divalent heterocyclic group, or divalent group having metal complex structure. X₁, X₂ and X₃ each independently represent —CR₁₅═CR₁₆—, —C≡C—, —N(R₁₇)—, or —(SiR₁₈R₁₉)ₘ—. R₁₅ and R₁₆ each independently represents hydrogen atom, alkyl group, aryl group, monovalent heterocyclic group, carboxyl group, substituted carboxyl group, or cyano group. R₁₇, R₁₈ and R₁₉ each independently represent a hydrogen atom, alkyl group, aryl group, monovalent heterocyclic group, arylalkyl group, or substituted amino group. ff represents 1 or 2. m represents an integer of 1 to 12. R₁₅, R₁₆, R₁₇, R₁₈ and R₁₉ respectively exist in plural, they may be the same or different.)

The arylene group is an atomic group in which two hydrogen atoms of an aromatic hydrocarbon are removed, and usually, the number of carbon atoms is about 6 to 60, and preferably 6 to 20. The aromatic hydrocarbon includes those having a condensed ring, an independent benzene ring, or two or more condensed rings bonded through groups, such as a direct bond or a vinylene group.

Examples of the arylene group include phenylene group (for example, following formulas 1-3), naphthalenediyl group (following formulas 4-13), anthracenylene group (following formulas 14-19), biphenylene group (following formulas 20-25), terphenyl-diyl group (following formulas 26-28), condensed ring compound group (following formulas 29-35), fluorene-diyl group (following formulas 36-38), stilbene-diyl (following formulas A-D), distilbene-diyl (following formulas E,F), etc. Among them, phenylene group, biphenylene group, and stilbene-diyl group are preferable.

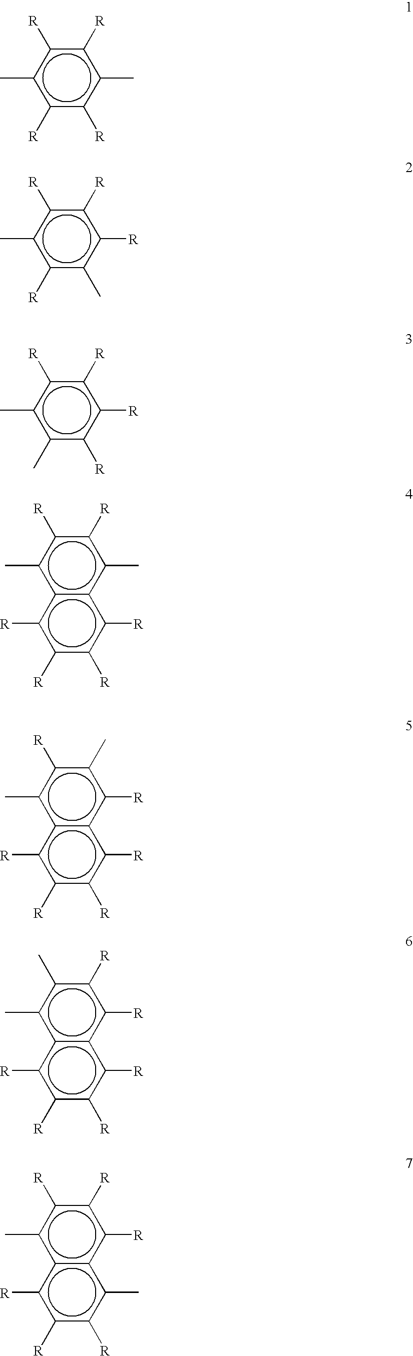

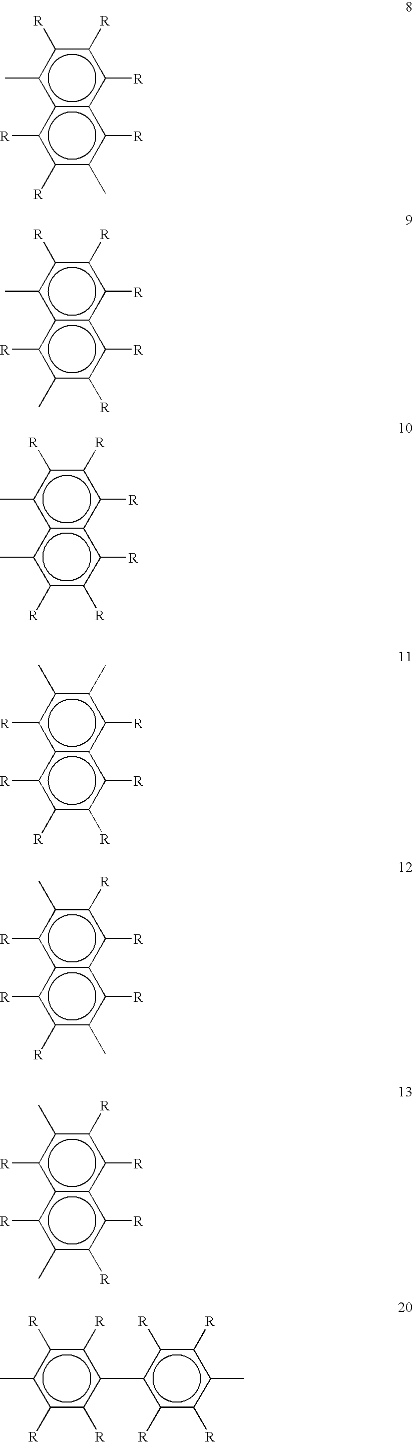

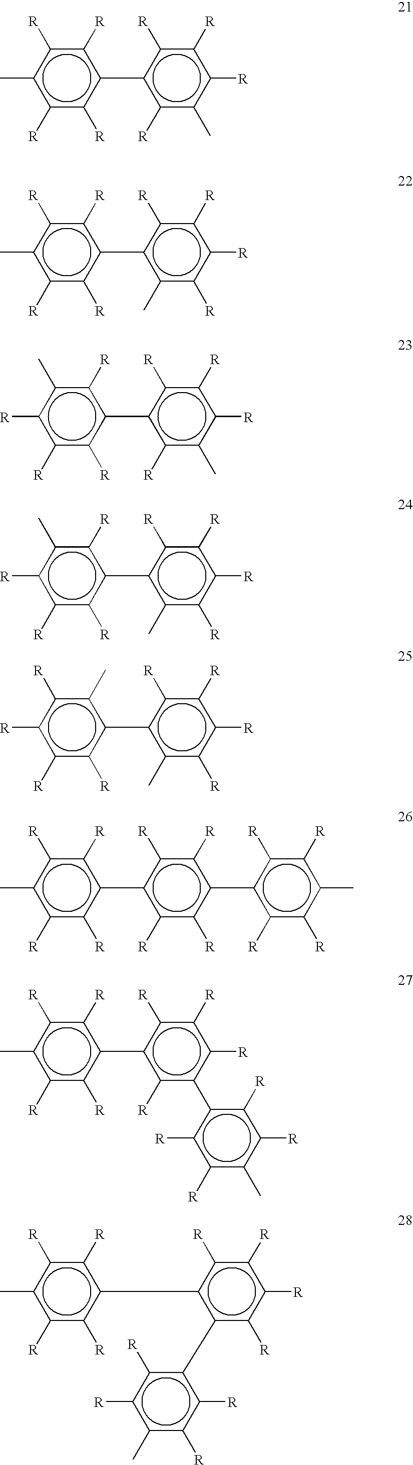

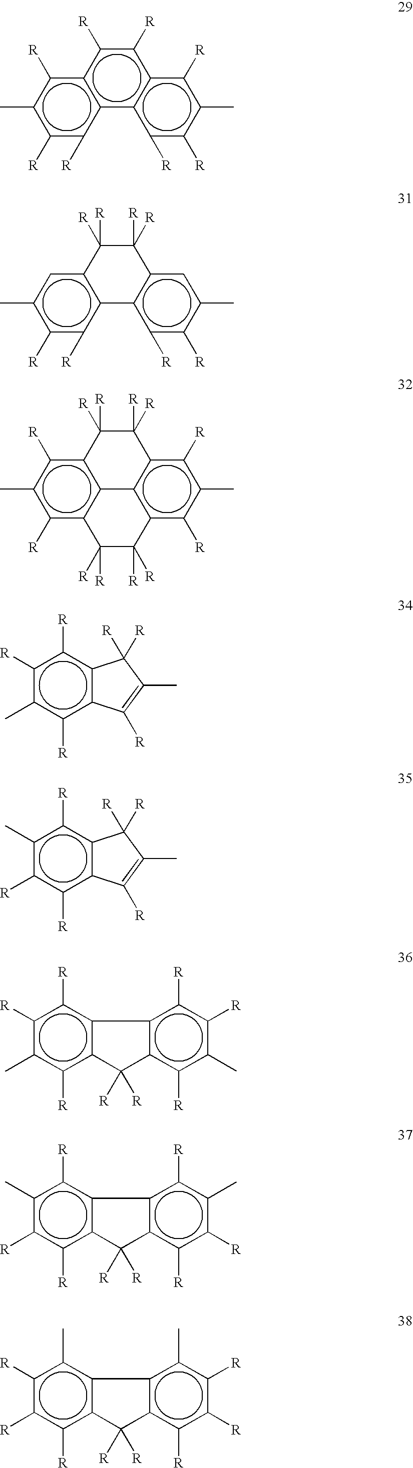

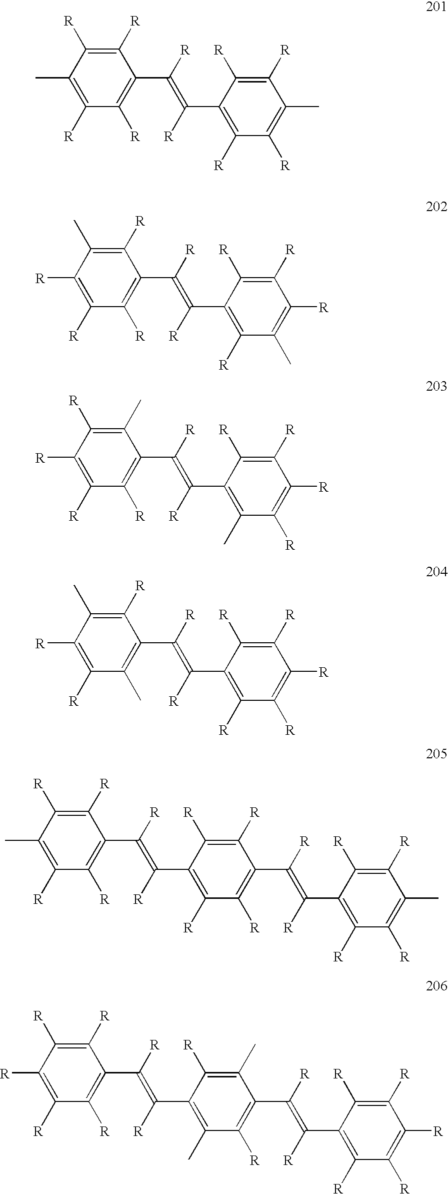

The divalent heterocyclic group means an atomic group in which two hydrogen atoms are removed from a heterocyclic compound, and the number of carbon atoms is usually about 3 to 60.

The heterocyclic compound means an organic compound having a cyclic structure in which at least one heteroatom such as oxygen, sulfur, nitrogen, phosphorus, boron, etc. is contained in the cyclic structure as the elements other than carbon atoms.

Examples of the divalent heterocyclic groups include the followings.

Divalent heterocyclic groups containing nitrogen as a hetero atom; pyridine-diyl group (following formulas 39-44), diaza phenylene group (following formulas 45-48), quinolinediyl group (following formulas 49-63), quinoxalinediyl group (following formulas 64-68), acridinediyl group (following formulas 69-72), bipyridyldiyl group (following formulas 73-75), phenanthrolinediyl group (following formulas 76-78), etc.

Groups having a fluorene structure containing silicon, nitrogen, selenium, etc. as a hetero atom (following formulas 79-93).

5 membered heterocyclic groups containing silicon, nitrogen, sulfur, selenium, etc. as a hetero atom: (following formulas 94-98).

Condensed 5 membered heterocyclic groups containing silicon, nitrogen, selenium, etc. as a hetero atom: (following formulas 99-110),

5 membered heterocyclic groups containing silicon, nitrogen, sulfur, selenium, etc. as a hetero atom, which are connected at the a position of the hetero atom to form a dimer or an oligomer (following formulas III-112);

5 membered ring heterocyclic groups containing silicon, nitrogen, sulfur, selenium, as a hetero atom is connected with a phenyl group at the a position of the hetero atom (following formulas 113-119); and

Groups of 5 membered ring heterocyclic groups containing nitrogen, oxygen, sulfur, as a hetero atom ono which a phenyl group, furyl group, or thienyl group is substituted (following formulas 120-125).

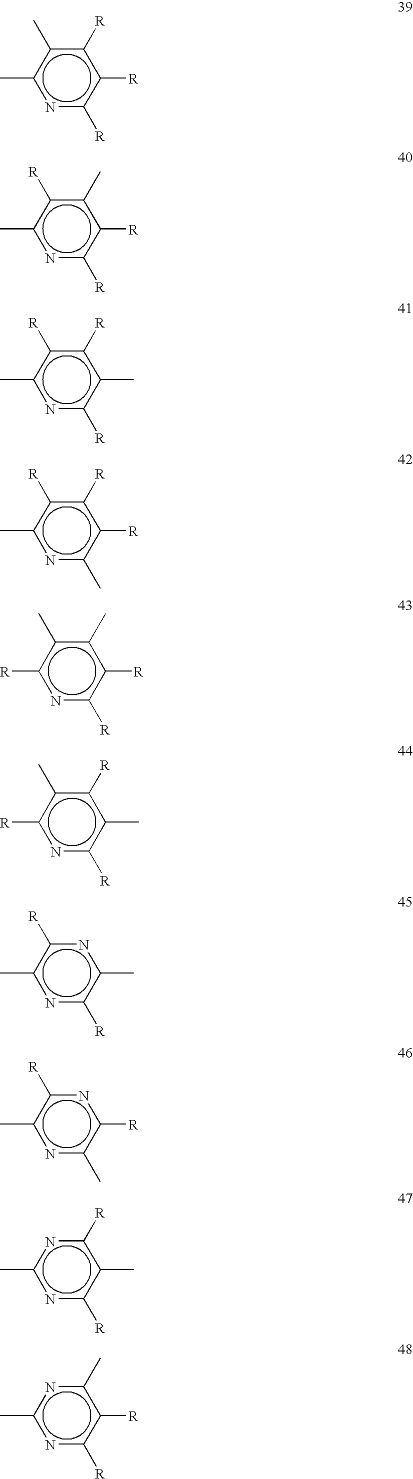

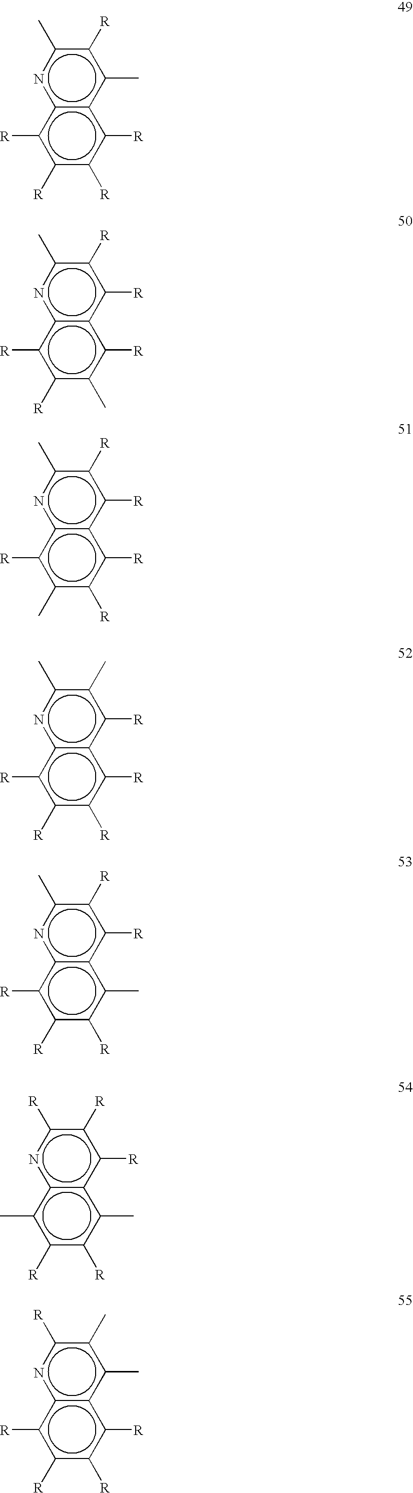

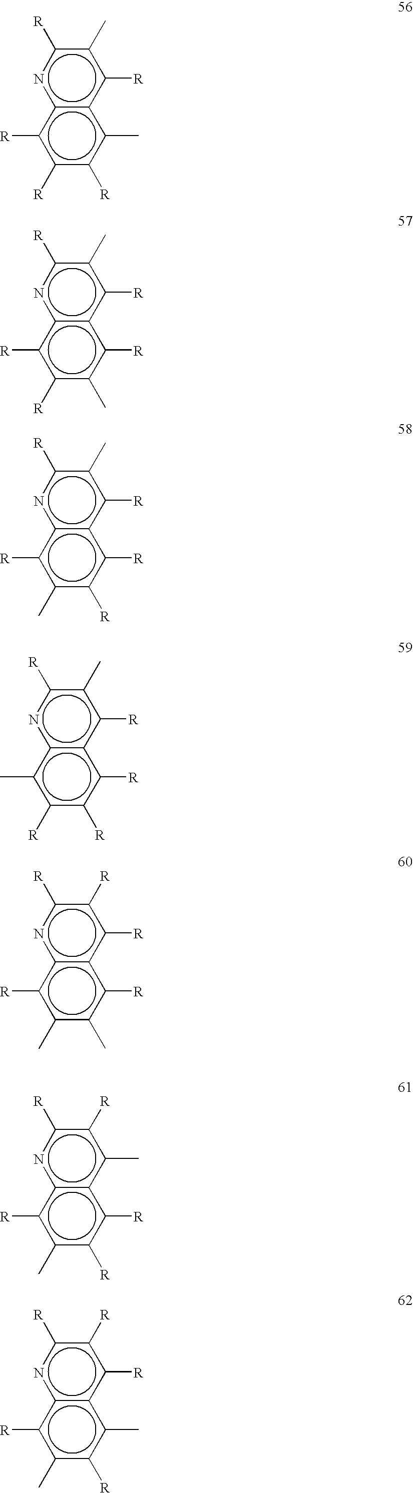

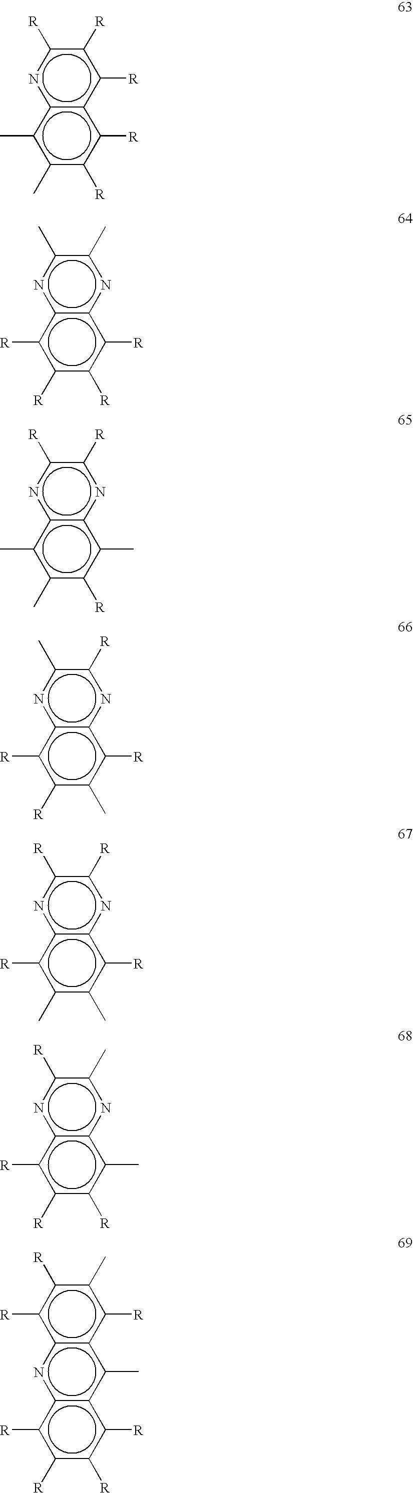

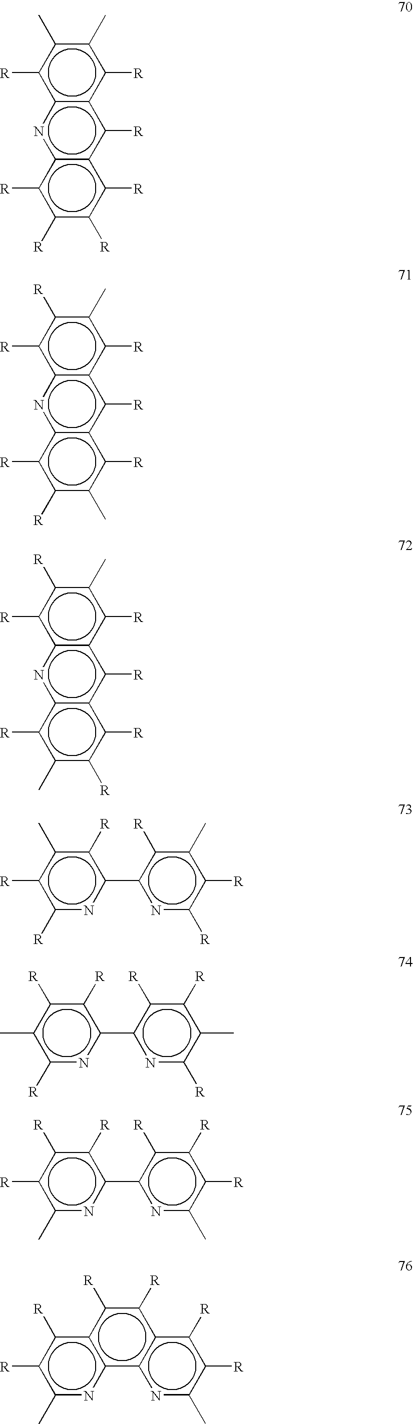

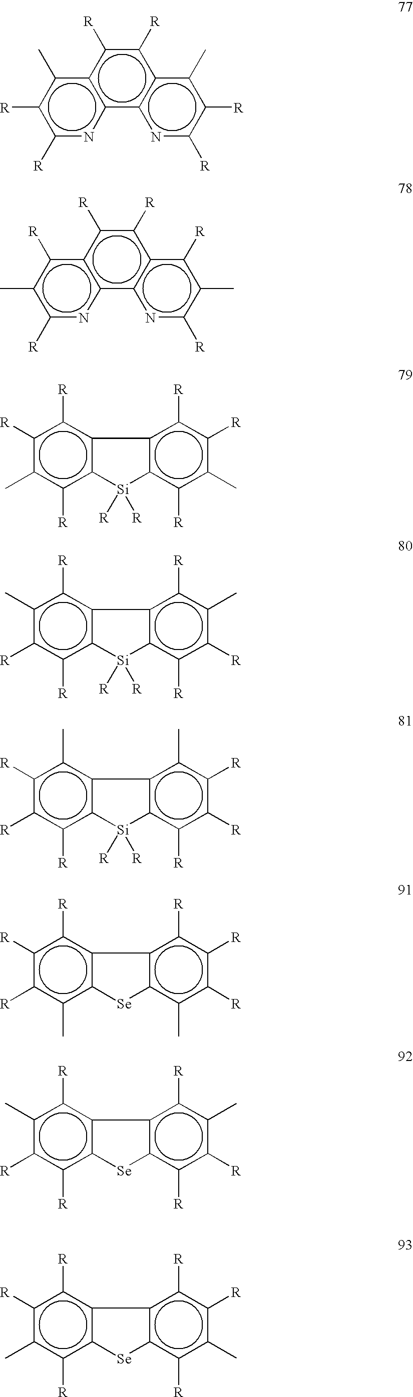

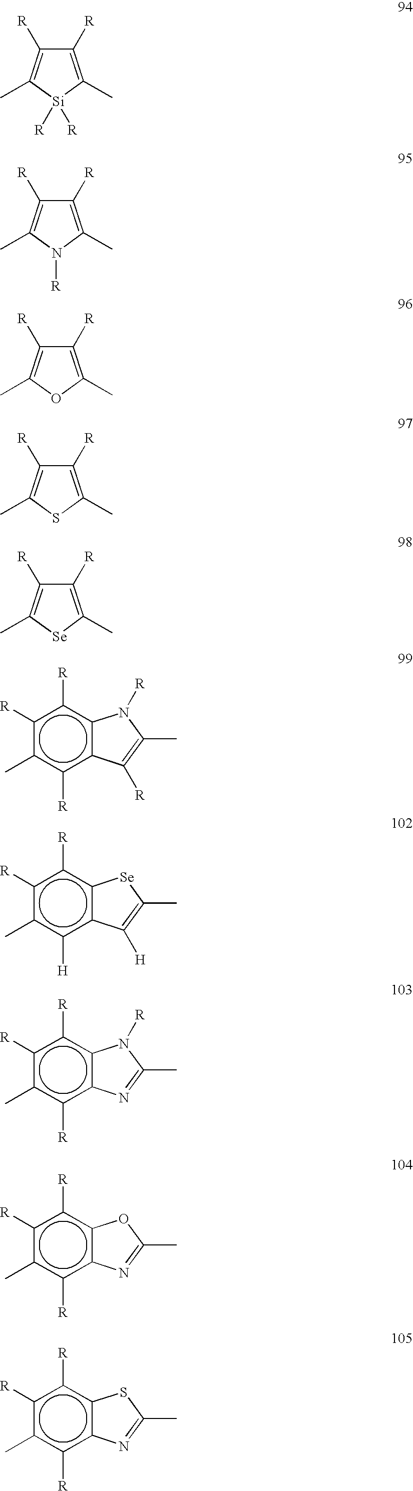

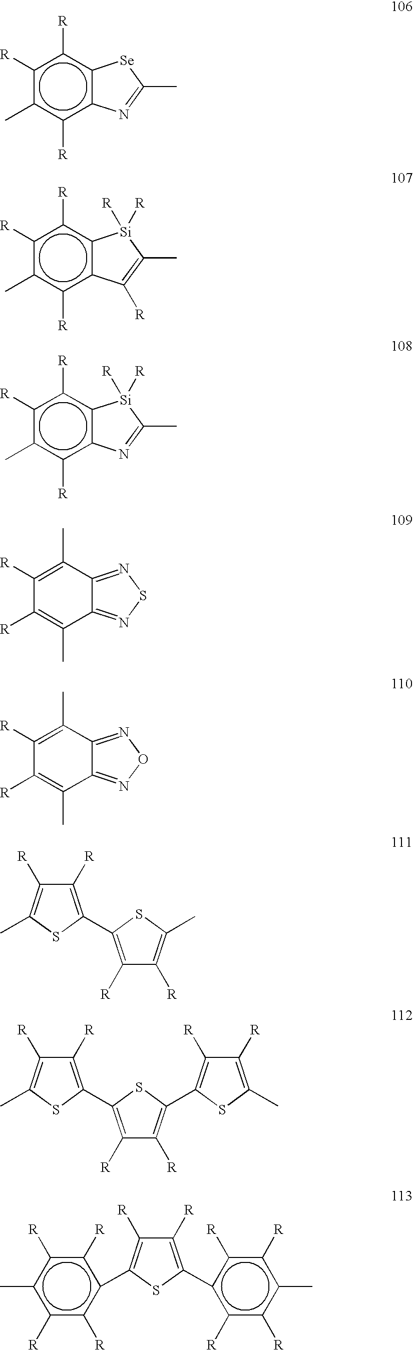

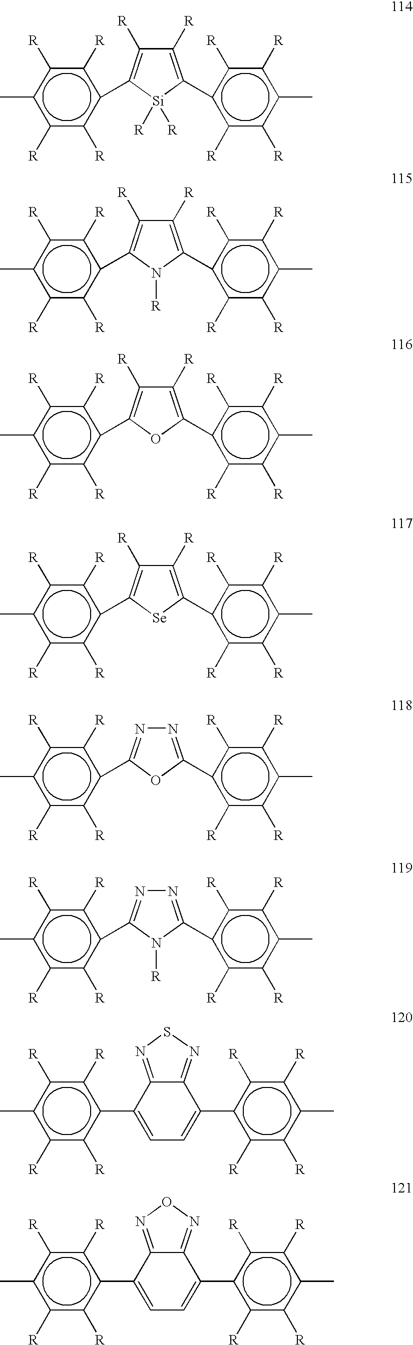

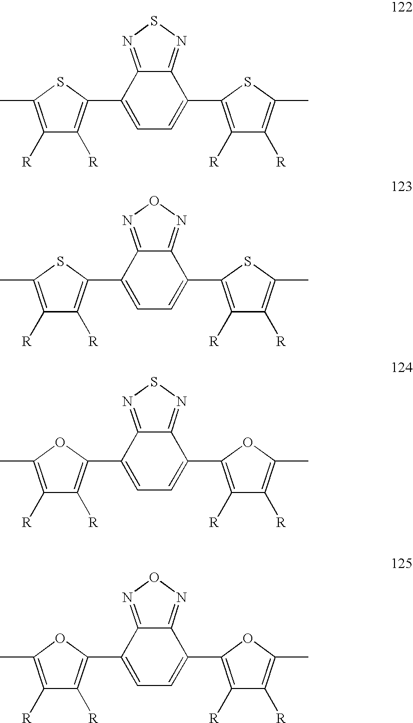

In the examples of the above formulae 1-125, Rs each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom (for example, chlorine, bromine, iodine), acyl group, acyloxy group, imine residue, amide group, acid imide group, monovalent heterocyclic group, carboxyl group, substituted carboxyl group, or cyano group. Carbon atom contained in the groups of formulas I-125 may be substituted by a nitrogen atom, oxygen atom, or sulfur atom, and a hydrogen atom may be substituted by a fluorine atom.

In order to improve the solubility in a solvent, it is preferable that Ar₁, Ar₂, Ar₃ and Ar₄ have substituent, and one or more of them include an alkyl group or alkoxy group having cyclic or long chain. Examples thereof include cyclopentyl group, cyclohexyl group, pentyl group, isoamyl group, hexyl group, octyl group, 2-ethylhexyl group, decyl group, 3,7-dimethyloctyl group, pentyloxy group, isoamyloxy group, hexyloxy group, octyloxy group, 2-ethylhexyloxy group, decyloxy group, and 3,7-dimethyloctyloxy group.

Two substituents may be connected to form a ring. Furthermore, a part of carbon atom of the alkyl may be replaced by a group containing a hetero atom, and examples of the hetero atom include an oxygen atom, a sulfur atom, a nitrogen atom, etc.

As the repeating unit of the above-mentioned formula (3), repeating units of the following formula (7), (9), (10), (11), (12), (13) or (14) are listed.

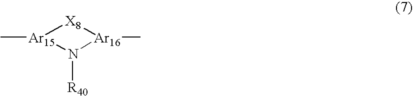

(wherein, Ar₁₅ and Ar₁₆ represent each independently a trivalent aromatic hydrocarbon group or trivalent heterocyclic group, R₄₀ represents an alkyl group, alkoxy group, alkylthio group, alkylsilyl group, alkylamino group, aryl group optionally having a substituent, or monovalent heterocyclic group, and X represents a single bond or the following group.

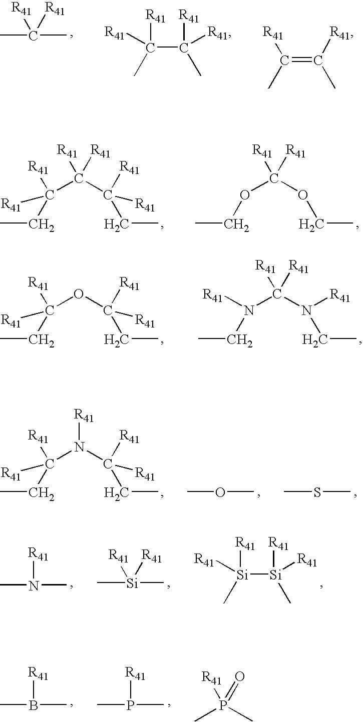

(wherein, R₄₁s represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group or cyano group. When there are a plurality of R₄₁s, they may be the same or different.).

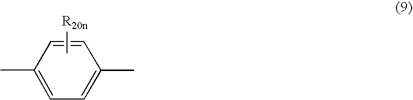

(wherein, R₂₀ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. n represents an integer of 0 to 4. When a plurality of R₂₀s are present, they may be the same or different.)

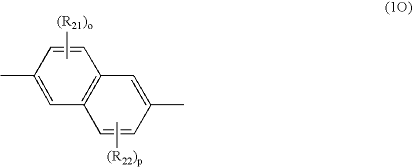

(wherein, R₂₁ and R₂₂ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. o and p each independently represent an integer of 0 to 3. When R₂₁ and R₂₂ are present each in plural number, they may be the same or different.)

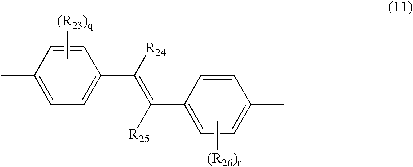

(wherein, R₂₃ and R₂₆ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. q and r each independently represent an integer of 0 to 4. R₂₄ and R₂₅ each independently represent a hydrogen atom, alkyl group, aryl group, monovalent heterocyclic group, carboxyl group, substituted carboxyl group or cyano group. When R₂₃ and R₂₆ are present in plural number, they may be the same or different.)

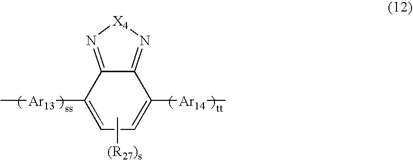

(wherein, R₂₇ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. s represents an integer of 0 to 2. Ar₁₃ and Ar₁₄ represent each independently an arylene group, divalent heterocyclic group or divalent group having a metal complex structure. ss and tt represent each independently 0 or 1. X₄ represents O, S, SO, SO₂, Se or Te. When there are a plurality of R₂₇s, they may be the same or different.).

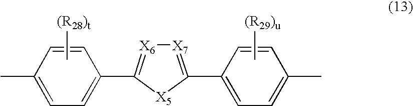

(wherein, R₂₈ and R₂₉ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. t and u represent each independently an integer of 0 to 4. X₅ represents O, S, SO₂, Se, Te, N—R₃₀ or SiR₃₁R₃₂. X₆ and X₇ represent each independently N or C—R₃₃. R₃₀, R₃₁, R₃₂ and R₃₃ represent each independently a hydrogen atom, alkyl group, aryl group, arylalkyl group or monovalent heterocyclic group. When there are a plurality of R₂₈, R₂₉ and R₃₃ respectively, they may be the same or different.).

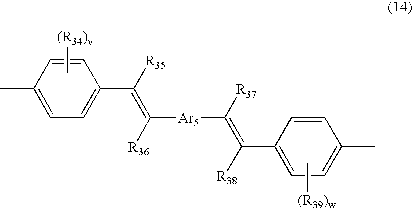

(wherein, R₃₄ and R₃₉ represent each independently an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. v and w represent each independently an integer of 0 to 4. R₃₅, R₃₆, R₃₇ and R₃₈ represent each independently a hydrogen atom, alkyl group, aryl group, monovalent heterocyclic group, carboxyl group, substituted carboxyl group or cyano group. Ar₅ represents an arylene group, divalent heterocyclic group or divalent group having a metal complex structure. When there are a plurality of R₃₄ and R₃₉ respectively, they may be the same or different.).

Examples of the repeating unit represented by the above formula (3) include a repeating unit of the following formula (8).

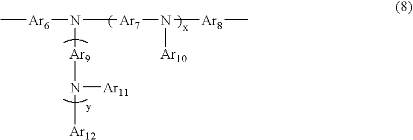

(wherein, Ar₆, Ar₇, Ar₈ and Ar₉ each independently represent an arylene group or divalent heterocyclic group. Ar₁₀, Ar₁₁, and Ar₁₂ each independently represent an aryl group or monovalent heterocyclic group. Ar₆, Ar₇, Ar₈, Ar₉ and Ar₁₀ may have a substituent. x and y each independently represent 0 or 1, and 0=x+y=1).

Among the structures represented by the above formula (8), structures j represented by the below formula (15) are preferable.

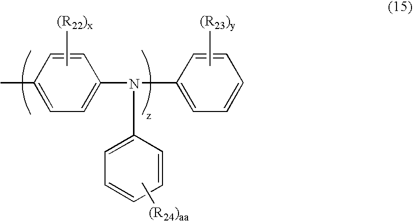

(wherein, R₂₂, R₂₃ and R₂₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. x and y each independently represent an integer of 0-4. z represents an integer of 1-2. aa represents an integer of 0-5.)

As R₂₄ in the above formula (15), an alkyl group, alkoxy group, aryl group, aryloxy group, arylalkyl group, arylalkoxy group, substituted amino group are preferable. As the substituted amino group, diaryl amino group is preferable, and diphenyl amino group is more preferable.

In the above, although preferable combination thereof differs according to a metal complex combined with the polymer, combinations of the above formula (A-1-4-1) with the above formula (7), (8) or (9) are preferable, and combinations of formula (A-1-4-1) with formula (8) or (9) are more preferable.

In the structure represented by the above formula (A-1-4-1), it is preferable that Y is a sulfur atom, or oxygen atom.

Furthermore, the end group of polymer compound of the present invention may also be protected with a stable group, since light emitting property and life time when made into a device may be deteriorated if a polymerizable group remains intact. Those having a conjugated bond continuing to a conjugated structure of the main chain are preferable, and there are exemplified structures connected to an aryl group or heterocyclic compound group via a carbon-carbon bond. Specifically, substituents described as Chemical Formula 10 in JP-A-9-45478 are exemplified.

The polymer compound of the present invention may also be a random, block or graft copolymer, or a polymer having an intermediate structure thereof, for example, a random copolymer having block property. From the viewpoint for obtaining a polymer having high quantum yield, random copolymers having block property and block or graft copolymers are preferable than complete random copolymers. Further, a polymer having a branched main chain and more than three terminals, and a dendrimer may also be included.

It is preferable that the polymer compound of the present invention has a polystyrene reduced number average molecular weight of 10³-10⁸, and more preferably 10⁴-10⁷.

As the manufacture method of the polymer compound of the present invention, a monomer having a plurality of polymerizable groups is dissolved in an organic solvent according to necessity, and can be reacted using alkali or appropriate catalyst, at a temperature between the boiling point and the melting point of the organic solvent.

For example, known methods which can be used are described in: Organic Reactions, volume 14, page 270-490, John Wiley & Sons, Inc., 1965; Organic Syntheses, Collective Volume VI, page 407-411, John Wiley & Sons, Inc., 1988; Chemical Review (Chem. Rev.), Volume 95, page 2457 (1995); Journal of Organometallic Chemistry (J. Organomet. Chem.), Volume 576, page 147 (1999); and Macromolecular Chemistry, Macromolecular Symposium (Makromol. Chem., Macromol. Symp.), Volume 12th, page 229 (1987).

In the manufacture method of the polymer compound of the present invention, known condensation reactions can be used as the method of carrying out condensation polymerization. As the method of condensation polymerization, in case of producing double bond, for example, a method described in JP-A-5-202355 is exemplified. That is, exemplified are: polymerization by Wittig reaction of a compound having formyl group and a compound having phosphonium-methyl group, or a compound having formyl group and phosphonium-methyl group; polymerization by Heck reaction of a compound having vinyl group and a compound having halogen atom; polycondensation by dehydrohalogenation method of a compound having two or more monohalogenated-methyl groups; polycondensation by sulfonium-salt decomposition method of a compound having two or more sulfonium-methyl groups; polymerization by Knoevenagel reaction of a compound having formyl group and a compound having cyano group; and polymerization by McMurry reaction of a compound having two or more formyl groups.

When a polymer compound of the present invention has a triple bond in the main chain by condensation polymerization, for example, Heck reaction can be used.

In case of producing neither a double bond nor a triple bond, exemplified are: a method of polymerization by Suzuki coupling reaction from corresponding monomer; a method of polymerization by Grignard reaction; a method of polymerization by Ni(0) complex; a method of polymerization by oxidizing agent, such as FeCl₃; a method of electrochemical oxidative polymerization; and a method by decomposition of an intermediate polymer having a suitable leaving group.

Among these, a polymerization by Wittig reaction, a polymerization by Heck reaction, a polymerization by Knoevenagel reaction, a method of polymerization by Suzuki coupling reaction, a method of polymerization by Grignard reaction, and a method of polymerization by nickel zero-valent complex are preferable, since it is easy to control the structure.

When the reactive substituent in the raw monomer for the polymer compound used for the present invention is a halogen atom, alkylsulfonate group, arylsulfonate group, or arylalkylsulfonate group, a manufacture method by condensation polymerization in the existence of nickel-zerovalent-complex is preferable.

As the raw material compound, a dihalogenated compound, bis (alkylsulfonate) compound, bis(arylsulfonate) compound, bis (arylalkylsulfonate) compound, or halogen-alkylsulfonate compound, halogen-arylsulfonate compound, halogen-arylalkylsulfonate compound, alkylsulfonate-arylsulfonate compound, alkylsulfonate-arylalkylsulfonate compound are exemplified.

Moreover, when the reactive substituent in the raw monomer for the polymer compound used for the present invention is a a halogen atom, alkylsulfonate group, arylsulfonate group, arylalkylsulfonate group, boric-acid group, or boric acid ester group, it is preferable that the ratio of the total mol of a halogen atom, alkylsulfonate group, arylsulfonate group, and arylalkylsulfonate group, with the total of boric-acid group and boric acid ester group is substantially 1 (usually in the range of 0.7 to 1.2), and the manufacture method is a condensation polymerization using a nickel catalyst or a palladium catalyst.

Concrete examples of the combination of raw material compounds include combinations of a dihalogenated compound, bis (alkylsulfonate) compound, bis(arylsulfonate) compound or bis(arylalkylsulfonate) compound, with a diboric acid compound, or diboric acid ester compound.

Moreover, halogen-boric acid compound, halogen-boric acid ester compound, alkylsulfonate-boric acid compound, alkylsulfonate-boric acid ester compound, arylsulfonate-boric acid compound, arylsulfonate-boric acid ester compound, arylalkylsulfonate-boric acid compound, and arylalkylsulfonate-boric acid ester compound are exemplified.

It is preferable that the organic solvent used is subjected to a deoxygenation treatment sufficiently and the reaction is progressed under an inert atmosphere, generally for suppressing a side reaction, though the treatment differs depending on compounds and reactions used. Further, it is preferable to conduct a dehydration treatment likewise. However, this is not applicable in the case of a reaction in a two-phase system with water, such as a Suzuki coupling reaction.

For the reaction, alkali or a suitable catalyst is added. It can be selected according to the reaction to be used. It is preferable that the alkali or the catalyst can be dissolved in a solvent used for a reaction. Example of the method for mixing the alkali or the catalyst, include a method of adding a solution of alkali or a catalyst slowly, to the reaction solution with stirring under an inert atmosphere of argon, nitrogen, etc. or conversely, a method of adding the reaction solution to the solution of alkali or a catalyst slowly.

When the polymer compounds of the present invention are used for a polymer LED, the purity thereof exerts an influence on light emitting property, therefore, it is preferable that a monomer is purified by a method such as distillation, sublimation purification, re-crystallization and the like before being polymerized. Further, it is preferable to conduct a purification treatment such as re-precipitation purification, chromatographic separation and the like after the polymerization.

Next, the metal complex (B) in the polymer compound of the present invention will be explained.

The metal complex (B) has at least one tridentate ligand and has a central metal of which atomic number is 21 or more. Here, as the tridentate ligand, mentioned are ligands coordinated to one metal atom or metal ion through three independent atoms in the same molecule.

The tridentate ligand preferably contains at least one aromatic ring, and preferably contains further a condensed ring for obtaining higher light emission efficiency. As the atom to be coordinated to a metal, preferable are carbon, nitrogen, oxygen, sulfur and phosphorus.

As the tridentate ligand, for example, the following moieties are listed.

(In the drawings, * represents an atom coordinated to a metal ion. R represents the same meaning as described above, and Rs in the same molecule may be the same or different.).

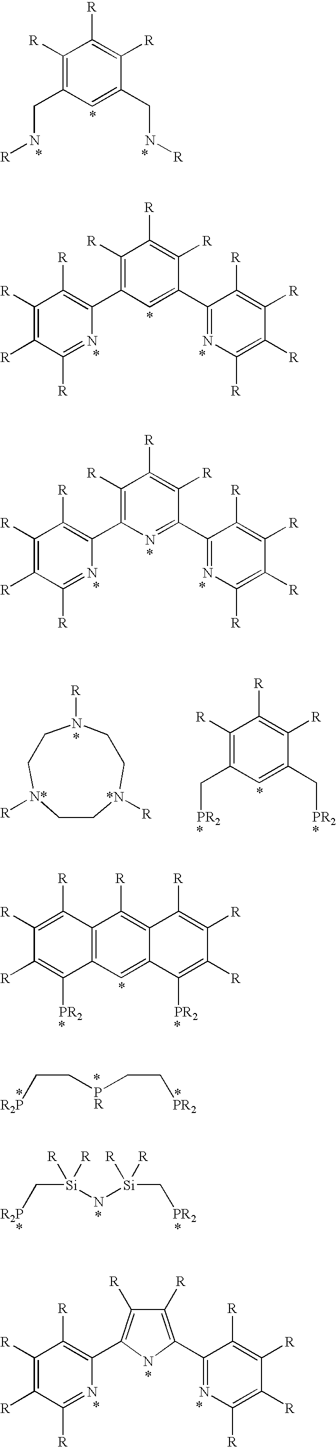

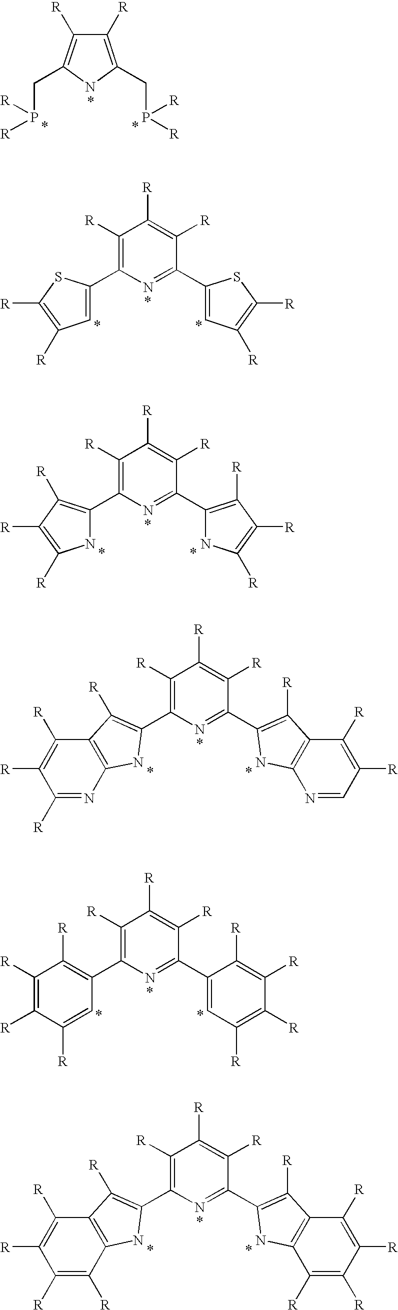

Ligands other than the tridentate ligand are not particularly restricted, and may be appropriately monodentate ligands or bidentate ligands depending on the valency that can be manifested by the central metal to be used, and two tridentate ligands may be present.

Ligands other than the tridentate ligand also preferably contains at least one aromatic ring, and preferably contains further a condensed ring for obtaining higher light emission efficiency. As the atom to be coordinated to a metal, preferable are carbon, nitrogen, oxygen, sulfur and phosphorus, and particularly, carbon, nitrogen and phosphorus are further preferable. Furthermore, the ligand may have a substituent from the standpoint of improvement in solubility, and the like.

As the ligands other than the tridentate ligand, for example, the following moieties are listed.

(in the drawings, * and R represent the same meanings as described above.).

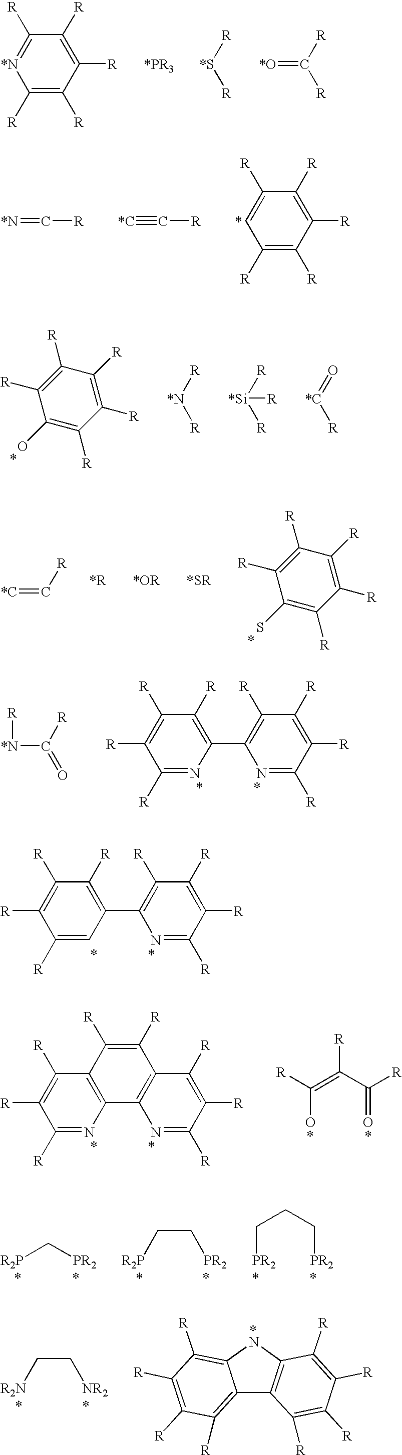

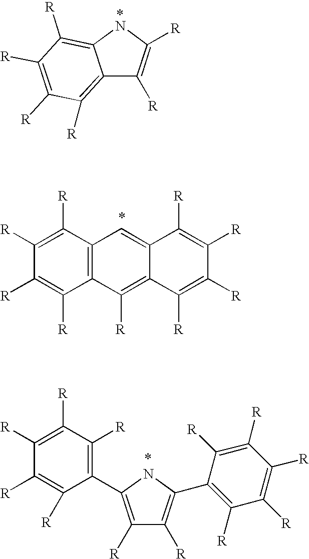

The combination of the tridentate ligand with other ligands is not particularly restricted and preferable combinations can be appropriately selected depending on the valency of the central metal, and from the standpoint of controlling emitting color in the visible region, it is preferable to combine the tridentate ligand with at least one monodentate ligand.

The central metal is an atom of which atomic number is 21 or more, and preferably a metal showing a spin-orbital mutual action to the complex and capable of causing intersystem crossing between the singlet state and the triplet state, and examples thereof include transition metals of IV and V periods, W, Os, Ir, Au, lanthanoids, Re, Sc, Pt, Ru and the like, and from the standpoint of light emission efficiency, Ru, Rh, W, Os, Ir, Au, Eu and Tb are preferable, W, Os, Ir and Au are more preferable, Wand Au are further preferable, and Au is most preferable.

Among metal complexes to be used in the present invention, light-emitting metal complexes are preferable, and metal complexes showing light emission from the triplet excitation state are more preferable.

As the metal complex showing light emission from the triplet excitation state, for example, compounds in which phosphorescence, and fluorescence in addition to the phosphorescence are observed are also included.

As the structure of the metal complex (B) in the polymer compound, the following structures (B-1) to (B-5) are specifically listed.

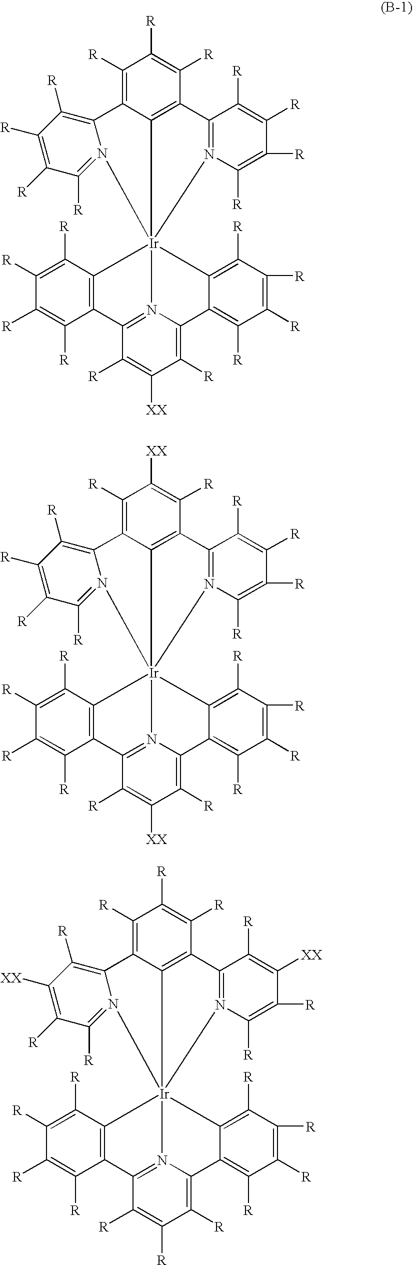

(wherein, R represents the same meaning as described above. XX represents a position to be connected to a polymer chain.)

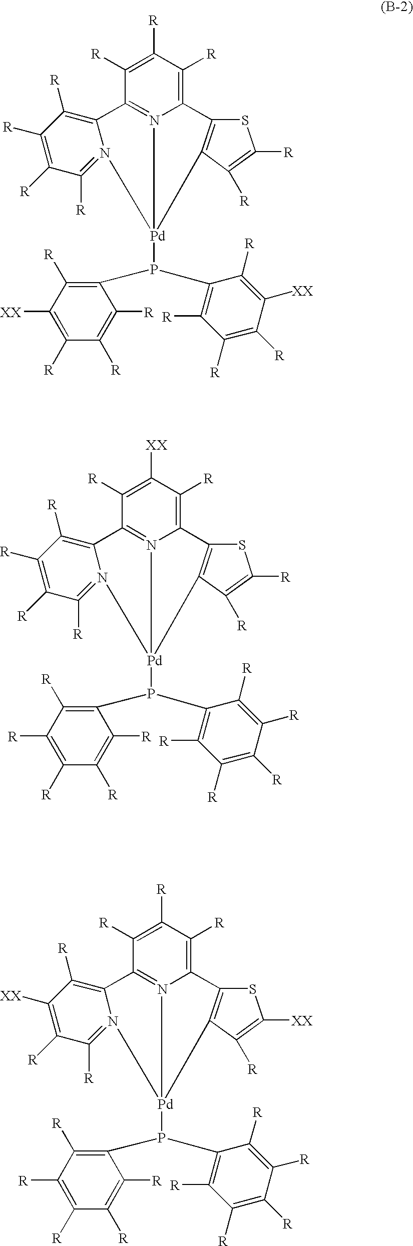

(wherein, R represents the same meaning as described above. XX represents a position to be connected to a polymer chain.)

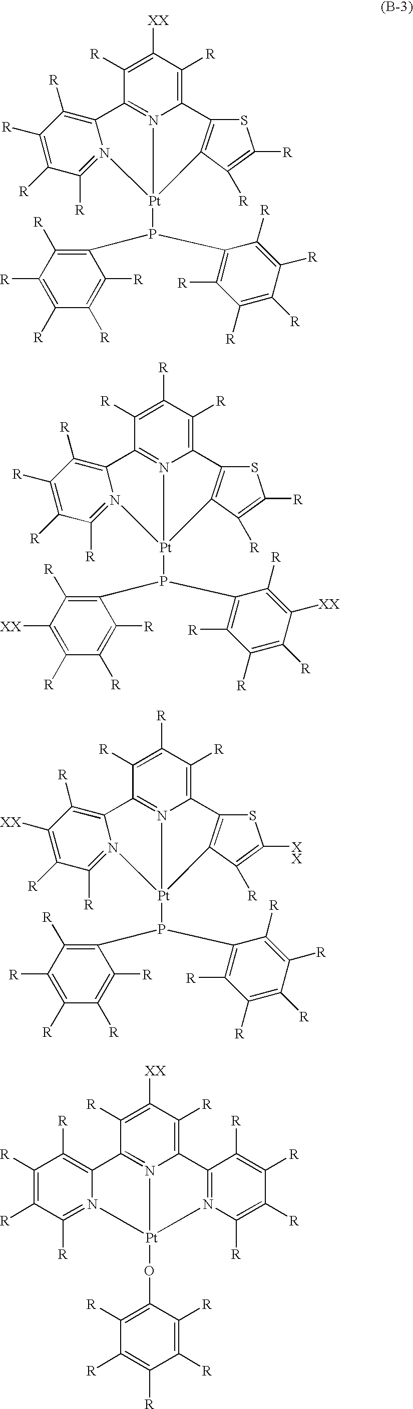

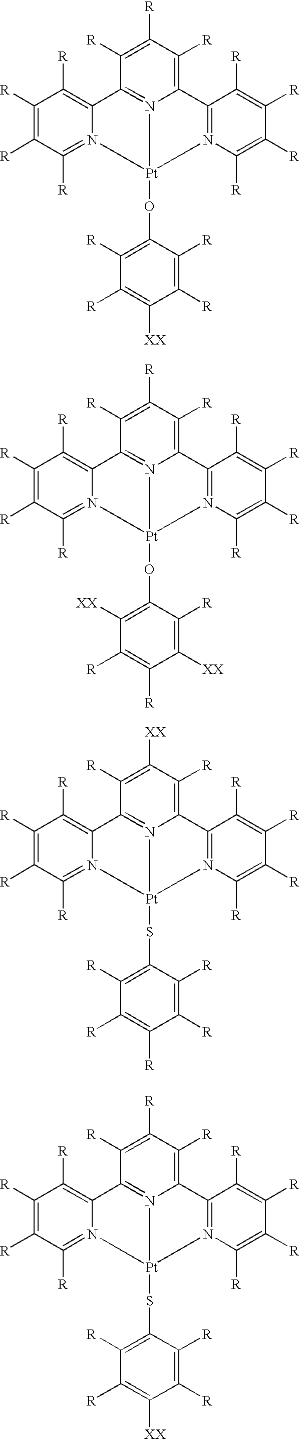

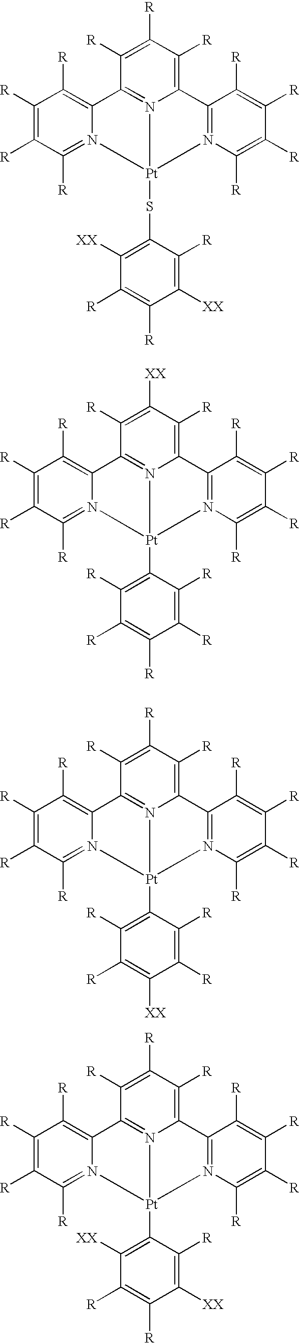

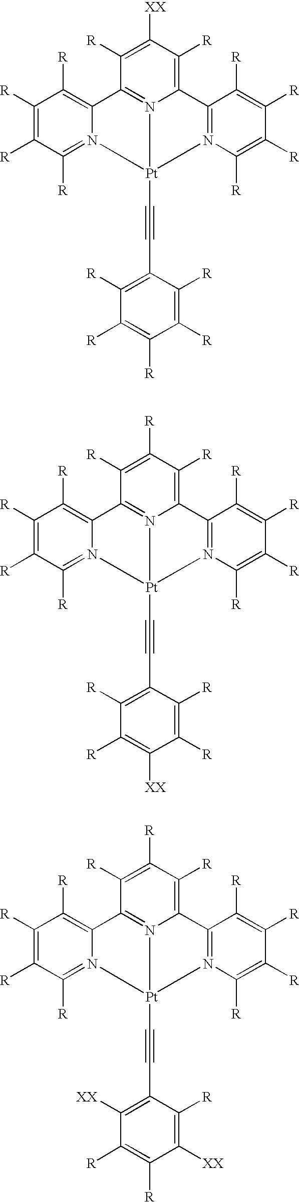

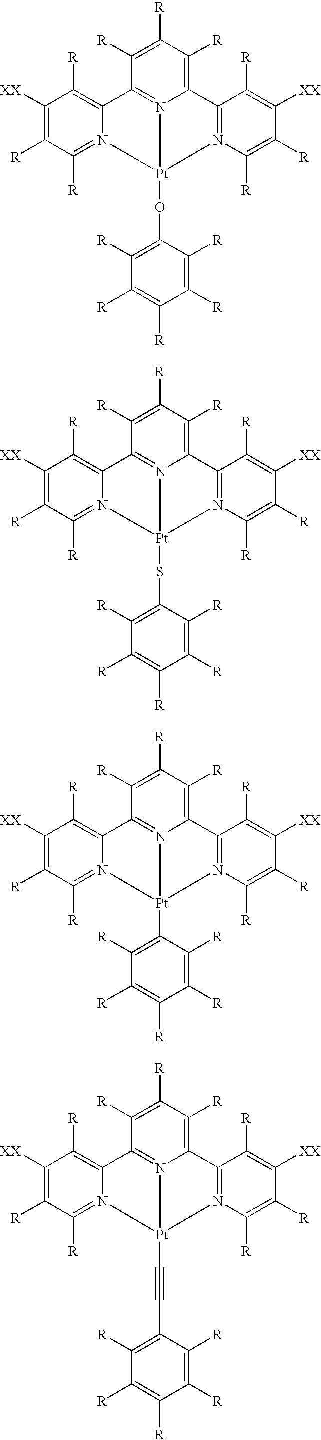

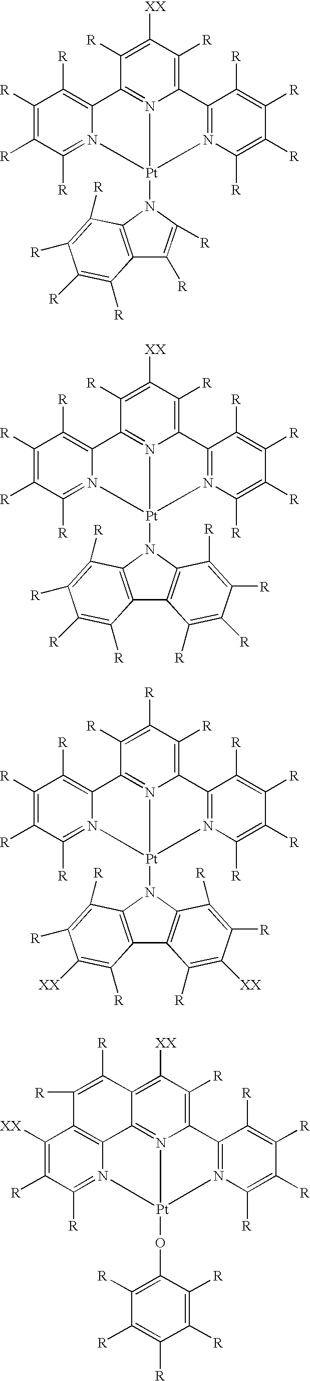

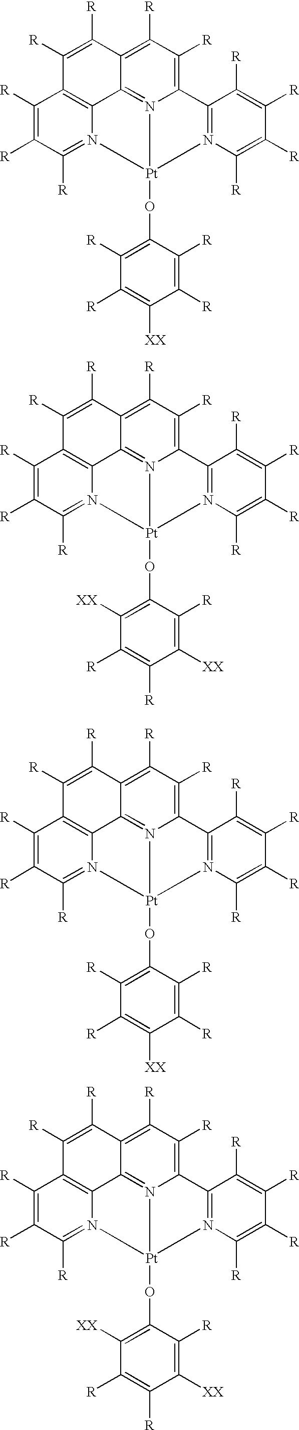

(wherein, R represents the same meaning as described above. XX represents a position to be connected to a polymer chain.)

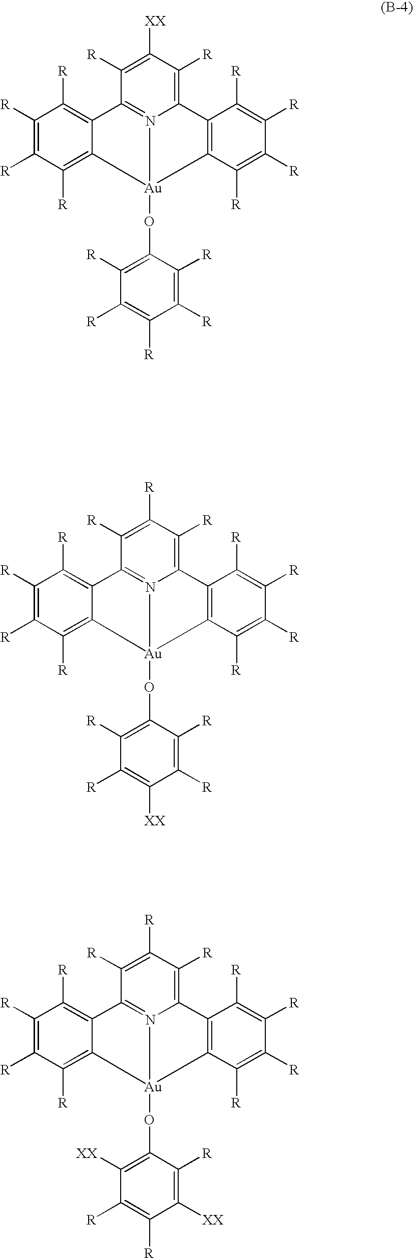

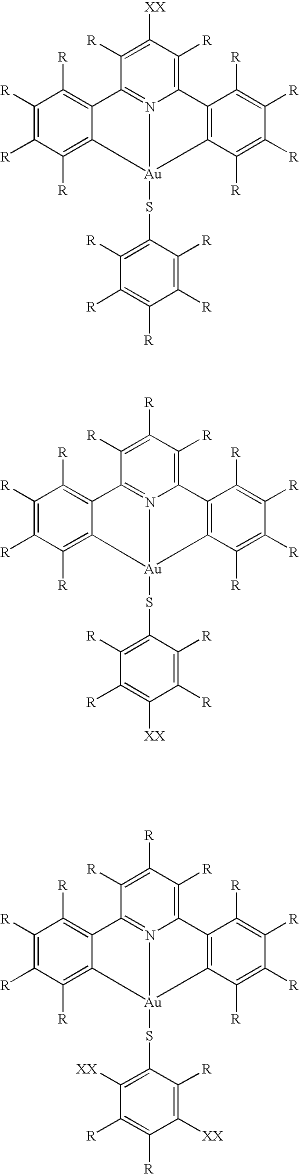

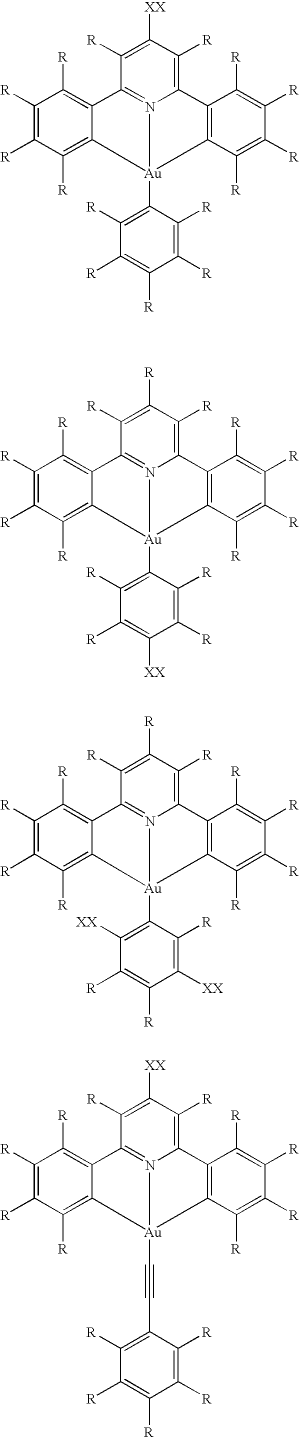

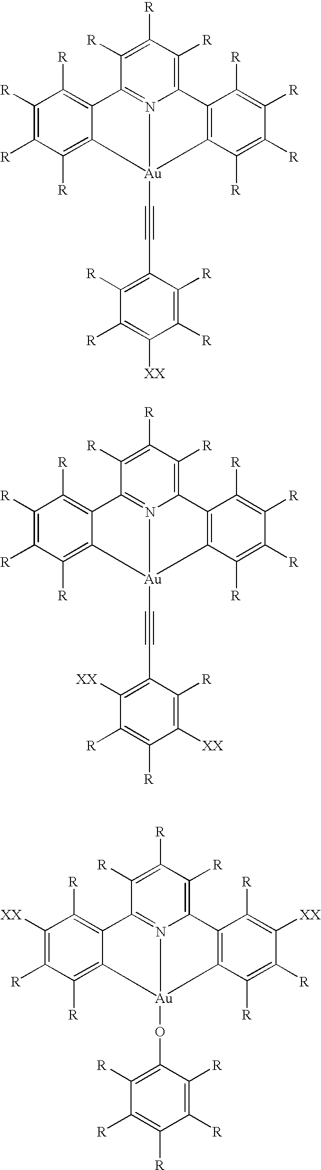

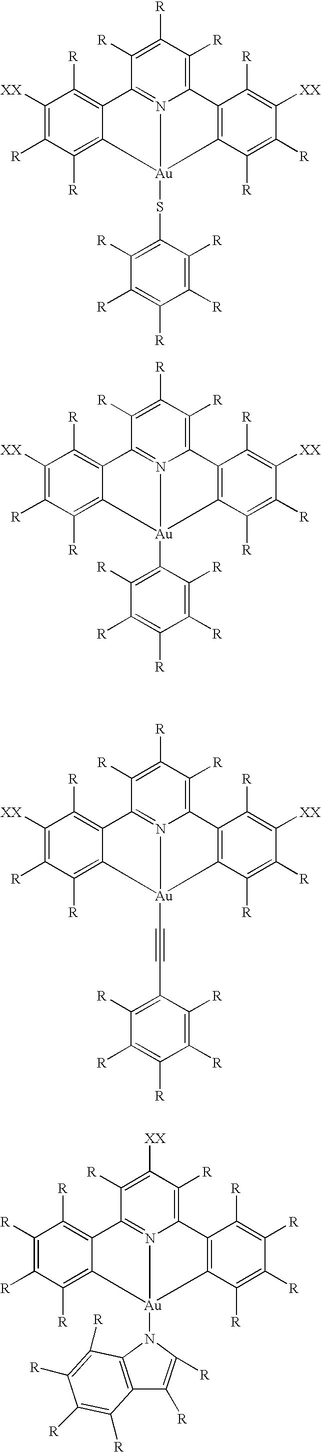

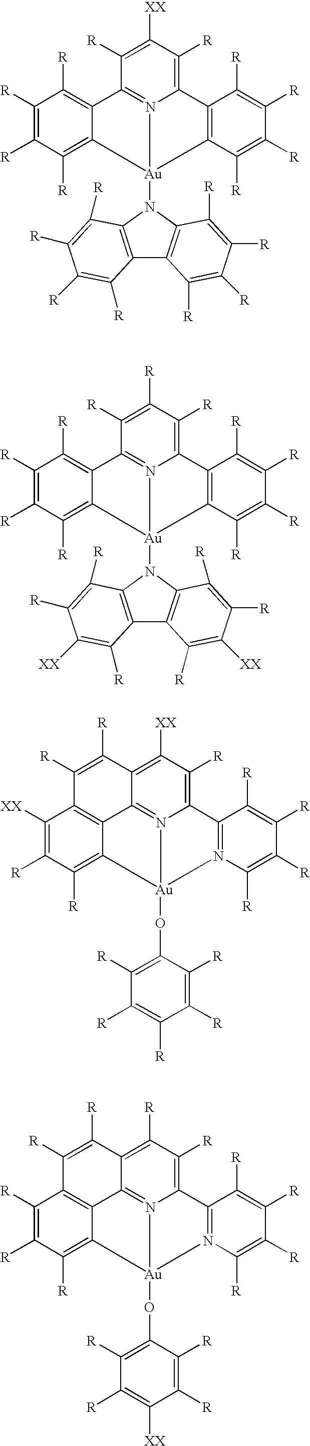

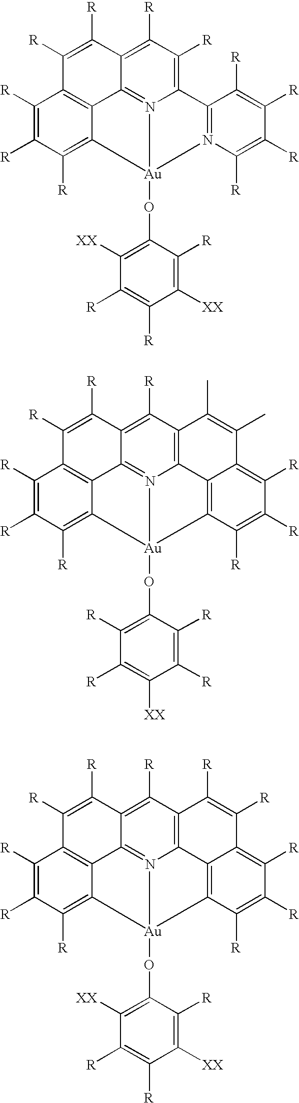

(wherein, R represents the same meaning as described above. XX represents a position to be connected to a polymer chain.)

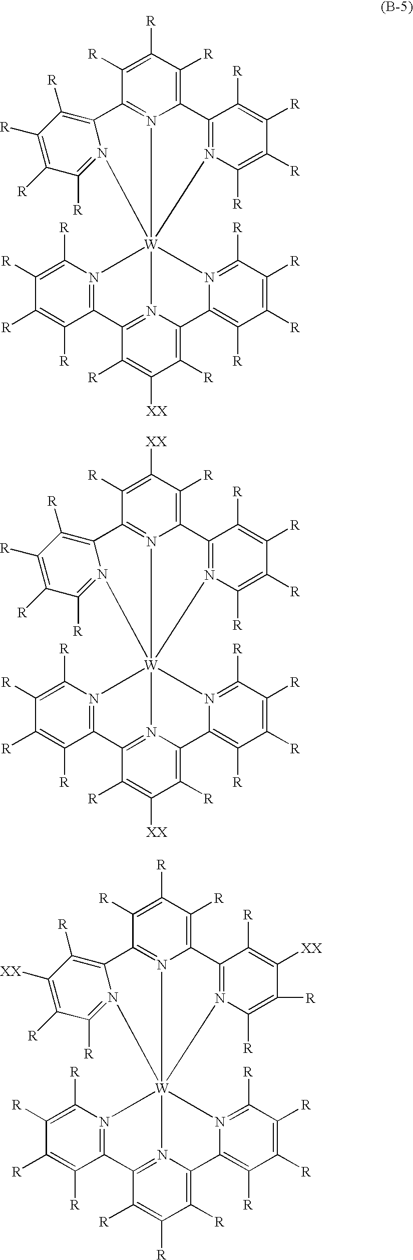

(wherein, R represents the same meaning as described above. XX represents a position to be connected to a polymer chain.)

The amount of the metal complex (B) in the polymer compound of the present invention is not particularly restricted since the amount varies depending on the kind of the conjugated polymer (A) to be combined and properties to be optimized, and usually 0.01 to 80 parts by weight, preferably 0.1 to 60 parts by weight when the amount of the polymer (A) is 100 parts by weight.

In the polymer compound of the present invention, the conjugated polymer (A) has in the molecule the metal complex (B) as a partial structure, and in its embodiments, a ligand of the metal complex (B) is connected to a conjugated polymer. Examples thereof include those containing a repeating unit of the general formula (A-1), having a polystyrene-reduced number-average molecular weight of 10³ to 10⁸, and having a structure of the metal complex (B) at its side chain, main chain and/or end.

Polymer compounds having a structure of the metal complex (B) at the side chain of the conjugated polymer (A) contain, for example, a repeating unit of the following formula.

—Ar¹⁸—

(wherein, Ar¹⁸ represents a divalent aromatic ring, or a divalent heterocyclic group having at least one atom selected from the group consisting of an oxygen atom, nitrogen atom, silicon atom, germanium atom, tin atom, phosphorus atom, boron atom, sulfur atom, selenium atom and tellurium atom, and the Ar¹⁸ has 1 or more and 4 or less groups represented by -L-X, and X represents a monovalent group containing a metal complex and L represents a single bond, —O—, —S—, —CO— —CO₂—, —SO—, —SO₂—, —SiR⁶⁸R⁶⁹—, NR⁷⁰—, —BR⁷¹—, —PR⁷³—, —P(═O)(R⁷³)—, alkylene group optionally substituted, alkenylene group optionally substituted, alkynylene group optionally substituted, arylene group optionally substituted, or divalent heterocyclic group optionally substituted, and when the alkylene group, alkenylene group and alkynylene contain a —CH₂— group, one or more —CH₂— groups contained in the alkylene group, one or more —CH₂— groups contained in the alkenylene group and one or more —CH₂— groups contained in the alkynylene group may be respectively substituted by groups selected from the group consisting of —O—, —S—, —CO— —CO₂—, —SO—, —SO₂—, —SiR⁷⁴R⁷⁵—, NR⁷⁶—, —BR⁷⁷— —PR⁷⁸— and —P(═O)(R⁷⁹)—. R⁶⁸, R⁶⁹, R⁷⁰, R⁷¹, R⁷², R⁷³, R^{θ}, R⁷⁵, R⁷⁶, R⁷⁷, R⁷⁸ and R⁷⁹ represent each independently a group selected from the group consisting of a hydrogen atom, alkyl groups, aryl groups, monovalent heterocyclic groups and cyano group. Ar¹⁸ may further have a substituent selected from the group consisting of alkyl groups alkoxy groups, alkylthio groups, aryl groups, aryloxy groups, arylthio groups, arylalkyl groups, arylalkoxy groups, arylalkylthio groups, arylalkenyl groups, arylalkynyl groups, amino group, substituted amino groups, silyl group, substituted silyl groups, halogen atoms, acyl group, acyloxy group, imine residue, amide group, acid imide group, monovalent heterocyclic groups, carboxyl group, substituted carboxyl groups and cyano group, in addition to the group represented by -L-X. When Ar¹⁸ have a plurality of substituents, they may be the same or mutually different.).

Here, as the divalent aromatic ring, exemplified are phenylene and naphthylene, or rings as represented by the above-mentioned general formula (A-1).

Polymer compounds having a structure of the metal complex (B) in the main chain of the conjugated polymer (A) contain, for example, a repeating unit of the following formula.

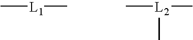

(wherein, L₁ and L₂ represent a metal complex structure, and a divalent or trivalent connecting group in the formula is connected to a repeating unit in which a ligand of a metal complex forms a polymer main chain.).

Polymer compounds having a structure of the metal complex (B) at the end of the conjugated polymer (A) contain, for example, a structure of the following formula.

—X-L₃

(wherein, L₃ represents a monovalent group containing a metal complex, and the monovalent connecting group is connected to X in a ligand of the metal complex. X represents a single bond, alkenylene group optionally substituted, alkynylene group optionally substituted, arylene group optionally substituted or divalent heterocyclic group optionally substituted.).

The polymer compounds having a metal complex structure at the side chain, main chain or end can be produced for example by the above-mentioned method using a monomer having a metal complex structure as one of raw materials.

The present invention relates to a light emitting material containing the above-mentioned polymer compound. In this case, it is preferable that the metal complex is a light-emitting metal complex.

Next, the method for producing a metal complex to be used in the present invention will be explained. The polymer compound of the present invention contains a metal complex structure and a polymer in the same molecule, thus, it is necessary to produce a metal complex having a reactive group which can be incorporated into the polymer.

The metal complex having a reactive group can be produced, for example, by brominating a complex to be used with a general brominating agent such as bromine, N-bromosuccinimide and the like, and polymerizing this as a complex monomer by the above-mentioned polymer compound production method. It is also possible to synthesize a desired metal complex using a ligand having already a reactive group.

Apart from the above-mentioned method, it is also possible to synthesize a polymer compound containing a tridentate ligand portion or other coordinated portion already incorporated, and introduce a complex structure into this to produce a polymer compound to be used in the present invention.

From the standpoint of improving film formability and device properties when a film is formed using a polymer compound of the present invention, it may also be permissible that the polymer compound of the present invention, and other lower molecular weight organic compound and/or polymer compound are mixed to give a polymer composition.

The polymer composition of the present invention contains at least one polymer compound of the present invention. In addition to the polymer compound of the present invention, at least one material selected from hole transporting materials, electron transporting materials and light emitting materials is contained in the composition.

The lower molecular weight organic compound and polymer compound to be combined are not particularly restricted, and those having hole injection transportability (hole transporting material) and electron injection transportability (electron transporting material) are preferably used, and specifically, listed as the lower molecular weight organic compound are triphenylamine, tetraphenyldiamine, biscarbazolylbiphenyl and derivatives thereof and the like, and listed as the polymer compound are polyvinylcarbazole or derivatives thereof, polysilane or derivatives thereof, polysiloxane derivatives having an aromatic amine compound group at the side chain or main chain, polyaniline or derivatives thereof, polythiophene or derivatives thereof, poly(p-phenylenevinylene) or derivatives thereof, or poly(2,5-thienylenevinylene) or derivatives thereof, and the like.

The present invention provides a metal complex (B′) comprising a metal selected from transition metals of IV and V periods and W, Os, Ir, Au and lanthanoids, a monodentate ligand, and a tridentate ligand containing at least one aromatic ring and containing tridentate atoms in the ring structure, the metal complex showing light emission in the visible region at 10° C. or higher, of the complex structure (B).

Further, the present invention provides a metal complex (B″) comprising a metal selected from transition metals of IV and V periods and W, Os, Ir, Au and lanthanoids, a monodentate ligand having an aromatic ring, and a tridentate ligand containing at least one aromatic ring and containing tridentate atoms in the ring structure, of the complex structure (B).

The metal in the metal complexes (B′) and (B″) is a metal selected from transition metals of IV and V periods and W, Os, Ir, Au and lanthanoids, and specific examples thereof include Sc, Ti, Cr, Mn, Fe, Co, Ni, Cu, Zn, Y, Zr, Nb, Mo, Tc, Ru, Rh, Pd, Ag, Hf, Ta, W, Os, Ir, Au, La, Ce, Pr, Nd, Pm, Sm, Eu, Gd, Tb, Dy, Ho, Er, Tm, Yb and Lu, and from standpoint of obtaining higher efficiency, Ru, Rh, W, Os, Ir, Au, Eu and Tb are preferable, W, Os, Ir and Au are more preferable, W and Au are further preferable, and Au is most preferable.

As the monodentate ligand in the metal complex (B′), exemplified are a hydrogen atom, alkyl groups, alkoxy groups, alkylthio groups, aryl groups, aryloxy groups, arylthio groups, acyl group, amide group, acid imide group, amino group, silyl group, carboxyl group, heterocyclic ligands, carbonyl ligand, alkene ligands, alkyne ligands, amine ligand, imine ligand, isonitrile ligand, phosphine ligand, phosphineoxide ligand, phosphite ligand, ether ligand, sulfone ligand, sulfoxide ligand, sulfide ligand and the like. All of the ligands may be substituted with a halogen atom such as fluorine, chlorine and the like.

The alkyl group, alkoxy group, alkylthio group, aryl group, aryloxy group, arylthio group, acyl group, amide group and acid imide group are the same groups as described above.

The heterocyclic ligand may be zerovalent or monovalent, and examples of the zerovalent ligand include 2,2′-bipyridyl, 1,10-phenanthroline, 2-(4-thiophen-2-yl)pyridine, 2-(benzothiophen-2-yl)pyridine and the like, and examples of the monovalent ligand include phenylpyridine, 2-(paraphenylphenyl)pyridine, 7-bromobenzo[h]quinoline, 2-(4-phenylthiophen-2-yl)pyridine, 2-phenylbenzooxazole, 2-(paraphenylphenyl)benzooxazole, 2-phenylbenzothiazole, 2-(paraphenylphenyl)benzothiazole and the like.

Examples of the carbonyl ligand include carbon monoxide, ketones such as acetone, benzophenone and the like, diketones such as acetylacetone, acenaphthoquinone and the like, acetonate ligands such as acetyl acetonate, dibenzo methylate, thenoyltrifluoro acetonate and the like.

The alkene ligand is not particularly restricted and examples thereof include ethylene, propylene, butane, hexene, decene and the like.

The alkyne ligand is not particularly restricted and examples thereof include acetylene, phenylacetylene, diphenylacetylene and the like.

The amine ligand is not particularly restricted and examples thereof include triethylamine, tributylamine and the like.

The imine ligand is not particularly restricted and examples thereof include benzophenoneimine, methyl ethyl ketone imine and the like.

The isonitrile ligand is not particularly restricted and examples thereof include t-butylisonitrile, phenylisonitrile and the like.

The phosphine ligand is not particularly restricted and examples thereof include triphenylphosphine, tritolylphosphine, tricyclohexylphosphine, tributylphosphine and the like.

The phosphine oxide ligand is not particularly restricted and examples thereof include tributylphosphine oxide, triphenylphoshpine oxide and the like.

The phosphite ligand is not particularly restricted and examples thereof include triphenylphosphite, tritolylphosphite, tributylphosphite, triethylphosphite and the like.

The ether ligand is not particularly restricted and examples thereof include dimethyl ether, diethyl ether, tetrahydrofuran and the like.

The sulfone ligand is not particularly restricted and examples thereof include dimethylsulfone, dibutylsulfone and the like.

The sulfoxide ligand is not particularly restricted and examples thereof include dimethyl sulfoxide, dibutyl sulfoxide and the like.

The sulfide ligand is not particularly restricted and examples thereof include ethyl sulfide, butyl sulfide and the like.

Examples of the monodentate ligand in the metal complex (B″) include aryl groups, aryloxy groups, arylthio groups, arylalkyloxy groups, arylalkylthio groups, arylalkenyl groups, arylalkynyl groups, heterocyclic groups and the like, and all of the ligands may be substituted by a halogen atom such as fluorine, chlorine and the like.

The monodentate ligand preferably has an aromatic ring, and further, it is preferable that the coordinated atom in the aromatic ring is carbon or nitrogen or the aromatic ring is a condensed ring.

From the standpoint of light emission efficiency, the monodentate ligand in which the coordinated atom in the aromatic ring is carbon or nitrogen is preferably a compound or group containing a structure of the following formula (S-1).

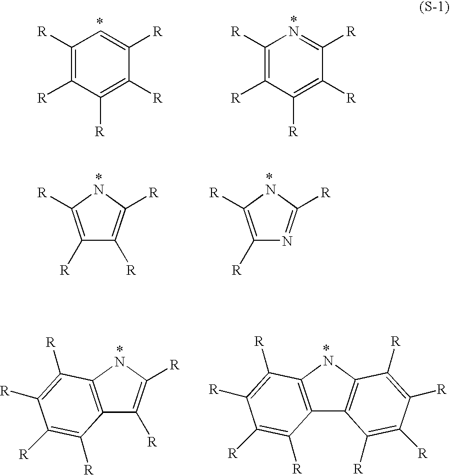

### (In the above-described formula (S-1), * represents an atom coordinated to a metal, and R represents the same meaning as described above.)

From the standpoint of light emission efficiency, the monodentate ligand which is a condensed ring is preferably a compound or group containing a structure of the following formula (S-2).

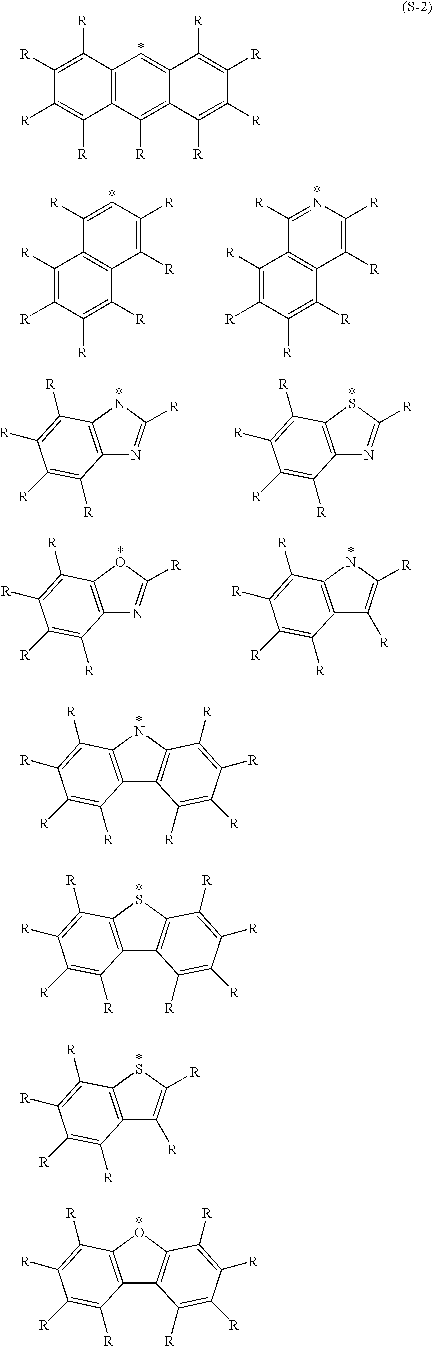

### (In the above-described formula (S-2), * represents an atom coordinated to a metal, and R represents the same meaning as described above.)

From the standpoint of synthesis, R represents preferably a hydrogen atom, alkyl group, alkoxy group or halogen atom in the formulae (S-1) and (S-2).

Particularly when tridentate ligands of the following formulae (B′-1) to (B′-3) do not contain a condensed ring, it is preferable that the monodentate ligand has a condensed ring.

The metal complexes (B′) and (B″) are preferably metal complexes having a structure of the following general formula (B′-1), (B′-2) or (B′-3) and a monodentate ligand.

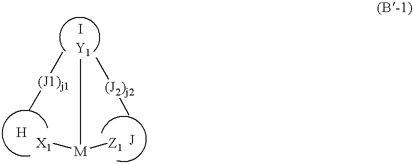

(wherein, M represents a metal selected from transition metals of IV and V periods and W, Os, Ir, Au and lanthanoids, H ring, I ring and J ring represent each independently an aromatic ring, and X₁, Y₁ and Z₁ present in each ring structure represent each independently an atom coordinated to the metal M. J1 and J2 represent each independently an alkylene group having 1 to 6 carbon atoms, alkenylene group having 2 to 6 carbon atoms or alkynylene group having 2 to 6 carbon atoms, and carbon atoms in the alkylene group, alkenylene group and alkynylene group may each be substituted with an oxygen atom or sulfur atom. j1 and j2 represent each independently 0 or 1.).

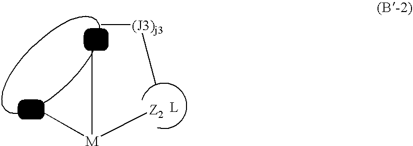

(wherein, M represents a metal selected from transition metals of IV and V periods and W, Os, Ir, Au and lanthanoids, K ring and L ring represent each independently an aromatic ring, X₂, Y₂ and Z₂ present in each ring structure represent each independently an atom coordinated to the metal M, J3 represents an alkylene group having 1 to 6 carbon atoms, alkenylene group having 2 to 6 carbon atoms or alkynylene group having 2 to 6 carbon atoms, carbon atoms in the alkylene group, alkenylene group and alkynylene group may each be substituted with an oxygen atom or sulfur atom, and j3 represents 0 or 1.).

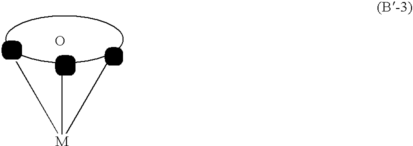

(wherein, M represents a metal selected from transition metals of IV and V periods and W, Os, Ir, Au and lanthanoids, O ring represents an aromatic ring, and X₃, Y₃ and Z₃ present in the ring structure represent each independently an atom coordinated to the metal M.).

M in the above-mentioned formula (B′-1) is a metal selected from transition metals of IV and V periods and W, Os, Ir, Au and lanthanoids, and specific examples thereof include Sc, Ti, Cr, Mn, Fe, Co, Ni, Cu, Zn, Y, Zr, Nb, Mo, Tc, Ru, Rh, Pd, Ag, Hf, Ta, W, Os, Ir, Au, La, Ce, Pr, Nd, Pm, Sm, Eu, Gd, Tb, Dy, Ho, Er, Tm, Yb and Lu, and from standpoint of obtaining higher efficiency, Ru, Rh, W, Os, Ir, Au, Eu and Tb are preferable, W, Os, Ir and Au are more preferable, W and Au are further preferable, and Au is most preferable.

H ring, I ring and J ring in the above-mentioned formula (B′-1) represent each independently an aromatic ring.

As the aromatic ring, aromatic hydrocarbon rings and heteroaromatic rings are listed. The aromatic ring may be a monocyclic ring or condensed ring.

As the monocyclic aromatic hydrocarbon ring, for example, benzene is mentioned.

As the condensed aromatic hydrocarbon ring, for example, naphthalene, anthracene, phenanthrene and the like are mentioned.

As the monocyclic heteroaromatic ring, for example, pyridine, pyrimidine, pyridazine, quinoline and the like are mentioned.

As the condensed heteroaromatic ring, for example, quinoxaline, phenanthroline, carbazole, dibenzofuran, dibenzothiophene, dibenzosilol and the like are mentioned.

X₁ in H ring, X₂ in I ring and X₃ in J ring in the formula (B′-1) represent an atom coordinated to a metal (M) contained in each ring structure.

As the coordination atom, mentioned are a carbon atom, nitrogen atom, oxygen atom, silicon atom, sulfur atom, phosphorus atom, arsenic atom and selenium atom, and preferable are a carbon atom, nitrogen atom, oxygen atom, silicon atom, sulfur atom and phosphorus atom, further preferable are a carbon atom, nitrogen atom, oxygen atom and sulfur atom.

As specific examples of I ring, the following moieties are listed as aromatic hydrocarbon rings.

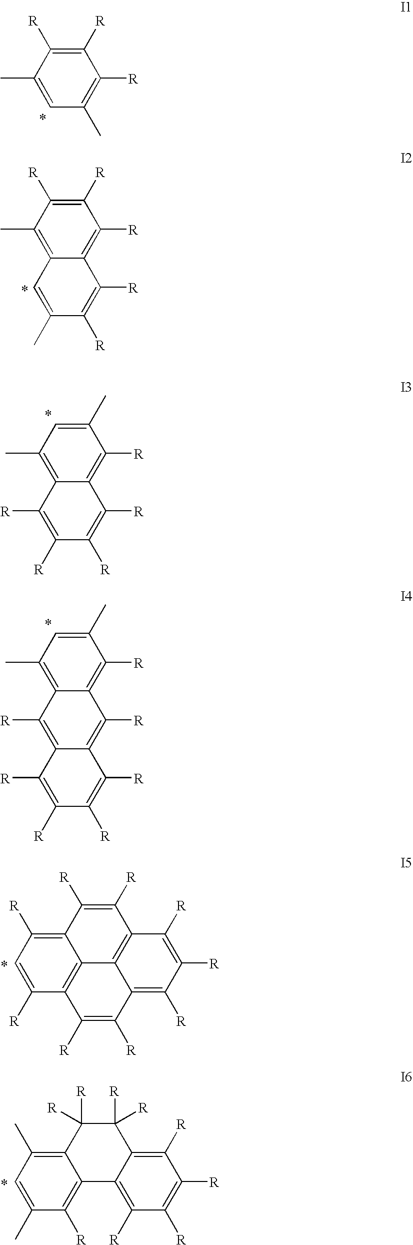

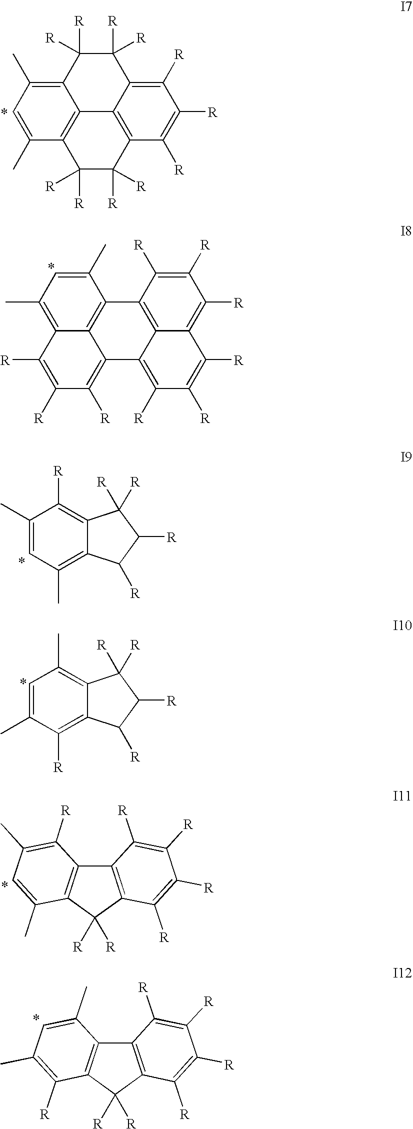

R in the above-mentioned moieties represents the same meaning as described above, and a plurality of Rs may be the same or different. In the drawings, * represents a position to be connected to a central metal M.

As specific examples of I ring, the following moieties are listed as heteroaromatic rings (I13 to I62).

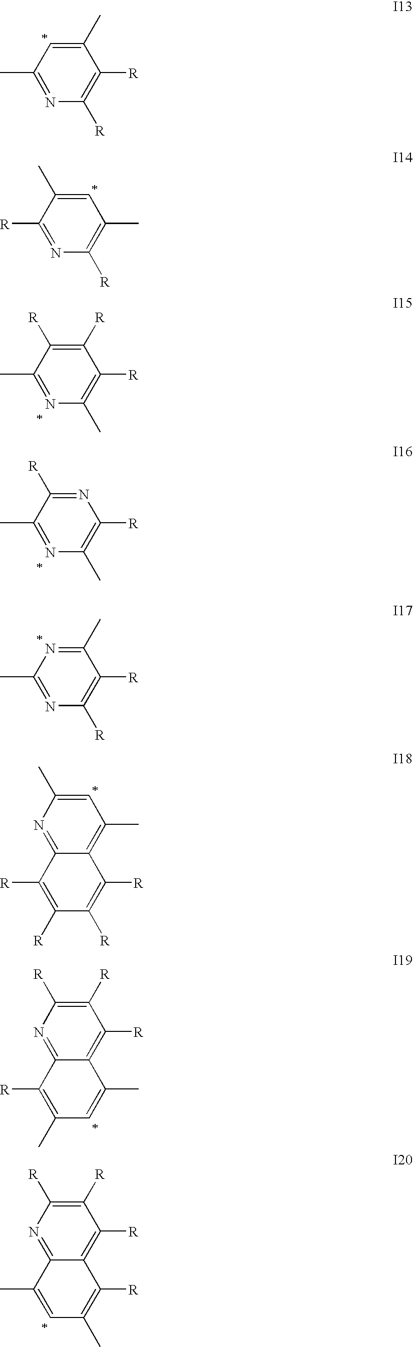

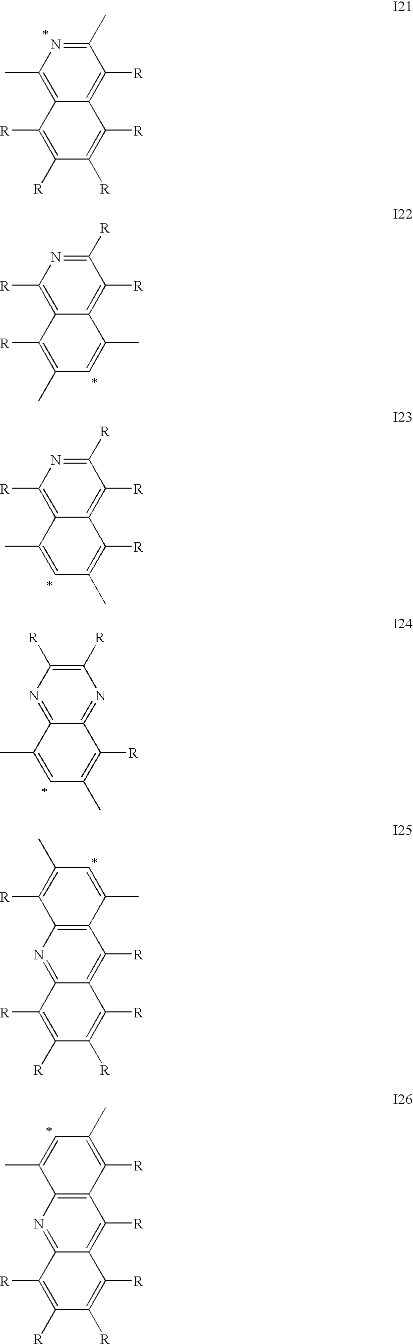

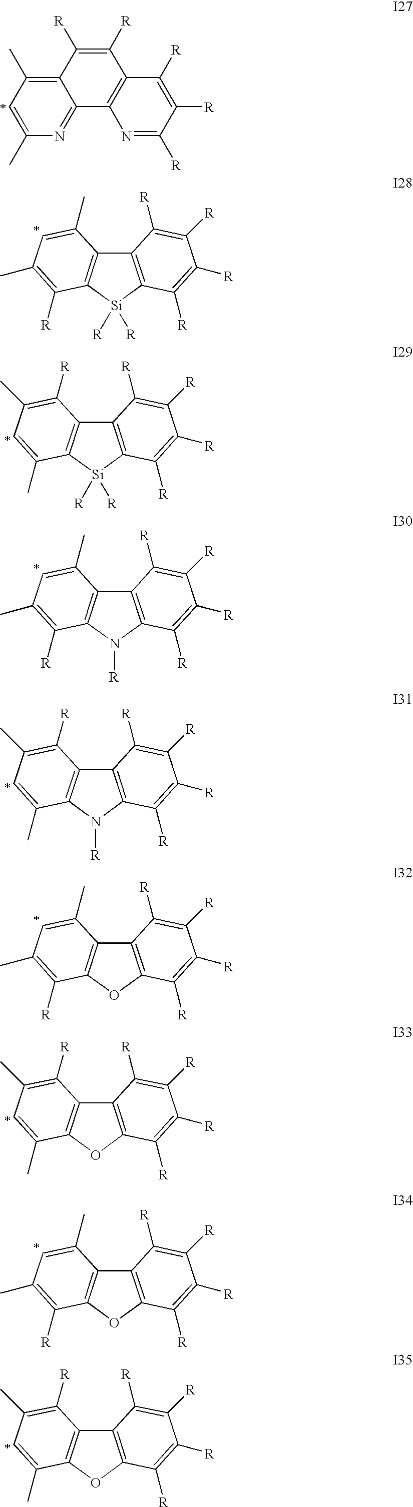

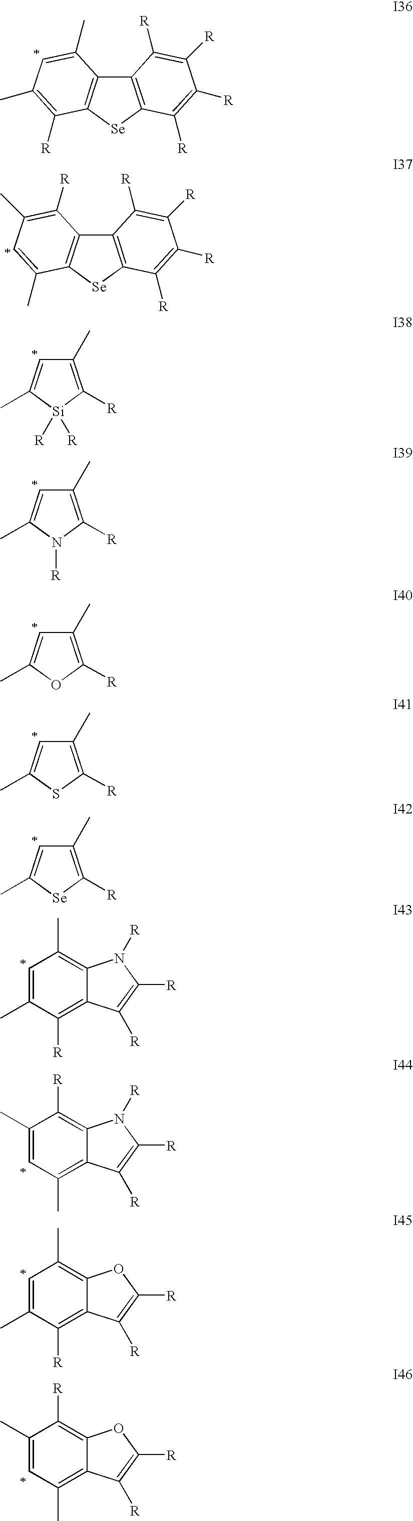

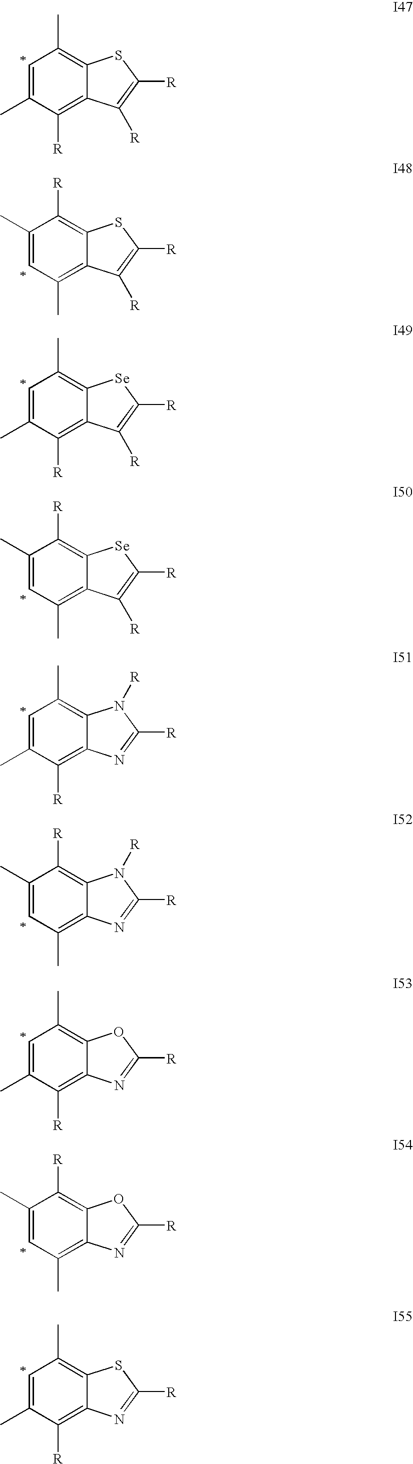

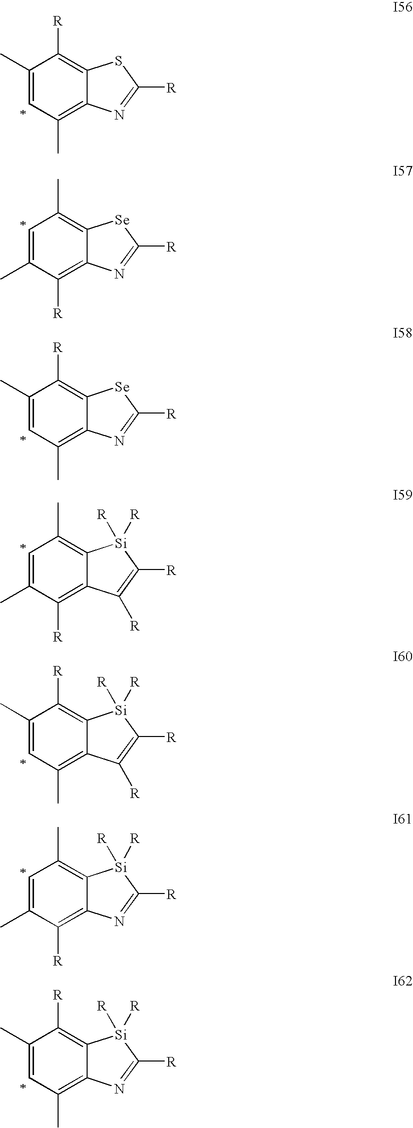

In the above-mentioned formulae, * represents the same meaning as described above.

As the specific examples of H ring and J ring, there are exemplified groups obtained by substituting one of connecting bonds in the above-mentioned specific examples of I ring by a substituent R.

In the formula (B′-1), j1 and J2 represent each independently 0 or 1, and J1 and J2 represent each independently an alkylene group having 1 to 6 carbon atoms, alkenylene group having 2 to 6 carbon atoms or alkynylene group having 2 to 6 carbon atoms, and carbon atoms in the alkylene group, alkenylene group and alkynylene group may each be substituted with an oxygen atom or sulfur atom.

Here, as the alkylene group having 1 to 6 carbon atoms, mentioned are —CH₂—, —C₂H₄—, —C₃H₆— and —C₄H₈—. As those obtained by substituting a carbon atom (or part thereof) with oxygen, mentioned are —OCH₂— and —CH₂OC₂H₄—, and as those obtained by substituting a carbon atom (or part thereof) with sulfur, mentioned are —SCH₂— and —CH₂SC₂H₄—.

As the alkenylene group having 2 to 6 carbon atoms, mentioned are —CH═CH—CH₂—, —CH═CH—C₂H₄— and —CH₂—CH═CH—C₂H₄—. As those obtained by substituting a carbon atom (or part thereof) with oxygen, mentioned is —CH═CH—CH₂O—, and as those obtained by substituting a carbon atom (or part thereof) with sulfur, mentioned is —CH═CH—CH₂S—.

As the alkynylene group having 2 to 6 carbon atoms, mentioned are —C═C—CH₂—, —C═C—C₂H₄— and —CH₂—C═C—C₂H₄—. As those obtained by substituting a carbon atom (or part thereof) with oxygen, mentioned is —HC═CH—CH₂O—, and as those obtained by substituting a carbon atom (or part thereof) with sulfur, mentioned is —HC═CH—CH₂S—.

As the tridentate ligand in the above-mentioned formula (B′-1), the following moieties are exemplified.

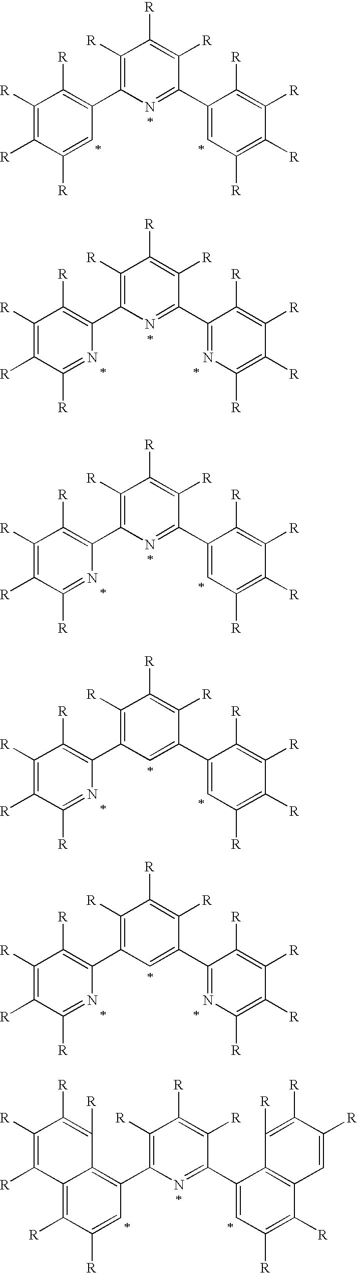

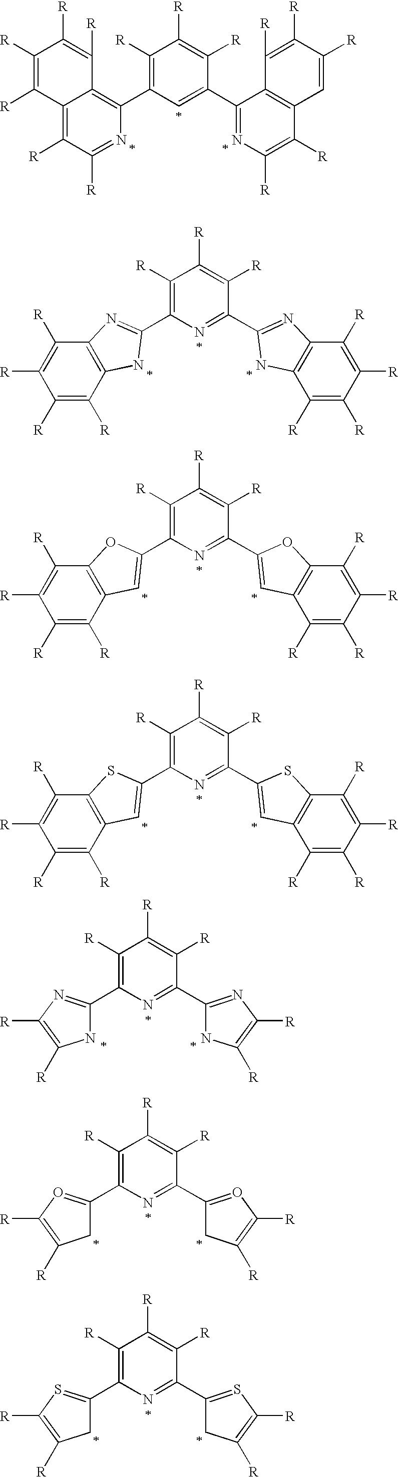

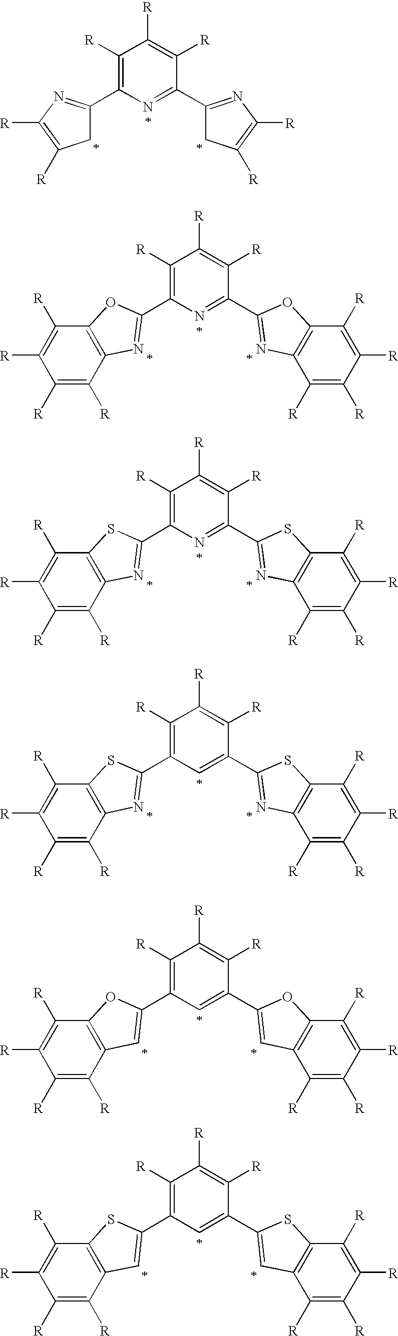

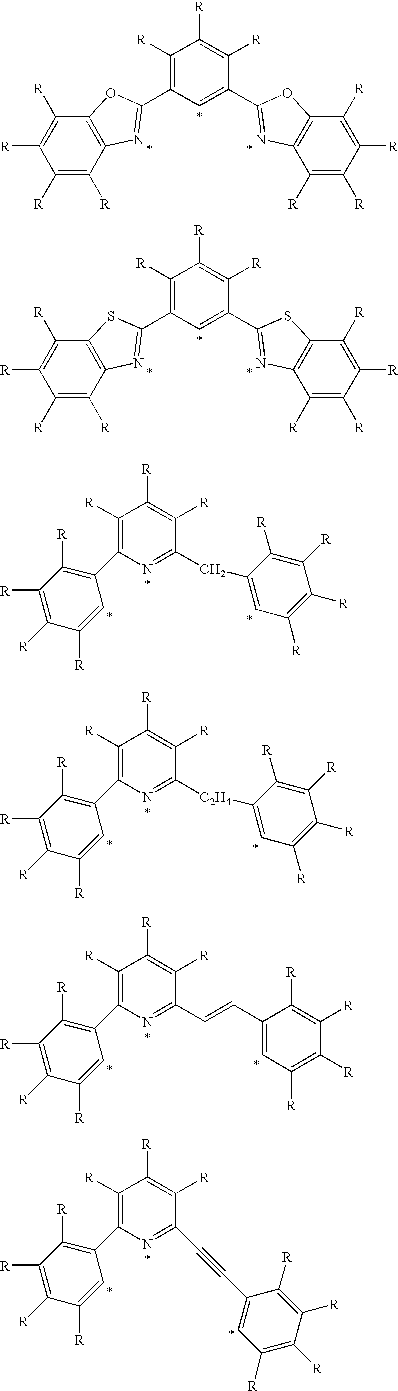

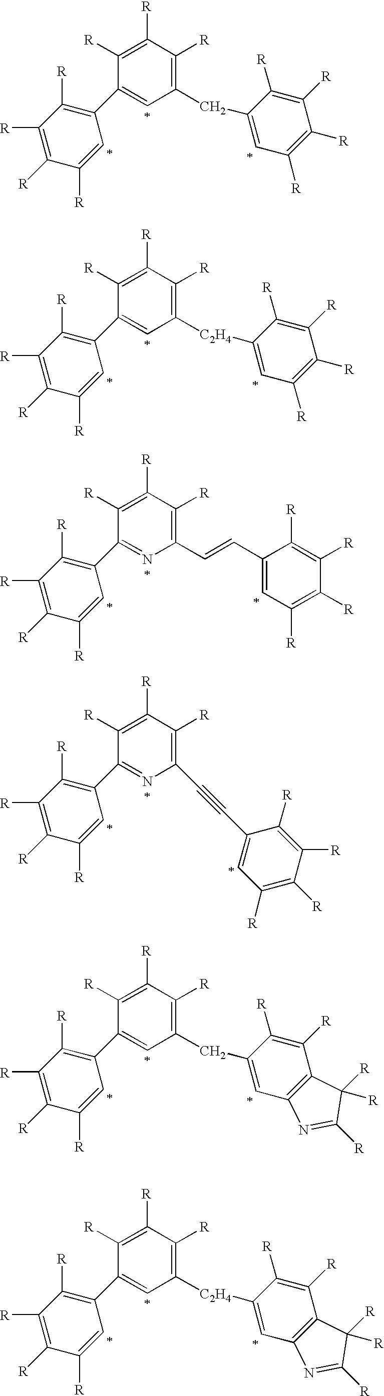

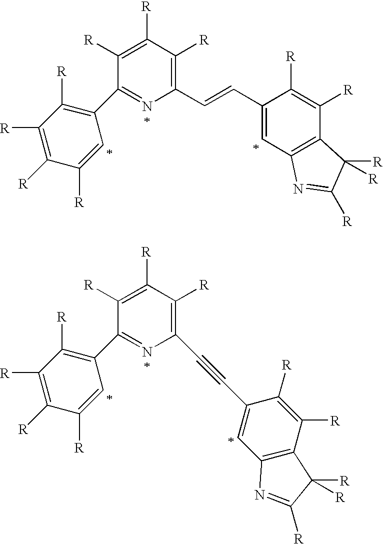

In the above-mentioned formulae, R and * represent the same meanings as described above.

From the standpoint of synthesis, it is preferable that H ring, I ring and J ring represent a monocyclic aromatic hydrocarbon ring or monocyclic hetero ring.

Next, metal complexes having a structure of the formula (B′-2) will be explained.

M in the above-mentioned formula (B′-2) is a metal selected from transition metals of IV and V periods and W, Os, Ir, Au and lanthanoids, and specific examples thereof include Sc, Ti, Cr, Mn, Fe, Co, Ni, Cu, Zn, Y, Zr, Nb, Mo, Tc, Ru, Rh, Pd, Ag, Hf, Ta, W, Os, Ir, Au, La, Ce, Pr, Nd, Pm, Sm, Eu, Gd, Tb, Dy, Ho, Er, Tm, Yb and Lu, and from standpoint of obtaining higher efficiency, Ru, Rh, W, Os, Ir, Au, Eu and Tb are preferable, W, Os, Ir and Au are more preferable, W and Au are further preferable, and Au is most preferable.

K ring and L ring in the formula (B′-2) represent each independently an aromatic ring, and X₂, Y₂ and Z₂ present in each ring structure represent each independently an atom coordinated to a metal M, J3 represents an alkylene group having 1 to 6 carbon atoms, alkenylene group having 2 to 6 carbon atoms or alkynylene group having 2 to 6 carbon atoms, carbon atoms in the alkylene group, alkenylene group and alkynylene group may each be substituted with an oxygen atom or sulfur atom, and j3 represents 0 or 1.

Here, the definitions and specific examples of the aromatic ring, alkylene group having 1 to 6 carbon atoms, alkenylene group having 2 to 6 carbon atoms or alkynylene group having 2 to 6 carbon atoms are the same as the definitions and specific examples thereof in the formula (B′-1).

As K ring, the following rings are exemplified, and from the standpoint of stability of a complex, condensed rings are preferable.

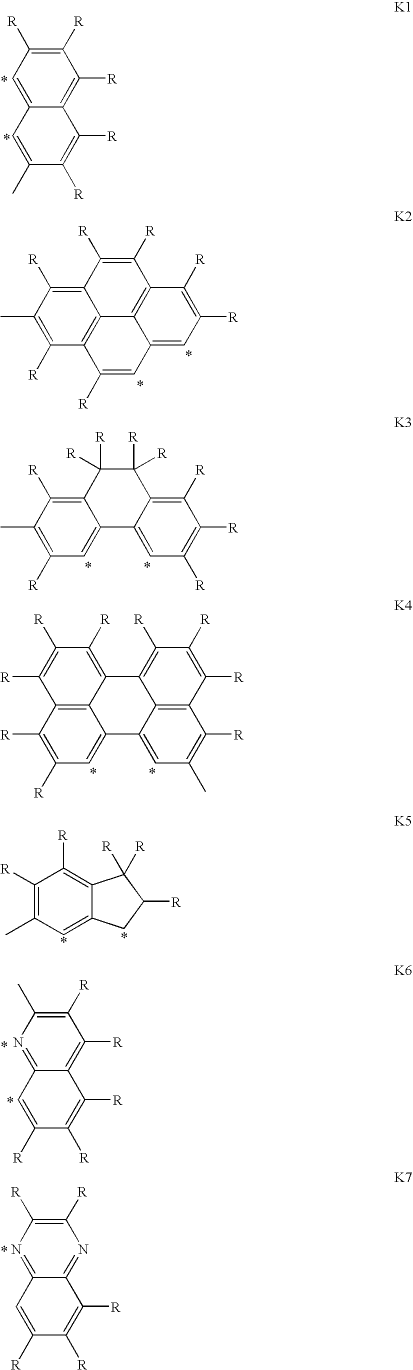

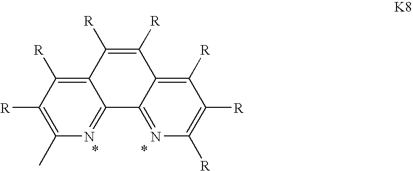

In the above-mentioned formulae, R and * represent the same meanings as described above.

As the specific examples of L ring, there are exemplified groups obtained by substituting one of connecting bonds in I1 to I62 by a substituent R, and from the standpoint of synthesis, monocyclic aromatic hydrocarbon rings or monocyclic hetero rings are preferable.

As the tridentate ligand in the above-mentioned formula (B′-2), the following moieties are exemplified.

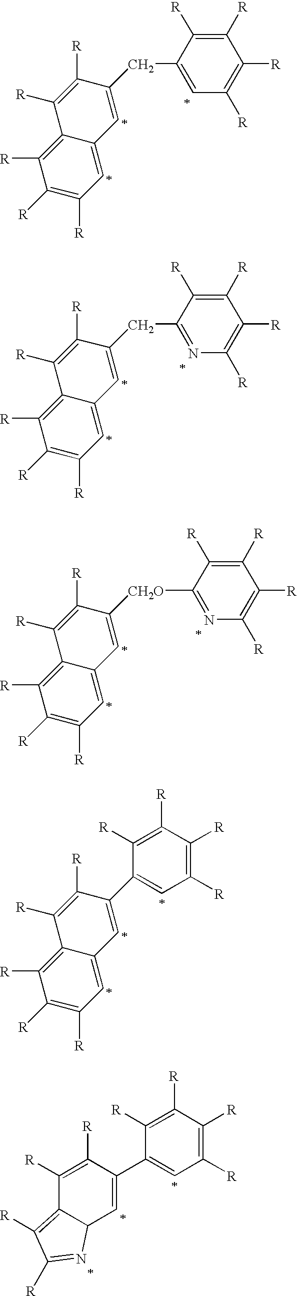

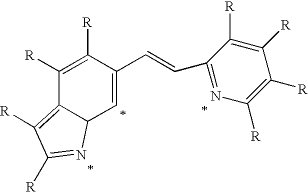

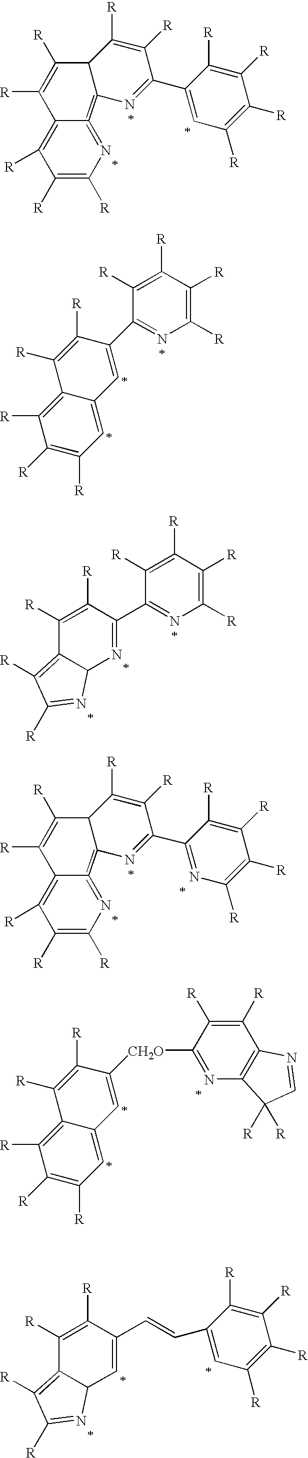

Next, metal complexes having a structure of the formula (B′-3) will be explained.

M in the above-mentioned formula (B′-3) is a metal selected from transition metals of IV and V periods and W, Os, Ir, Au and lanthanoids, and specific examples thereof include Sc, Ti, Cr, Mn, Fe, Co, Ni, Cu, Zn, Y, Zr, Nb, Mo, Tc, Ru, Rh, Pd, Ag, Hf, Ta, W, Os, Ir, Au, La, Ce, Pr, Nd, Pm, Sm, Eu, Gd, Tb, Dy, Ho, Er, Tm, Yb and Lu, and from standpoint of obtaining higher efficiency, Ru, Rh, W, Os, Ir, Au, Eu and Tb are preferable, W, Os, Ir and Au are more preferable, W and Au are further preferable, and Au is most preferable.

O ring represents an aromatic ring, and X₃, Y₃ and Z₃ present in each ring structure represent each independently an atom coordinated to a metal M.

Here, the definitions and specific examples of the aromatic ring are the same as the definitions and specific examples thereof in the formula (B′-1).

As the specific examples of O ring, namely, as the tridentate ligand of the above-mentioned formula (B′-3), the following moieties are mentioned, and from the standpoint of stability of a complex, condensed rings are preferable.

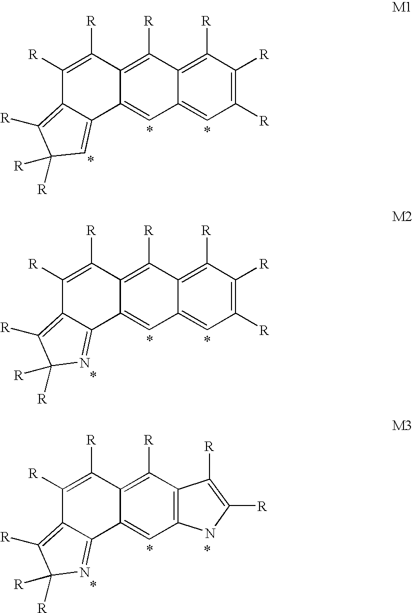

In the above-mentioned formulae, R and * represent the same meanings as described above.

Metal complex compounds having a structure of the above-mentioned formulae (B′-1) to (B′-3) may have two tridentate ligands, or may have a bidentate ligand in addition to one tridentate ligand and monodentate ligand.

The bidentate ligand is not particularly restricted, and for example, there are mentioned phenylpyridine, phenanthroline and phenylquinoline optionally substituted with an alkyl group or halogen atom, and bidentate ligands described in Patent Application National Publication No. 2003-515897, and the like.

Light emission from the metal complex of the present invention is not particularly restricted, and from the standpoint of obtaining higher efficiency, it is preferable that light emission from MLCT excited state (Metal to Ligang charge transfer excited state) is included.

Next, methods for synthesizing the metal complexes (B′) and (B″) of the present invention will be explained.

When halides of metals and hydrates are stably available, a metal salt and a ligand are heated in a suitable solvent such as alcohol and the like, and an intermediate M(L₁)(L₂) can be synthesized through a de-HX (X=halogen ion derived from metal salt) reaction typified by an ortho-metallization reaction. Here, L₁ represents the tridentate ligand described above, and L₂ represents a halogen ion derived from the metal salt. For example, a method described in non-patent document is exemplified as the synthesis method.

The same reaction can be applied not only to metal halides but also to general metal salts such as acetates, nitrates, sulfates, perchlorates and the like.

In addition to the method for synthesizing an intermediated by an ortho-metallization reaction of a metal halide, a synthesis method by oxidative addition of a ligand to a metal of lower valency can also be used. That is, if the metal ion of the intermediate M(L₁)(L₂) has a valency of n, then, M(L₁)(Z) can be obtained by an oxidative addition reaction using a (n−2)-valent metal metal M′ and L₁-Z. Here, metal M′ may have a substitution-active ligand such as phosphine and carbonyl, and Z represents a substituent liable to cause oxidative addition such as bromine and iodine, and should be substituted on a position connecting to a metal on L₁. Z is a ligand having the same substitution-activity as the L₂, thus, also the resultant M′ (L₁)(Z) can be used as an intermediate in the present invention.

The raw material M(L₁)(L₂) can be subjected to a ligand-exchange reaction in a suitable organic solvent, to convert a halogen ligand into the above-mentioned monodentate ligand. All the reactions described here are performed usually in an organic solvent, and as the solvent, for example, ether solvents such as diethyl ether, tetrahydrofuran, tertiary butyl methyl ether, dioxane and the like, hydrocarbon solvents such as hexane, cyclohexane, toluene, xylene and the like, ester solvents such as ethyl acetate, methyl propionate and the like, halogen solvents such as dichloromethane, chloroform, 1,2-dichloroethane and the like, ketone solvents such as acetone, methyl isobutyl ketone, diethyl ketone and the like, alcohol solvents such as ethanol, butanol, ethylene glycol, glycerine and the like are used. The use amount of the solvent is not particularly restricted, and usually about 10 to 500-fold by weight ratio based on the total weight of raw material complexes and ligands.

The reaction temperature is not particularly restricted and the reaction can be performed usually from the melting point of the solvent to the boiling point thereof and temperatures from −78° C. to the boiling point of the solvent are preferable.

The reaction time is not particularly restricted and it is usually from about 30 minutes to 30 hours.

In the synthesis operation, a solvent is placed into a flask and the flask is deaerated by bubbling with an inert gas, for example, a nitrogen gas or argon gas, then, a complex and a ligand are placed into this while stirring the solvent. While stirring, the temperature is raised up to temperatures at which ligand exchange is carried out under an inert gas atmosphere, and the reaction mixture is stirred under thermal insulation. Termination of the reaction can be determined by stop of reduction of raw materials or disappearance of either raw material using a TLC monitor or high performance liquid chromatography.

Removal of the intended substance from the reaction mixture and purification thereof vary depending on the complex, and usual complex purification methods are used.

For example, 1 N hydrochloric acid aqueous solution which is a poor solvent for a complex is added to cause deposition of the complex, and this is removed by filtration and this solid is dissolved in an organic solvent such as dichloromethane, chloroform and the like. This solution is filtrated to remove insoluble materials and concentrated again, and purified by silica gel column chromatography (dichloromethane elution), and fraction solutions of the intended substance are collected, and for example, methanol (poor solvent) is added in a suitable amount, and the solution is concentrated to cause deposition of the intended complex which is filtrated and dried, to obtain a complex.

Identification and analysis of the compound can be conducted by CHN elemental analysis and NMR.

The composition of the present invention contains the above-mentioned metal complex of the present invention and an organic compound.

The composition of the present invention represents a composition obtained by mixing other organic compound as a host compound for example, and as the host compound, polymers and lower molecular weight host compounds for metal complex phosphorescent emitting compounds known to date are mentioned.

As the lower molecular weight host compound, the following compounds are specifically mentioned.

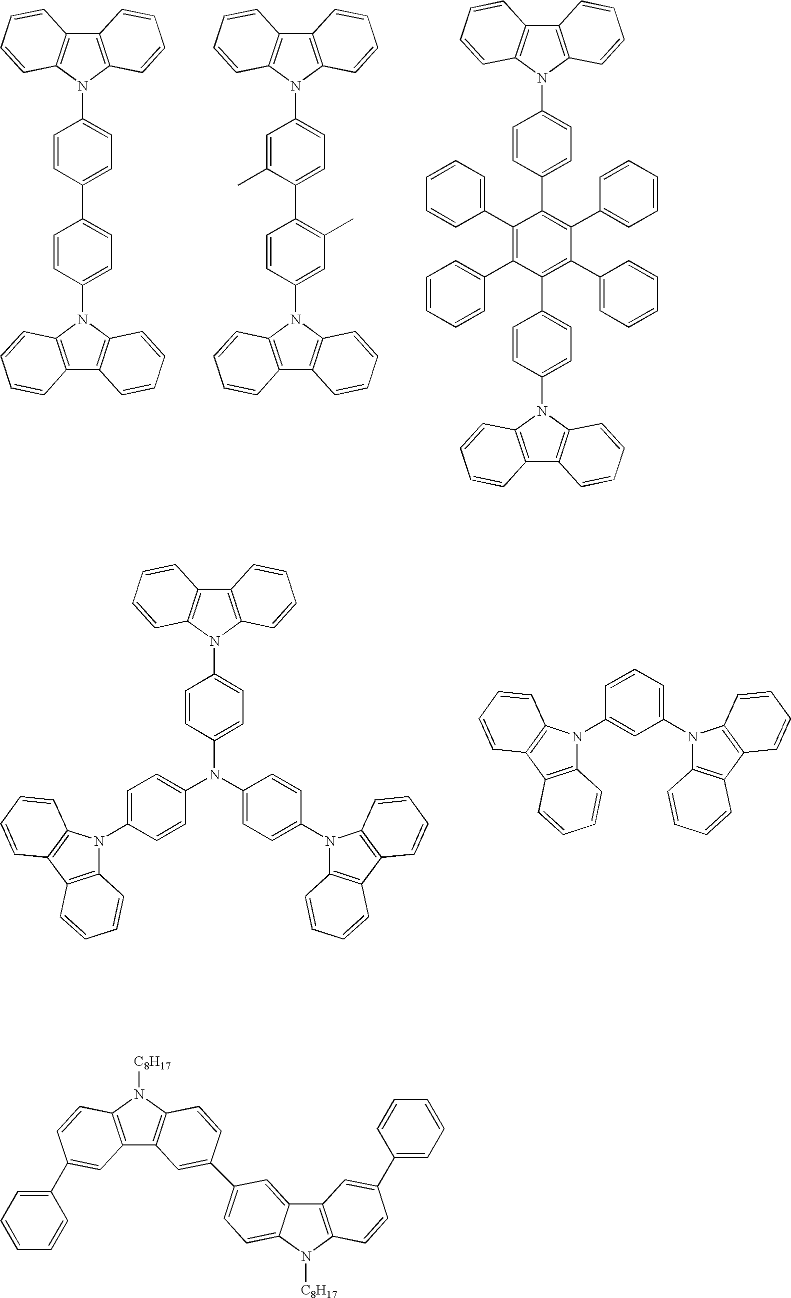

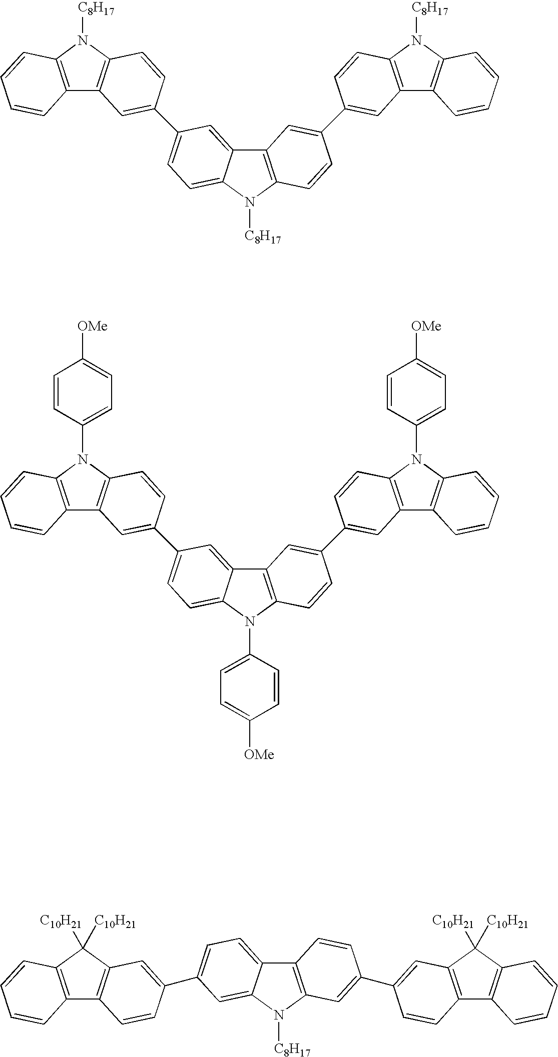

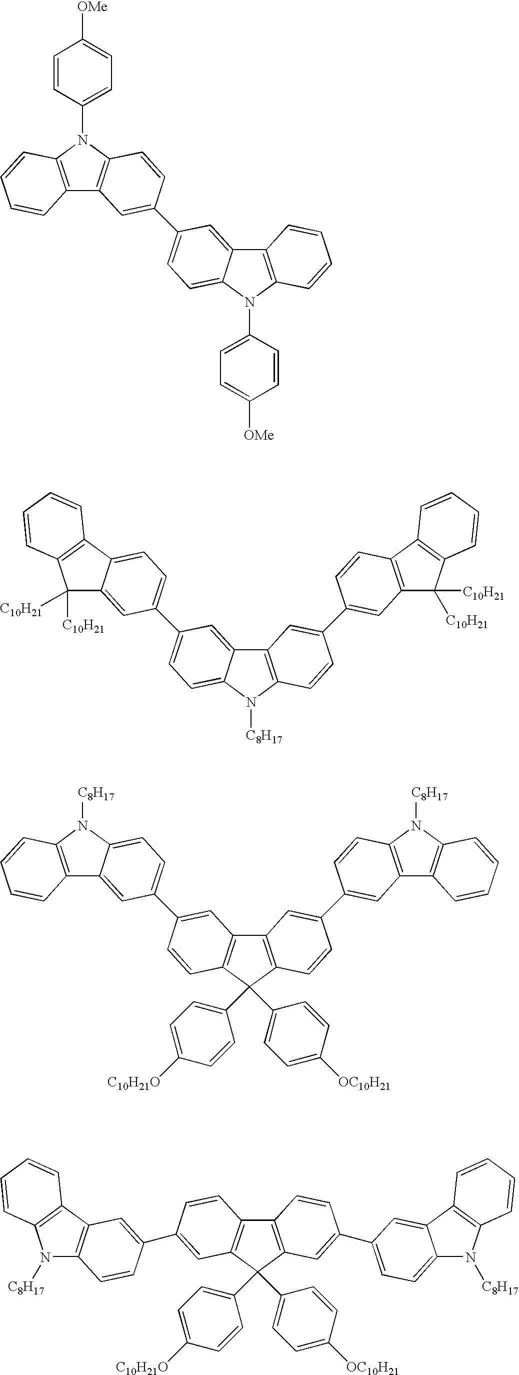

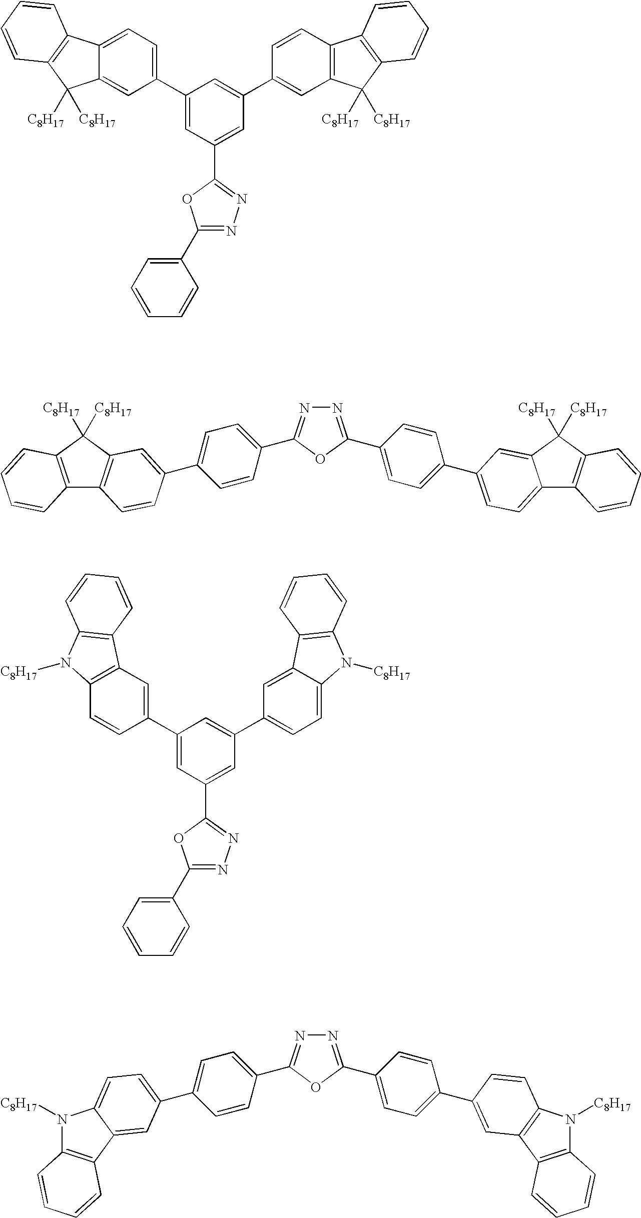

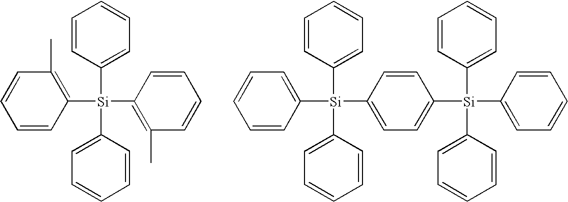

As the host compound, polymers can also be used. Mentioned as the polymer are non-conjugated polymers and conjugated polymers (A). As the non-conjugated polymer, polyvinylcarbazole and the like are mentioned.

The conjugated polymer has the same meaning as described above.

The polymer to be used as a host may be a conjugated polymer (A) having in the molecule a partial structure of a metal complex (B′) or (B″), or may be a polymer composition.

The conjugated polymer (A) having in the molecule a partial structure of a metal complex (B′) or (B″) is the same as a conjugated polymer (A) having in the molecule a partial structure of a metal complex (B).

The polymer to be used in the composition of the present invention has a polystyrene-reduced number-average molecular weight of preferably 10³ to 10⁸, further preferably 10⁴ to 10⁶. The polystyrene-reduced weight-average molecular weight is 103 to 108, preferably 5×10⁴ to 5×10⁶.

The metal complex of the present invention may be incorporated as a partial structure in the polymer. That is, the present invention relates to a polymer metal complex containing in the molecule a structure of the metal complex of the present invention. pAs the polymer into which a metal complex is incorporated, polymers described above as the polymer to be used as the composition of the present invention are exemplified likewise.

The amount of a metal complex in the composition of the present invention is not particularly restricted since the amount varies depending on the kind of an organic compound to be combined and on properties to be optimized, and usually 0.01 to 80 parts by weight, preferably 0.1 to 60 parts by weight when the amount of the organic compound is 100 parts by weight. Further, two or more metal complexes may be contained.

The composition of the present invention may further contain at least one material selected from hole transporting materials, electron transporting materials and light emitting materials.

As the hole transporting material, there are mentioned materials as used to date as a hole transporting material in an organic EL device such as aromatic amines, carbazole derivatives, polyparaphenylene derivatives and the like.

As the electron transporting material, there are mentioned materials as used likewise to date as an electron transporting material in an organic EL device such as oxadiazole derivatives, anthraquinodimethane or derivatives thereof, benzoquinone or derivatives thereof, naphthoquinone or derivatives thereof, anthraquinone or derivatives thereof, tetracyanoanthraquinodimethane or derivatives thereof, fluorenone derivatives, diphenyldicyanoethylene or derivatives thereof, diphenoquinone derivatives, and metal complexes of 8-hydroxyquinoline or derivatives thereof, and polyquinoline or derivatives thereof, polyquinoxaline or derivatives thereof, polyfluorene or derivatives thereof, and the like.

As the light emitting material, known materials can be used. Of lower molecular compounds, for example, naphthalene derivatives anthracene or derivatives thereof, perylene or derivatives thereof, coloring matters of polymethines, xanthenes, coumarins, cyanines and the like, metal complexes of 8-hydrozyquinoline or derivatives thereof, aromatic amines, tetraphenylcyclopentadiene or derivatives thereof, tetraphenylbutadiene or derivatives thereof, and the like can be used.

The polymer compound, polymer composition, metal complex or composition to be used in the present invention can be used not only as a light emitting material but also as an organic semiconductor material or optical material, or as an electrically conductive material by doping.

Next, the device of the present invention will be explained.

The device of the present invention is characterized in that a layer containing the polymer compound, polymer composition, metal complex or composition of the present invention is inserted between electrodes composed of an anode and a cathode.

As the device of the present invention, light emitting devices, photoelectric devices and the like are mentioned.

When the device of the present invention is a light emitting device, it is preferable that the layer containing the polymer compound, polymer composition, metal complex or composition of the present invention is an organic layer, further, is a light emitting layer, namely, light-emitting thin film.

Moreover, the polymer LED of the present invention include: a polymer LED having an electron transporting layer between a cathode and a light emitting layer; a polymer LED having an hole transporting layer between an anode and a light emitting layer; and a polymer LED having an electron transporting layer between an cathode and a light emitting layer, and a hole transporting layer between an anode and a light emitting layer.

Furthermore, exemplified are: a polymer-LED in which a layer containing a conductive polymer is disposed between at least one of the above electrodes and a light emitting layer adjacently to the electrode; and a polymer LED in which a buffer layer having a mean film thickness of 2 nm or less is disposed between at least one of the above electrodes and a light emitting layer adjacently to the electrode.

Specifically, the following structures a)-d) are exemplified.

a) anode/light emitting layer/cathode
b) anode/hole transporting layer/light emitting layer/cathode
c) anode/light emitting layer/electron transporting layer/cathode
d) anode/hole transporting layer/light emitting layer/electron transporting layer/cathode
(wherein, “/” indicates adjacent lamination of layers. Hereinafter, the same).

Herein, the light emitting layer is a layer having function to emit a light, the hole transporting layer is a layer having function to transport a hole, and the electron transporting layer is a layer having function to transport an electron. Herein, the electron transporting layer and the hole transporting layer are generically called a charge transporting layer.

The light emitting layer, hole transporting layer and electron transporting layer also may be used each independently in two or more layers.

Charge transporting layers disposed adjacent to an electrode, that having function to improve charge injecting efficiency from the electrode and having effect to decrease driving voltage of a device are particularly called sometimes a charge injecting layer (hole injecting layer, electron injecting layer) in general.

For enhancing adherence with an electrode and improving charge injection from an electrode, the above-described charge injecting layer or insulation layer having a thickness of 2 nm or less may also be provided adjacent to an electrode, and further, for enhancing adherence of the interface, preventing mixing and the like, a thin buffer layer may also be inserted into the interface of a charge transporting layer and light emitting layer.

The order and number of layers laminated and the thickness of each layer can be appropriately applied while considering light emitting efficiency and life of the device.

In the present invention, as the polymer LED having a charge injecting layer (electron injecting layer, hole injecting layer) provided, there are listed a polymer LED having a charge injecting layer provided adjacent to a cathode and a polymer LED having a charge injecting layer provided adjacent to an anode.

For example, the following structures e) to p) are specifically exemplified.

e) anode/charge injecting layer/light emitting layer/cathode
f) anode/light emitting layer/charge injecting layer/cathode
g) anode/charge injecting layer/light emitting layer/charge injecting layer/cathode
h) anode/charge injecting layer/hole transporting layer/light emitting layer/cathode
i) anode/hole transporting layer/light emitting layer/charge injecting layer/cathode
j) anode/charge injecting layer/hole transporting layer/light emitting layer/charge injecting layer/cathode
k) anode/charge injecting layer/light emitting layer/electron transporting layer/cathode
l) anode/light emitting layer/electron transporting layer/charge injecting layer/cathode
m) anode/charge injecting layer/light emitting layer/electron transporting layer/charge injecting layer/cathode
n) anode/charge injecting layer/hole transporting layer/light emitting layer/electron transporting layer/cathode
o) anode/hole transporting layer/light emitting layer/electron transporting layer/charge injecting layer/cathode
p) anode/charge injecting layer/hole transporting layer/light emitting layer/electron transporting layer/charge injecting layer/cathode

As the Concrete examples of the charge injecting layer, there are exemplified layers containing an conducting polymer, layers which are disposed between an anode and a hole transporting layer and contain a material having an ionization potential between the ionization potential of an anode material and the ionization potential of a hole transporting material contained in the hole transporting layer, layers which are disposed between a cathode and an electron transporting layer and contain a material having an electron affinity between the electron affinity of a cathode material and the electron affinity of an electron transporting material contained in the electron transporting layer, and the like.

When the above-described charge injecting layer is a layer containing an conducting polymer, the electric conductivity of the conducting polymer is preferably 10⁻⁵ S/cm or more and 10³ S/cm or less, and for decreasing the leak current between light emitting pixels, more preferably 10⁻⁵ S/cm or more and 10² S/cm or less, further preferably 10⁻⁵ S/cm or more and 10¹ S/cm or less.

Usually, to provide an electric conductivity of the conducting polymer of 10⁻⁵ S/cm or more and 10³ S/cm or less, a suitable amount of ions are doped into the conducting polymer.

Regarding the kind of an ion doped, an anion is used in a hole injecting layer and a cation is used in an electron injecting layer. As examples of the anion, a polystyrene sulfonate ion, alkylbenzene sulfonate ion, camphor sulfonate ion and the like are exemplified, and as examples of the cation, a lithium ion, sodium ion, potassium ion, tetrabutyl ammonium ion and the like are exemplified.

The thickness of the charge injecting layer is for example, from 1 nm to 100 nm, preferably from 2 nm to 50 nm.

Materials used in the charge injecting layer may properly be selected in view of relation with the materials of electrode and adjacent layers, and there are exemplified conducting polymers such as polyaniline and derivatives thereof, polythiophene and derivatives thereof, polypyrrole and derivatives thereof, poly(phenylene vinylene) and derivatives thereof, poly(thienylene vinylene) and derivatives thereof, polyquinoline and derivatives thereof, polyquinoxaline and derivatives thereof, polymers containing aromatic amine structures in the main chain or the side chain, and the like, and metal phthalocyanine (copper phthalocyanine and the like), carbon and the like.

The insulation layer having a thickness of 2 nm or less has function to make charge injection easy. As the material of the above-described insulation layer, metal fluoride, metal oxide, organic insulation materials and the like are listed. As the polymer LED having an insulation layer having a thickness of 2 nm or less, there are listed polymer LEDs having an insulation layer having a thickness of 2 nm or less provided adjacent to a cathode, and polymer LEDs having an insulation layer having a thickness of 2 nm or less provided adjacent to an anode.

Specifically, there are listed the following structures q) to ab) for example.

q) anode/insulation layer having a thickness of 2 nm or less/light emitting layer/cathode
r) anode/light emitting layer/insulation layer having a thickness of 2 nm or less/cathode
s) anode/insulation layer having a thickness of 2 nm or less/light emitting layer/insulation layer having a thickness of 2 nm or less/cathode
t) anode/insulation layer having a thickness of 2 nm or less/hole transporting layer/light emitting layer/cathode
u) anode/hole transporting layer/light emitting layer/insulation layer having a thickness of 2 nm or less/cathode
v) anode/insulation layer having a thickness of 2 nm or less/hole transporting layer/light emitting layer/insulation layer having a thickness of 2 nm or less/cathode
w) anode/insulation layer having a thickness of 2 nm or less/light emitting layer/electron transporting layer/cathode
x) anode/light emitting layer/electron transporting layer/insulation layer having a thickness of 2 nm or less/cathode
y) anode/insulation layer having a thickness of 2 nm or less/light emitting layer/electron transporting layer/insulation layer having a thickness of 2 nm or less/cathode
z) anode/insulation layer having a thickness of 2 nm or less/hole transporting layer/light emitting layer/electron transporting layer/cathode
aa) anode/hole transporting layer/light emitting layer/electron transporting layer/insulation layer having a thickness of 2 nm or less/cathode
ab) anode/insulation layer having a thickness of 2 nm or less/hole transporting layer/light emitting layer/electron transporting layer/insulation layer having a thickness of 2 nm or less/cathode

A hole preventing layer is a layer having a function of transporting electrons and confining the holes transported from anode, and the layer is prepared at the interface on the side cathode of the light emitting layer, and consists of a material having larger ionization potential than that of the light emitting layer, for example, a metal complex of bathocuproine, 8-hydroxy quinoline, or derivatives thereof.

The film thickness of the hole preventing layer, for example, is 1 nm to 100 nm, and preferably 2 nm to 50 nm.

Specifically, there are listed the following structures ac) to an) for example.

ac) anode/charge injection layer/light emitting layer/hole preventing layer/cathode
ad) anode/light emitting layer/hole preventing layer/charge injection layer/cathode
ae) anode/charge injection layer/light emitting layer/hole preventing layer/charge injection layer/cathode
af) anode/charge injection layer/hole transporting layer/light emitting layer/hole preventing layer/cathode
ag) anode/hole transporting layer/light emitting layer/hole preventing layer/charge injection layer/cathode
ah) anode/charge injection layer/hole transporting layer/light emitting layer/hole preventing layer/charge injection layer/cathode
ai) anode/charge injection layer/light emitting layer/hole preventing layer/charge transporting layer/cathode
aj) anode/light emitting layer/hole preventing layer/electron transporting layer/charge injection layer/cathode
ak) anode/charge injection layer/light emitting layer/hole preventing layer/electron transporting layer/charge injection layer/cathode
al) anode/charge injection layer/hole transporting layer/light emitting layer/hole preventing layer/charge transporting layer/cathode
am) anode/hole transporting layer/light emitting layer/hole preventing layer/electron transporting layer/charge injection layer/cathode
an) anode/charge injection layer/hole transporting layer/light emitting layer/hole preventing layer/electron transporting layer/charge injection layer/cathode

In producing a polymer LED, when a film is formed from a solution by using such complex composition or polymer complex compound of the present invention, only required is removal of the solvent by drying after coating of this solution, and even in the case of mixing of a charge transporting material and a light emitting material, the same method can be applied, causing an extreme advantage in production. As the film forming method from a solution, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like.

Regarding the ink composition (for example, used as a solvent in a printing method and the like), it is advantageous that the composition contains at least one polymer material of the present invention.

The ink composition contains usually a solvent in addition to the polymer material of the present invention, and may also contain a hole transporting material, electron transporting material, light emitting material, stabilizer, additive for controlling viscosity and/or surface tension, and additives such as an antioxidant and the like.

The proportion of a polymer material of the present invention in the ink composition is usually 20 wt % to 100 wt %, preferably 40 wt % to 100 wt % based on the total weight of the ink composition excepting a solvent.

The proportion of a solvent in the ink composition is 1 wt % to 99.9 wt %, preferably 60 wt % to 99.9 wt %, further preferably 90 wt % to 99.8 wt % based on the total weight of the ink composition.

The viscosity of the ink composition varies depending on a printing method, and is in the range of 0.5 to 500 mPa·s, preferably 1 to 100 mPa·s at 25° C., and when an ink composition passes through a discharge instrument such as in an ink jet printing method and the like, it is preferable that the viscosity at 25° C. is in the range of 1 to 20 mPa·s for preventing clogging in discharging and aviation curve.

As the solvent to be used in the ink composition, those capable of dissolving or uniformly dispersing a polymer compound, polymer composition, metal complex or composition of the present invention are preferable. Examples of the solvent include chlorine solvents such as chloroform, methylene chloride, 1,2-dichloroethane, 1,1,2-trichloroethane, chlorobenzene, o-dichlorobenzene and the like, ether solvents such as tetrahydrofuran, dioxane and the like, aromatic hydrocarbon solvents such toluene, xylene, trimethylbenzene, mesitylene and the like, aliphatic hydrocarbon solvents such as cyclohexane, methylcyclohexane, n-pentane, n-hexane, n-heptane, n-octane, n-nonane, n-decane and the like, ketone solvents such as acetone, methyl ethyl ketone, cyclohexanone and the like, ester solvents such as ethyl acetate, butyl acetate, methyl benzoate, ethylcellosolve acetate and the like, polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerine, 1,2-hexanediol and the like and derivatives thereof, alcohol solvents such as methanol, ethanol, propanol, isopropanol, cyclohexanol and the like, sulfoxide solvents such as dimethyl sulfoxide and the like, and amide solvents such as N-methyl-2-pyrrolidone, N,N-dimethylformamide and the like. These organic solvents can be used singly or in combination of two or more. Among the above-mentioned solvents, at least one organic solvent having a structure containing at least one benzene ring and having a melting point of 0° C. or lower and a boiling point of 100° C. or higher is preferably contained.

Regarding to the kind of the solvent, aromatic hydrocarbon solvents, aliphatic hydrocarbon solvent, ester solvents and ketone solvents are preferable from the standpoint of solubility into an organic solvent, uniformity in film formation, viscosity property and the like of a polymer compound, polymer composition, metal complex or composition of the present invention, and preferable are toluene, xylene, ethylbenzene, diethylbenzene, trimethylbenzene, mesitylene, n-propylbenzene, i-propylbenzene, n-butylbenzene, i-butylbenzene, s-butylbenzene, anisole, ethoxybenzene, 1-methylnaphthalene, cyclohexane, cyclohexanone, cyclohexylbenzene, bicyclohexyl, cyclohexenylcyclohexanone, n-heptylcyclohexane, n-hexylcyclohexane, methyl benzoate, 2-propylcyclohexanone, 2-heptanone, 3-heptanone, 4-heptanone, 2-octanone, 2-nonanone, 2-decanone and dicyclohexylketone, and it is more preferable that at least one of xylene, anisole, mesitylene, cyclohexylbenzene and bicyclohexyl methyl benzoate is contained.

The number of solvents in the ink composition is preferably 2 or more, more preferably 2 to 3, and further preferably 2, from the standpoint of film formability and from the standpoint of device properties and the like.

When 2 solvents are contained in the ink composition, one of the two solvents may be solid at 25° C. From the standpoint of film formability, it is preferable that one solvent has a boiling point of 180° C. or higher and another solvent has a boiling point of 180° C. or lower, and it is more preferable that one solvent has a boiling point of 200° C. or higher and another solvent has a boiling point of 180° C. or lower. From the standpoint of viscosity, it is preferable that both of the two solvents dissolve a polymer compound, polymer composition, metal complex or composition of the present invention in an amount of 0.2 wt % or more at 60° C., and it is preferable that one of the two solvents dissolves a polymer compound, polymer composition, metal complex or composition of the present invention in an amount of 0.2 wt % or more at 25° C.

When three kinds of solvents are contained in the ink composition, one or two of the solvents may be solid at 25° C. From the standpoint of film formability, it is preferable that at least one of the three kinds of solvents has a boiling point of 180° C. or higher and at least one solvent has a boiling point of 180° C. or lower, and it is more preferable that at least one of the three kinds of solvents has a boiling point of 200° C. or higher and 300° C. or lower and at least one solvent has a boiling point of 180° C. or lower. From the standpoint of viscosity, it is preferable that two of the three kinds of solvents dissolve a polymer compound, polymer composition, metal complex or composition of the present invention in an amount of 0.2 wt % or more at 60° C., and it is preferable that one of the three kinds of solvents dissolves a polymer compound, polymer composition, metal complex or composition of the present invention in an amount of 0.2 wt % or more at 25° C.

When two or more solvents are contained in the ink composition, the proportion of a solvent having the highest boiling point is preferably 40 to 90 wt %, more preferably 50 to 90 wt % and further preferably 65 to 85 wt % based on the weight of all solvents in the ink composition, from the standpoint of viscosity and film formability.

As the ink composition of the present invention, a composition composed of anisole and bicyclohexyl, a composition composed of anisole and cyclohexylbenzene, a composition composed of xylene and bicyclohexyl, a composition composed of xylene and cyclohexylbenzene and a composition composed of mesitylene and methyl benzoate are preferable, from the standpoint of viscosity and film formability.

Among additives which can be contained in the ink composition of the present invention, mentioned as the hole transporting material are polyvinylcarbazole or derivatives thereof, polysilane or derivatives thereof, polysiloxane derivatives having an aromatic amine at the side chain or main chain, pyrazoline derivatives, arylamine derivatives, stilbene derivatives, triphenyldiamine derivatives, polyaniline or derivatives thereof, polythiophene or derivatives thereof, polypyrrole or derivatives thereof, poly(p-phenylenevinylene) or derivatives thereof, or poly(2,5-thienylenevinylene) or derivatives thereof.

Mentioned as the electron transporting material are oxadiazole derivatives, anthraquinodimethane or derivatives thereof, benzoquinone or derivatives thereof, naphthoquinone or derivatives thereof, anthraquinone or derivatives thereof, tetracyanoanthraquinodimethane or derivatives thereof, fluorenone derivatives, diphenyldicyanoethylene or derivatives thereof, diphenoquinone derivatives, and metal complexes of 8-hydroxyquinoline or derivatives thereof, and polyquinoline or derivatives thereof, polyquinoxaline or derivatives thereof, polyfluorene or derivatives thereof.

As the light emitting material, naphthalene derivatives anthracene or derivatives thereof, perylene or derivatives thereof, coloring matters of polymethines, xanthenes, coumarins, cyanines and the like, metal complexes of 8-hydrozyquinoline or derivatives thereof, aromatic amines, tetraphenylcyclopentadiene or derivatives thereof, tetraphenylbutadiene or derivatives thereof, and the like are mentioned.

As the stabilizer, phenol antioxidants, phosphorus antioxidants and the like are mentioned.

As the additive for controlling viscosity and/or surface tension, higher molecular weight polymer compounds (thickening agents) and poor solvents for enhancing viscosity, lower molecular weight compounds for lowering viscosity, surfactants for lowering surface tension, and the like may be appropriately combined and used.

The above-mentioned higher molecular weight polymer compound is advantageously that which is soluble in the same solvent as for the polymer material of the present invention and does not disturb light emission and charge transportation. For example, polystyrene of higher molecular weight, polymethyl methacrylate, and polymer compounds of the present invention having higher molecular weight, and the like can be used. The weight-average molecular weight is preferably 500000 or more, and more preferably 1000000 or more. Poor solvents can also be used as a thickening agent. That is, viscosity can be enhanced by adding a small amount of poor solvent for solid content in a solution. When a poor solvent is added for this purpose, it is advantageous that the kind and addition amount of a solvent are so selected that the solid content in a solution does not deposit. When stability in preservation is also taken into consideration, the amount of a poor solvent is preferably 50 wt % or less, further preferably 30 wt % or less based on the whole solution.

The antioxidant is advantageously that which is soluble in the same solvent for the polymer material of the present invention and does not disturb light emission and charge transportation, and exemplified are phenol antioxidants, phosphorus antioxidants and the like. By using an antioxidant, preservation stability of the polymer material of the present invention and the solvent can be improved.

From the standpoint of solubility of the polymer material of the present invention into a solvent, it is preferable that the difference between solubility parameter of a solvent and solubility parameter of a polymer compound is 10 or less, and the difference is more preferably 7 or less.

The solubility parameter of a solvent and the solubility parameter of a polymer material of the present invention can be determined by a method described in “Solvent Handbook (published by Kodansha Ltd. Publisher, 1976)”.

The polymer compound, polymer composition, metal complex or composition of the present invention to be contained in the ink composition may be present singly or two or more of each compound may be present, and a polymer compound other than the polymer compound or polymer composition of the present invention may also be contained in a range not deteriorating device properties and the like.

The optimum value of the thickness of a light emitting layer varies depending on a material to be used, and the thickness is advantageously selected so that driving voltage and light emission efficiency shows suitable values, and for example, 1 nm to 1 μm, preferably 2 nm to 500 nm, further preferably 5 nm to 200 nm.

In the polymer LED of the present invention, a light emitting material other than the light emitting material of the present invention may also be mixed into a light emitting layer. In the polymer LED of the present invention, a light emitting layer containing a light emitting material other than the light emitting material of the present invention may be laminated with a light emitting layer containing the light emitting material of the present invention.

As the light emitting material, known materials can be used. In the case of the lower molecular weight compound, for example, naphthalene derivatives anthracene or derivatives thereof, perylene or derivatives thereof, coloring matters of polymethines, xanthenes, coumarins, cyanines and the like, metal complexes of 8-hydrozyquinoline or derivatives thereof, aromatic amines, tetraphenylcyclopentadiene or derivatives thereof, tetraphenylbutadiene or derivatives thereof, and the like can be used.

Specifically, known material such as those described in, for example, Japanese Patent Application Laid-Open (JP-A) Nos. 57-51781 and 59-194393 and the like can be used.

When the polymer LED of the present invention has a hole transporting layer, exemplified as the hole transporting material to be used are polyvinylcarbazole or derivatives thereof, polysilane or derivatives thereof, polysiloxane derivatives having an aromatic amine at the side chain or main chain, pyrazoline derivatives, arylamine derivatives, stilbene derivatives, triphenyldiamine derivatives, polyaniline or derivatives thereof, polythiophene or derivatives thereof, polypyrrole or derivatives thereof, poly(p-phenylenevinylene) or derivatives thereof, or poly(2,5-thienylenevinylene) or derivatives thereof, and the like.

Specifically, as the hole transporting material, those described in JP-A Nos. 63-70257, 63-175860, 2-135359, 2-135361, 2-209988, 3-37992, 3-152184, and the like are exemplified.

Among them, as the hole transporting material to be used in a hole transporting layer, preferable are polymer hole transporting materials such as polyvinylcarbazole or derivatives thereof, polysilane or derivatives thereof, polysiloxane derivatives having an aromatic amine compound group at the side chain or main chain, polyaniline or derivatives thereof, polythiophene or derivatives thereof, poly(p-phenylenevinylene) or derivatives thereof, or poly(2,5-thienylenevinylene) or derivatives thereof, and the like, and further preferable are polyvinylcarbazole or derivatives thereof, polysilane or derivatives thereof, and polysiloxane derivatives having an aromatic amine at the side chain or main chain. In the case of the lower molecular weight hole transporting material, it is preferable that material is dispersed in a polymer binder.

The polyvinylcarbazole or derivatives thereof are obtained by cation polymerization or radical polymerization from a vinyl monomer, for example.

As the polysilane or derivatives thereof, compounds described in Chem. Rev., vol. 89, p. 359 (1989) and GB Patent 2300196, and the like are exemplified. Also synthesis methods described in these documents can be used, and particularly, a Kipping method is suitably used.

As the polysiloxane or derivatives thereof, those having a structure of the lower molecular weight hole transporting material at the side chain or main chain are suitably used since the siloxane skeleton structure has little hole transportability. In particular, those having a hole transporting aromatic amine at the side chain or main chain are exemplified.

The method for film formation of the hole transporting layer is not particularly restricted, and in the case of the lower molecular weight hole transporting material, exemplified is a method for film formation from a mixed solvent with a polymer binder. In the case of the higher molecular weight hole transporting material, exemplified is a method for film formation from a solution.

The solvent to be used for film formation from a solution is not particularly restricted providing it can dissolve a hole transporting material. Exemplified as the solvent are chlorine solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethylcellosolve acetate and the like.

As the film formation method from a solution, coating methods can be used such as a spin coat method, casting method, micro-gravure coat method, gravure coat method, bar coat method, roll coat method, wire bar coat method, dip coat method, spray coat method, screen printing method, flexo printing method, offset printing method, ink jet printing method and the like from a solution.

The polymer binder mixed is preferably that does not disturb charge transport extremely, and that does not have strong absorption of a visible light is suitably used. As such polymer binder, polycarbonate, polyacrylate, poly(methyl acrylate), poly(methyl methacrylate), polystyrene, poly(vinyl chloride), polysiloxane and the like are exemplified.

Regarding the thickness of the hole transporting layer, the optimum value differs depending on material used, and may properly be selected so that the driving voltage and the light emitting efficiency become optimum values, and at least a thickness at which no pin hole is produced is necessary, and too large thickness is not preferable since the driving voltage of the device increases. Therefore, the thickness of the hole transporting layer is, for example, from 1 nm to 1 μm, preferably from 2 nm to 500 nm, further preferably from 5 nm to 200 nm.

When the polymer LED of the present invention has an electron transporting layer, known compounds are used as the electron transporting materials, and there are exemplified oxadiazole derivatives, anthraquinodimethane or derivatives thereof, benzoquinone or derivatives thereof, naphthoquinone or derivatives thereof, anthraquinone or derivatives thereof, tetracyanoanthraquinodimethane or derivatives thereof, fluorenone derivatives, diphenyldicyanoethylene or derivatives thereof, diphenoquinoline derivatives, or metal complexes of 8-hydroxyquinoline or derivatives thereof, polyquinoline and derivatives thereof, polyquinoxaline and derivatives thereof, polyfluorene or derivatives thereof, and the like.

Specifically, there are exemplified those described in JP-A Nos. 63-70257, 63-175860, 2-135359, 2-135361, 2-209988, 3-37992 and 3-152184.

Among them, oxadiazole derivatives, benzoquinone or derivatives thereof, anthraquinone or derivatives thereof, or metal complexes of 8-hydroxyquinoline or derivatives thereof, polyquinoline and derivatives thereof, polyquinoxaline and derivatives thereof, polyfluorene or derivatives thereof are preferable, and 2-(4-biphenyl)-5-(4-t-butylphenyl)-1,3,4-oxadiazole, benzoquinone, anthraquinone, tris(8-quinolinol)aluminum and polyquinoline are further preferable.

The method for forming the electron transporting layer is not particularly restricted, and in the case of an electron transporting material having lower molecular weight, a vapor deposition method from a powder, or a method of film-forming from a solution or melted state is exemplified, and in the case of a polymer electron transporting material, a method of film-forming from a solution or melted state is exemplified, respectively.

The solvent used in the film-forming from a solution is not particularly restricted provided it can dissolve electron transporting materials and/or polymer binders. As the solvent, there are exemplified chlorine solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethylcellosolve acetate and the like.

As the film-forming method from a solution or melted state, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like.

The polymer binder to be mixed is preferably that which does not extremely disturb a charge transport property, and that does not have strong absorption of a visible light is suitably used. As such polymer binder, poly(N-vinylcarbazole), polyaniline or derivatives thereof, polythiophene or derivatives thereof, poly(p-phenylene vinylene) or derivatives thereof, poly(2,5-thienylene vinylene) or derivatives thereof, polycarbonate, polyacrylate, poly(methyl acrylate), poly(methyl methacrylate), polystyrene, poly(vinyl chloride), polysiloxane and the like are exemplified.

Regarding the thickness of the electron transporting layer, the optimum value differs depending on material used, and may properly be selected so that the driving voltage and the light emitting efficiency become optimum values, and at least a thickness at which no pin hole is produced is necessary, and too large thickness is not preferable since the driving voltage of the device increases. Therefore, the thickness of the electron transporting layer is, for example, from 1 nm to 1 μm, preferably from 2 nm to 500 nm, further preferably from 5 nm to 200 nm.

The substrate forming the polymer LED of the present invention may preferably be that does not change in forming an electrode and layers of organic materials, and there are exemplified glass, plastics, polymer film, silicon substrates and the like. In the case of a opaque substrate, it is preferable that the opposite electrode is transparent or semitransparent.

Usually, at least one of the electrodes consisting of an anode and a cathode, is transparent or semitransparent. It is preferable that the anode is transparent or semitransparent.

As the material of this anode, electron conductive metal oxide films, semitransparent metal thin films and the like are used. Specifically, there are used indium oxide, zinc oxide, tin oxide, and composition thereof, i.e. indium/tin/oxide (ITO), and films (NESA and the like) fabricated by using an electron conductive glass composed of indium/zinc/oxide, and the like, and gold, platinum, silver, copper and the like. Among them, ITO, indium/zinc/oxide, tin oxide are preferable. As the fabricating method, a vacuum vapor deposition method, sputtering method, ion plating method, plating method and the like are used. As the anode, there may also be used organic transparent conducting films such as polyaniline or derivatives thereof, polythiophene or derivatives thereof and the like.

The thickness of the anode can be appropriately selected while considering transmission of a light and electric conductivity, and for example, from 10 nm to 10 μm, preferably from 20 nm to 1 μm, further preferably from 50 nm to 500 nm.

Further, for easy charge injection, there may be provided on the anode a layer comprising a phthalocyanine derivative conducting polymers, carbon and the like, or a layer having an average film thickness of 2 nm or less comprising a metal oxide, metal fluoride, organic insulating material and the like.

As the material of a cathode used in the polymer LED of the present invention, that having lower work function is preferable. For example, there are used metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like, or alloys comprising two of more of them, or alloys comprising one or more of them with one or more of gold, silver, platinum, copper, manganese, titanium, cobalt, nickel, tungsten and tin, graphite or graphite intercalation compounds and the like. Examples of alloys include a magnesium-silver alloy, magnesium-indium alloy, magnesium-aluminum alloy, indium-silver alloy, lithium-aluminum alloy, lithium-magnesium alloy, lithium-indium alloy, calcium-aluminum alloy and the like. The cathode may be formed into a laminated structure of two or more layers.

The thickness of the cathode can be appropriately selected while considering transmission of a light and electric conductivity, and for example, from 10 nm to 10 μm, preferably from 20 nm to 1 μm, further preferably from 50 nm to 500 nm.

As the method for fabricating a cathode, there are used a vacuum vapor deposition method, sputtering method, lamination method in which a metal thin film is adhered under heat and pressure, and the like. Further, there may also be provided, between a cathode and an organic layer, a layer comprising an conducting polymer, or a layer having an average film thickness of 2 nm or less comprising a metal oxide, metal fluoride, organic insulation material and the like, and after fabrication of the cathode, a protective layer may also be provided which protects the polymer LED. For stable use of the polymer LED for a long period of time, it is preferable to provide a protective layer and/or protective cover for protection of the device in order to prevent it from outside damage.

As the protective layer, there can be used a polymeric compound, metal oxide, metal fluoride, metal borate and the like. As the protective cover, there can be used a glass plate, a plastic plate the surface of which has been subjected to lower-water-permeation treatment, and the like, and there is suitably used a method in which the cover is pasted with a device substrate by a thermosetting resin or light-curing resin for sealing. If space is maintained using a spacer, it is easy to prevent a device from being injured. If an inner gas such as nitrogen and argon is sealed in this space, it is possible to prevent oxidation of a cathode, and further, by placing a desiccant such as barium oxide and the like in the above-described space, it is easy to suppress the damage of a device by moisture adhered in the production process. Among them, any one means or more are preferably adopted.

The polymer LED of the present invention can be used for a flat light source, a segment display, a dot matrix display, and a liquid crystal display as a back light, etc.

For obtaining light emission in plane form using the polymer LED of the present invention, an anode and a cathode in the plane form may properly be placed so that they are laminated each other. Further, for obtaining light emission in pattern form, there is a method in which a mask with a window in pattern form is placed on the above-described plane light emitting device, a method in which an organic layer in non-light emission part is formed to obtain extremely large thickness providing substantial non-light emission, and a method in which any one of an anode or a cathode, or both of them are formed in the pattern. By forming a pattern by any of these methods and by placing some electrodes so that independent on/off is possible, there is obtained a display device of segment type which can display digits, letters, simple marks and the like. Further, for forming a dot matrix device, it may be advantageous that anodes and cathodes are made in the form of stripes and placed so that they cross at right angles. By a method in which a plurality of kinds of polymeric compounds emitting different colors of lights are placed separately or a method in which a color filter or luminescence converting filter is used, area color displays and multi color displays are obtained. A dot matrix display can be driven by passive driving, or by active driving combined with TFT and the like. These display devices can be used as a display of a computer, television, portable terminal, portable telephone, car navigation, view finder of a video camera, and the like.

Further, the above-described light emitting device in plane form is a thin self-light-emitting one, and can be suitably used as a flat light source for back-light of a liquid crystal display, or as a flat light source for illumination. Further, if a flexible plate is used, it can also be used as a curved light source or a display.

The polymer compound, polymer composition, metal complex or composition of the present invention can be used also as an electrically conductive material or semiconductor material. An electrically conductive thin film or organic semiconductor thin film can be formed and made into a device by the same methods as the method for producing a light emitting device described above, and in the semiconductor thin film, it is preferable that either higher one of electron mobility or hole mobility is 10⁻⁵ cm²/V/sec or more.

The organic semiconductor thin film can be used as an organic solar battery material or organic transistor material.

Next, a photoelectric device will be explained as another embodiment of the present invention.

As the photoelectric device, there is for example a photoelectric conversion device, and exemplified are a device having layer containing a polymer compound or polymer composition of the present invention sandwiched between two electrodes at least one of which is transparent or semi-transparent, and a device having a comb-shaped electrode formed on a layer containing a polymer compound or polymer composition of the present invention formed on a substrate. For improving properties, fullerene and carbon nano tubes and the like may be mixed.

As the method for producing a photoelectric conversion device, a method described in Japanese Patent No. 3146296 is exemplified. Specifically, there are exemplified a method in which a polymer thin film is formed on a substrate having a first electrode, and a second electrode is formed thereon, a method in which a polymer thin film is formed on a pair of comb-shaped electrodes formed on a substrate. Either the first electrode or the second electrode is transparent or semi-transparent.

The method for forming a polymer thin film and the method for mixing fullerene or carbon nano tubes are not particularly restricted, and those exemplified for the light emitting device can be suitably used.

Examples will be shown below for illustrating the present invention further in detail, but the present invention is not limited to these examples.

Here, the polystyrene-reduced number-average molecular weight was measured by gel permeation chromatography (GPC: HLC-8220 GPC, manufactured by Tosoh Corporation, or SCL-10A, manufactured by Shimadzu Corporation) using tetrahydrofuran as a solvent.

### EXAMPLE 1

### Synthesis of Compound (M-2)

Under an argon atmosphere, sodium hydride (60 wt % in mineral oil, 17 mg, 0.43 mmol) was weighed in a 100 mL three-necked flask, and washed with hexane and the supernatant was removed by decantation. Into this was added dehydrated THF (20 ml), then, carbazole (72 mg, 0.43 mmol) and the mixture was stirred at room temperature for 30 minutes. Completion of generation of hydrogen was visually confirmed, and a compound (M-1) (200 mg, 0.43 mmol) was added and the mixture was stirred at room temperature. The reaction mixture was suspended in initiation of the reaction, however, when one hour elapsed, it turned to an orange solution. The solution was stirred at room temperature further for 1 hour, then, the solvent was distilled off under reduced pressure, and the resultant solid was dissolved in chloroform (100 ml) and passed through an alumina short column. The fraction was concentrated under reduced pressure, and a suitable amount of hexane was added to cause re-crystallization, to obtain a compound (M-2) in the form of red powder (216 mg).

¹H-NMR (CD₂Cl₂, 300 MHz) δ6.80 (d, 2H), 7.12-7.39 (m, 8H), 7.54 (d, 2H), 7.68 (d, 2H), 7.73 (d, 2H), 8.08 (t, 1H), 8.24 (d, 2H)

MS (ESI-positive) m/z: 594.1 ([M+H]⁺)

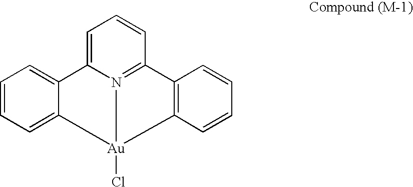

The compound (M-1) was synthesized by a method described in Organometallics; 1998, 17, 3505-3511.

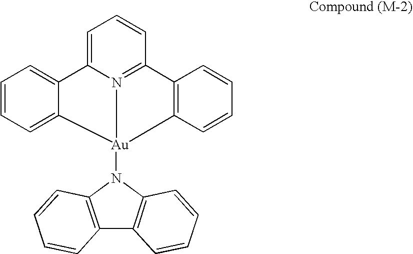

### EXAMPLE 2

### Synthesis of Compound (M-3)

Pentafluorophenylmagnesium bromide was prepared by reacting magnesium and bromofluorobenzene in THF under an argon atmosphere, and used as it was. Under an argon atmosphere, a compound (M-1) (400 mg, 0.86 mmol) was weighed in a 100 mL three-necked flask and dehydrated THF (40 ml) was added to this. The above-described pentafluorophenylmagnesium bromide THF solution (1 M, 1.3 ml, 1.3 mmol) was dropped from a syringe while cooling the resulting suspension with water. After dropping, the suspension was stirred at room temperature for 1 hour to give a colorless solution. Stirring was continued for a while, then, the solvent was distilled off under reduced pressure, and the complex was dissolved in chloroform and passed through an alumina short column. A yellow fraction developing first and a colorless fraction developing subsequently were separated, and a compound (M-3) was obtained (300 mg) from the colorless fraction.

¹H-NMR (CD₂Cl₂, 300 MHz) δ7.19 (d, 2H), 7.31-7.35 (m, 4H), 7.62 (d, 2H), 7.70 (dd, 2H), 8.01 (dd, 1H).

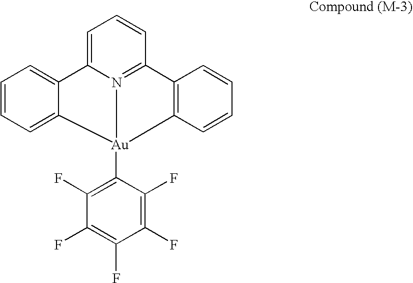

### EXAMPLE 3

A 0.8 wt % chloroform solution was prepared of a mixture prepared by adding the compound (M-2) in an amount of 2 wt % to a compound (M-4) described below.

On a glass substrate carrying an ITO film with a thickness of 150 nm formed by a sputtering method, a film was formed with a thickness of 80 nm by spin coat using a solution of poly(ethylenedioxyaminophene)/polystyrenesulfonic acid (Baytron P, manufactured by Bayer), and dried on a hot plate at 200° C. for 10 minutes. Next, a film was formed at a revolution of 3000 rpm by spin coat using the above-prepared chloroform solution. The thickness was about 100 nm. Further, this was dried under reduced pressure at 80° C. for 1 hour, then, LiF was vapor-deposited with a thickness of about 4 nm as a cathode buffer layer and calcium was vapor-deposited with a thickness of about 5 nm, then, aluminum was vapor-deposited with a thickness of about 80 nm as cathodes, to manufacture an EL device. After the degree of vacuum reached 1×10⁻⁴ Pa or less, vapor deposition of a metal was initiated.

By applying voltage at room temperature on the resultant device, EL light emission showing a peak at 575 nm in a light emission spectrum was obtained. EL property was measured by OLED TEST SYSTEM (manufactured by Tokyo System Development Co., Ltd.).

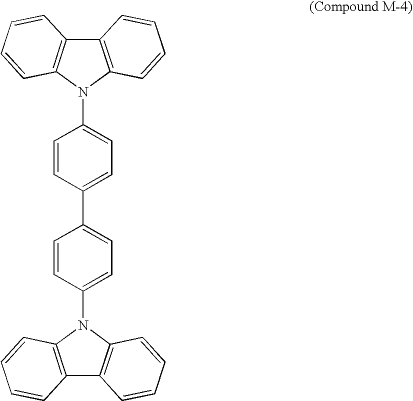

### EXAMPLE 4

A 0.8 wt % chloroform solution was prepared of a mixture prepared by adding the compound (M-3) in an amount of 2 wt % to the compound (M-4), and using this solution, an EL device was manufactured in the same manner as described in Example 3.

By applying voltage at room temperature on the resultant device, EL light emission showing peaks at 480 nm and 510 nm in a light emission spectrum was obtained. EL property was measured by OLED TEST SYSTEM (manufactured by Tokyo System Development Co., Ltd.).

### EXAMPLE 5

A 0.6 wt % chloroform solution was prepared of a mixture prepared by adding the compound (M-3) in an amount of 5 wt % to a polymer compound (P-1), and using this solution, an EL device was manufactured in the same manner as described in Example 3.

By applying voltage at room temperature on the resultant device, EL light emission showing a peak at 580 nm in a light emission spectrum was obtained. EL property was measured by OLED TEST SYSTEM (manufactured by Tokyo System Development Co., Ltd.).

The polymer compound (P-1) was synthesized by a method described in EP1344788 (polystyrene-reduced number-average molecular weight Mn=1.1×10⁵, weight-average molecular weight Mw=2.7×10⁵).

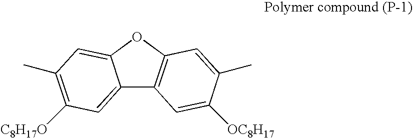

### COMPARATIVE EXAMPLE 1

A 0.6 wt % THF solution was prepared of a mixture prepared by adding the compound (M-1) in an amount of 5 wt % to the compound (P-1).

On a glass substrate carrying an ITO film with a thickness of 150 nm formed by a sputtering method, a film was formed with a thickness of 80 nm by spin coat using a solution of poly(ethylenedioxythiophene)/polystyrenesulfonic acid (Baytron P, manufactured by Bayer), and dried on a hot plate at 200° C. for 10 minutes. Next, a film was formed at a revolution of 2000 rpm by spin coat using the above-prepared THF solution. The thickness was about 70 nm. Further, this was dried under reduced pressure at 80° C. for 1 hour, then, LiF was vapor-deposited with a thickness of about 4 nm as a cathode buffer layer and calcium was vapor-deposited with a thickness of about 5 nm, then, aluminum was vapor-deposited with a thickness of about 80 nm as cathodes, to manufacture an EL device. After the degree of vacuum reached 1×10⁻⁴ Pa or less, vapor deposition of a metal was initiated. Though voltage was applied on the resulting device up to 20 V, light emission from the compound (M-1) was not observed.

### EXAMPLE 6

### Synthesis of Compound (M-5)

Under an argon atmosphere, sodium hydride (60 wt % in mineral oil, 87 mg, 2.17 mmol) was weighed in a 100 mL three-necked flask, and washed with hexane and the supernatant was removed by decantation. Into this was added dehydrated THF (200 ml), then, 2,7-dibromocarbazole (704 mg, 2.17 mmol) and the mixture was stirred at room temperature for 30 minutes. Completion of generation of hydrogen was visually confirmed, and a compound (M-1) (1.0 g, 2.17 mmol) was added and the mixture was stirred at room temperature. The reaction mixture was suspended in initiation of the reaction, however, when one hour elapsed, it turned to an orange solution. The solution was stirred at room temperature further for 1 hour, then, the solvent was distilled off under reduced pressure, and the resultant solid was dissolved in dichloromethane (300 ml) and filtrated through cerite. A suitable amount of hexane was added to cause re-crystallization, to obtain a compound (M-5) (1.3 g).

¹H-NMR (CD₂Cl₂, 300 MHz) δ6.74 (d, 2H), 7.17 (dd, 2H), 7.32 (m, 4H), 7.68 (m, 6H), 8.09 (dd, 3H).

MS (ESI-positive) m/z: 594.1 ([M+H]⁺)

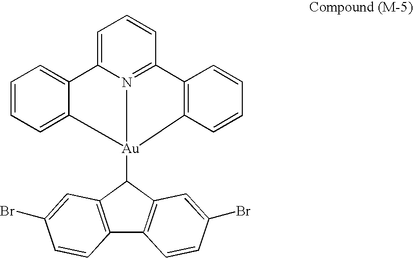

### EXAMPLE 7

### Synthesis of Polymer Compound (P-2)

25 mg (0.033 mmol) of the above-mentioned compound (M-5), 475 mg (0.82 mmol) of 2,7-dibromo-3,6-octyloxydibenzofurane and 351 mg of 2,2′-bipyridyl were charged in a reaction vessel, then, the atmosphere in the reaction system was purged with a nitrogen gas. To this was added 35 ml of tetrahydrofuran (dehydrated solvent) deaerated by previously bubbling with an argon gas. Next, to this mixed solution was added 630 mg of bis(1,5-cyclooctadiene)nickel(0){Ni(COD)₂}, and the mixture was stirred at room temperature for 30 minutes, then, reacted at 60° C. for 3.3 hours. The reaction was conducted in a nitrogen gas atmosphere. After the reaction, this solution was cooled, then, poured into a mixed solution of methanol 15 ml/ion exchanged water 15 ml/25% ammonia water 2.5 ml, and the resulting mixture was stirred for about 2 hours. Next, the produced precipitate was recovered by filtration. This precipitate was dried under reduced pressure, then, dissolved in toluene. This solution was filtrated and insoluble materials were removed, then, this solution was purified by passing through a column filled with alumina. Then, this solution was washed with 1 N hydrochloric acid, 2.5% ammonia water and ion exchanged water, and poured into methanol to cause re-precipitation, and the produced precipitate was recovered. This precipitate was dried under reduced pressure, to obtain 120 mg of a polymer (P-2).

This polymer had a polystyrene-reduced number-average molecular weight of 2.6×10⁴, and a polystyrene-reduced weight-average molecular weight of 4.5×10⁴.

2,7-dibromo-3,6-octyloxydibenzofuran was synthesized by a method described in EP1344788.

### EXAMPLE 8

### Synthesis of Polymer Compound (P-3)

50 mg (0.067 mmol) of the above-mentioned compound (M-5), 450 mg (0.77 mmol) of 2,7-dibromo-3,6-octyloxydibenzofurane and 354 mg of 2,2′-bipyridyl were charged in a reaction vessel, then, the atmosphere in the reaction system was purged with a nitrogen gas. To this was added 35 ml of tetrahydrofuran (dehydrated solvent) deaerated by previously bubbling with an argon gas. Next, to this mixed solution was added 623 mg of bis(1,5-cyclooctadiene)nickel(0){Ni(COD)₂}, and the mixture was stirred at room temperature for 30 minutes, then, reacted at 60° C. for 3.3 hours. The reaction was conducted in a nitrogen gas atmosphere. After the reaction, this solution was cooled, then, poured into a mixed solution of methanol 15 ml/ion exchanged water 15 ml/25% ammonia water 2.5 ml, and the resulting mixture was stirred for about 2 hours. Next, the produced precipitate was recovered by filtration. This precipitate was dried under reduced pressure, then, dissolved in toluene. This solution was filtrated and insoluble materials were removed, then, this solution was purified by passing through a column filled with alumina. Then, this solution was washed with 1 N hydrochloric acid, 2.5% ammonia water and ion exchanged water, and poured into methanol to cause re-precipitation, and the produced precipitate was recovered. This precipitate was dried under reduced pressure, to obtain 116 mg of a polymer (P-3).

This polymer had a polystyrene-reduced number-average molecular weight of 3.0×10⁴, and a polystyrene-reduced weight-average molecular weight of 4.8×10⁴.

### EXAMPLE 9

A 2 wt % toluene solution of the polymer compound (P-3) was prepared.

On a glass substrate carrying an ITO film with a thickness of 150 nm formed by a sputtering method, a film was formed with a thickness of 80 nm by spin coat using a solution of poly(ethylenedioxythiophene)/polystyrenesulfonic acid (Baytron P, manufactured by Bayer), and dried on a hot plate at 200° C. for 10 minutes. Next, a film was formed at a revolution of 600 rpm by spin coat using a 2 wt % toluene solution of the above-prepared polymer compound (P-3). The thickness was about 80 nm. Further, this was dried under reduced pressure at 80° C. for 1 hour, then, LiF was vapor-deposited with a thickness of about 4 nm as a cathode buffer layer and calcium was vapor-deposited with a thickness of about 5 nm, then, aluminum was vapor-deposited with a thickness of about 80 nm as cathodes, to manufacture an EL device. After the degree of vacuum reached 1×10⁻⁴ Pa or less, vapor deposition of a metal was initiated. By applying voltage at room temperature on the resultant device, EL light emission showing a peak at 460 nm in a light emission spectrum was obtained. EL property was measured by OLED TEST SYSTEM (manufactured by Tokyo System Development Co., Ltd.).

### EXAMPLE 10

Using the polymer compound (P-3), a device was manufactured in which hole current flows mainly. The device was manufactured as described below.

On a glass substrate carrying an ITO film with a thickness of 150 nm formed by a sputtering method, a film was formed with a thickness of 80 nm by spin coat using a solution of poly(ethylenedioxythiophene)/polystyrenesulfonic acid (Baytron P, manufactured by Bayer), and dried on a hot plate at 200° C. for 10 minutes. Next, a film was formed at a revolution of 2800 rpm by spin coat using a 1.7 wt % toluene solution of the polymer compound (P-3). The thickness was about 80 nm. Further, this was dried under reduced pressure at 80° C. for 1 hour, then, Au was vapor-deposited with a thickness of about 100 nm as a cathode buffer layer, to manufacture a device. After the degree of vacuum reached 1×10⁻⁴ Pa or less, vapor deposition of a metal was initiated.

The current densities when voltages of 5 V and 10 V were applied on the produced device were 2.0×10⁻⁵ A/cm² and 4.4×10⁻⁵ A/cm², respectively. For measurement of the current density, pico-ammeter 4140B (manufactured by Yokogawa Hewlett Packard) was used.

### COMPARATIVE EXAMPLE 2

For comparison, an analogous device was manufactured using the above-mentioned polymer compound (P-1) containing no metal complex structure. The current densities when voltages of 5 V and 10 V were applied on the produced device were 3.1×10⁻⁶ A/cm² and 8.7×10⁻⁶ A/cm², respectively, that is, the polymer compound (P-3) showed more excellent hole current injecting property and transportability.

### INDUSTRIAL APPLICABILITY

The light emitting device using the polymer compound of the present invention in a light emitting layer has excellent practical properties such as high efficiency, drivability at lower voltage and the like.

1. A polymer compound comprising in the same molecule a structure of (A) a conjugated polymer and a structure of (B) a metal complex having at least one tridentate ligand and having a central metal of which atomic number is 21 or more.

2. The polymer compound according to claim 1, having the structure of said metal complex (B) in the main chain of the conjugated polymer (A).

3. The polymer compound according to claim 1, having the structure of said metal complex (B) on the side chain of the conjugated polymer (A).

4. The polymer compound according to claim 1, having the structure of said metal complex (B) on the end of the conjugated polymer (A).

5. The polymer compound according to claim 1, wherein the conjugated polymer (A) contains an aromatic ring in the main chain.

6. The polymer compound according to claim 1, wherein the polystyrene-reduced number-average molecular weight is 10³ to 10⁸.

7. A metal complex (B′) comprising a metal selected from transition metals of IV and V periods and W, Os, Ir, Au and lanthanoids, a monodentate ligand, and a tridentate ligand containing at least one aromatic ring and containing tridentate atoms in the ring structure, the metal complex showing light emission in the visible region at 10° C. or higher.

8. A metal complex (B″) comprising a metal selected from transition metals of IV and V periods and W, Os, Ir, Au and lanthanoids, a monodentate ligand having an aromatic ring, and a tridentate ligand containing at least one aromatic ring and containing tridentate atoms in the ring structure.

9. The metal complex according to claim 7, having a monodentate ligand in which a coordinated atom in the aromatic ring is carbon or nitrogen.

10. The metal complex according to claim 9 wherein the monodentate ligand has a structure (S-1) shown below 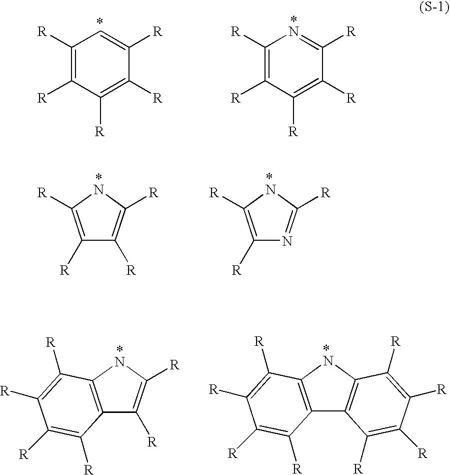
in the above-described formula (S-1), * represents an atom coordinated to a metal, and Rs represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group.

11. The metal complex according to claim 7, wherein the aromatic ring in the monodentate ligand is a condensed ring.

12. The metal complex according to claim 11 wherein the monodentate ligand has a structure (S-2) shown below 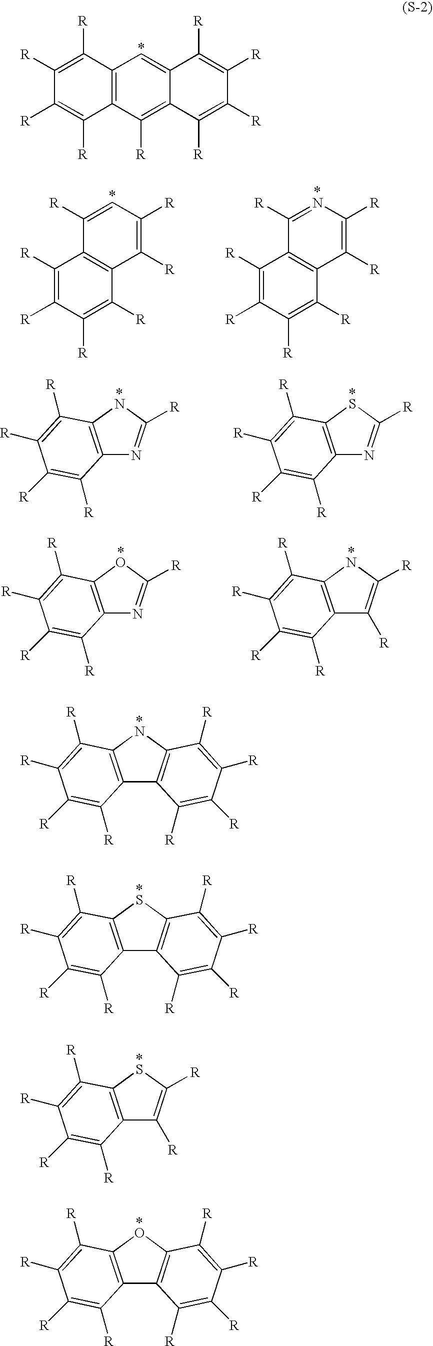
in the above-described formula (S-2), * represents an atom coordinated to a metal, and Rs represent each independently a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group.

13. The metal complex according to claim 7, wherein the central metal is W, Os, Ir or Au.

14. The metal complex according to claim 13 wherein the central metal is W or Au.

15. The metal complex according to claim 7, having a structure of the following general formula (B′-1), (B′-2) or (B′-3) and a monodentate ligand: 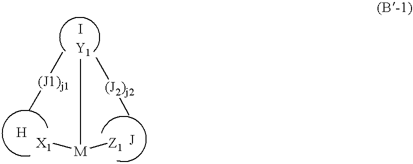
wherein, M represents a metal selected from transition metals of IV and V periods and W, Os, Ir, Au and lanthanoids, H ring, I ring and J ring represent each independently an aromatic ring, and X₁, Y₁ and Z₁ present in each ring structure represent each independently an atom coordinated to the metal M, J1 and J2 represent each independently an alkylene group having 1 to 6 carbon atoms, alkenylene group having 2 to 6 carbon atoms or alkynylene group having 2 to 6 carbon atoms, and carbon atoms in the alkylene group, alkenylene group and alkynylene group may each be substituted with an oxygen atom or sulfur atom, j1 and j2 represent each independently 0 or 1, 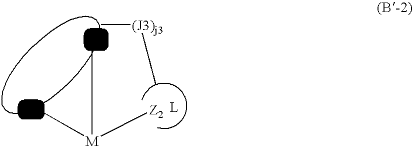
wherein, M represents a metal selected from transition metals of IV and V periods and W, Os, Ir, Au and lanthanoids, K ring and L ring represent each independently an aromatic ring, X₂, Y₂ and Z₂ present in each ring structure represent each independently an atom coordinated to the metal M, J3 represents an alkylene group having 1 to 6 carbon atoms, alkenylene group having 2 to 6 carbon atoms or alkynylene group having 2 to 6 carbon atoms, carbon atoms in the alkylene group, alkenylene group and alkynylene group may each be substituted with an oxygen atom or sulfur atom, and j3 represents 0 or 1, 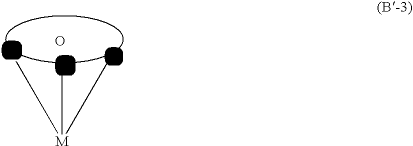
wherein, M represents a metal selected from transition metals of IV and V periods and W, Os, Ir, Au and lanthanoids, O ring represents an aromatic ring, and X₃, Y₃ and Z₃ present in the ring structure represent each independently an atom coordinated to the metal M.

16. The metal complex according to claim 15 wherein the aromatic ring represented by H ring, I ring, J ring, K ring, L ring and O ring in the above-described general formulae (B′-1), (B′-2) and (B′-3) is an aromatic hydrocarbon ring or heteroaromatic ring.

17. The metal complex according to claim 16 wherein the aromatic ring represented by H ring, I ring, J ring and L ring in the above-described general formulae (B′-1) and (B′-2) is a monocyclic aromatic hydrocarbon ring or monocyclic hetero ring.

18. The metal complex according to claim 16, wherein the aromatic ring represented by K ring and O ring in the above-described general formulae (B′-2) and (B′-3) is a condensed aromatic hydrocarbon ring or condensed hetero ring.

19. A polymer composition comprising the metal complex according to claim 7 and an organic compound.

20. The polymer composition according to claim 19 wherein the organic compound is a conjugated polymer.

21. The polymer compound according to claim 1 comprising in the same molecule a structure of a metal complex (B′) comprising a metal selected from transition metals of IV and V periods and W, Os, Ir, Au and lanthanoids, a monodentate ligand, and a tridentate ligand containing at least one aromatic ring and containing tridentate atoms in the ring structure, the metal complex showing light emission in the visible region at 10° C. or higher and a structure of the conjugated polymer (A).

22. A polymer composition comprising at least one polymer compound according to claim 1.

23. The polymer composition according to claim 20, further comprising at least one material selected from hole transporting materials, electron transporting materials and light emitting materials.

24. An ink composition comprising at least one of the polymer compound according to claim 1.

25. The ink composition according to claim 24, comprising two or more organic solvents.

26. The ink composition according to claim 24, wherein the viscosity is 1 to 100 mPa·s at 25° C.

27. A light emitting material comprising the polymer compound according to claim 1.

28. A light-emitting thin film comprising the polymer compound according to claim 1.

29. An electrically conductive thin film comprising the polymer compound according to claim 1.

30. An organic semiconductor thin film comprising the polymer compound according to claim 1.

31. An organic transistor comprising the organic semiconductor thin film according to claim 30.

32. A method for producing the thin film according to claim 28, using an inkjet method.

33. A device comprising a layer containing the polymer compound according to claim 1.

34. The device according to claim 33, comprising further a charge transporting layer between electrodes composed of an anode and a cathode.

35. The device according to claim 33, wherein the device is a polymer light emitting device.

36. A polymer light emitting device comprising an organic layer between electrodes composed of an anode and a cathode wherein the organic layer contains the polymer compound according to claim 1.

37. The polymer light emitting device according to claim 36 wherein the organic layer is a light emitting layer.

38. The polymer light emitting device according to claim 37 wherein the light emitting layer comprises further at least one material selected from hole transporting materials, electron transporting material or light emitting materials.

39. A sheet light source using the polymer light emitting device according to claim 36.

40. A segment display using the polymer light emitting device according to claim 36.

41. A dot matrix display using the polymer light emitting device according to claim 36.

42. A liquid crystal display using the polymer light emitting device according to claim 36 as a back light.
